(19) United States
(12) Patent Application Publication
(10) Pub. No.: US 2023/0079919 A1
(43) Pub. Date: Mar. 16, 2023

(54) APPARATUS, SYSTEMS, AND METHODS FOR TUNING THE STRUCTURE, CONDUCTIVITY, AND/OR WETTABILITY OF LASER INDUCED GRAPHENE FOR A VARIETY OF FUNCTIONS INCLUDING MULTIPLEXED OPEN MICROFLUIDIC ENVIRONMENTAL BIOSENSING AND ENERGY STORAGE DEVICES

(71) Applicant: Iowa State University Research Foundation, Inc., Ames, IA (US)

(72) Inventors: Jonathan Claussen, Ames, IA (US); Bolin Chen, San Jose, CA (US); Carmen L. Gomes, Ames, IA (US)

(21) Appl. No.: 17/931,228

(22) Filed: Sep. 12, 2022

Related U.S. Application Data
(60) Provisional application No. 63/261,085, filed on Sep. 10, 2021.

(51) Int. Cl. B23K 26/364; H01G 11/86; B01L 3/00; B23K 26/351; B23K 26/0622

(52) U.S. Cl. CPC B23K 26/364; H01G 11/86; B01L 3/502707; B01L 3/502715; B23K 26/351; B23K 26/0622; H01G 11/36

(57) ABSTRACT

Apparatus, systems, and methods for tuning the structure, conductivity, and/or wettability of laser induced graphene for a variety of functions including but not limited to multiplexed open microfluidic environmental biosensing and energy storage devices. Aspects of this invention introduce a one-step, mask-free process to create, pattern, and tune laser-induced graphene (LIG) with a ubiquitous CO2 laser or other laser. The laser parameters are adjusted to create LIG with different electrical conductivity, surface morphology, and surface wettability without the need for post chemical modification. This can be done with a single lasing. By optionally introducing a second (or third, fourth, or more) lasing(s), the LIG characteristics can be changed in just the same one step of using the laser scribing without other machines or sub-systems. One example is a second lasing with the same laser sub-system at low laser power, wherein the wettability of the LIG can be significantly altered. Such films presented unique superhydrophobicity owing to the combination of the micro/nanotextured structure and the removal of the hydrophilic oxygen-containing functional groups. The ability to tune the wettability of LIG while retaining high electrical conductivity and mechanical robustness allows rational design of LIG based on application.

### CROSS-REFERENCE TO RELATED APPLICATIONS

This application claims the benefit of Provisional Application U.S. Ser. No. 63/261,085 filed on Sep. 10, 2021, all of which is herein incorporated by reference in its entirety.

### GOVERNMENT RIGHTS CLAUSE

This invention was made with government support under contract number 1U01 AA029328-01 awarded by the National Institutes of Health; under contract numbers ECCS-1841649, CMMI-2037026, CBET1706994, CBET1756999 and CBET1805512 awarded by the National Science Foundation; and contract numbers 2016-67021-25038, 2020-67021-31375 and 2021-67021-34457 awarded by the United States Department of Agriculture. The government has certain rights in the invention.

### 1. BACKGROUND OF THE INVENTION

### 1.1. Field of the Invention

The present invention relates to laser-induced graphene (LIG) fabrication and functionalization of high resolution patterns on a substrate and, in particular, to tuning morphology, conductivity, and/or wettability of the LIG patterns for a wide variety of applications. Non-limiting examples of how the invention might be made, used, and implemented are described at Chen, et al., Tuning the Structure, Conductivity, and Wettability of Laser-Induced Graphene for Multiplexed Open Microfluidic Environmental Biosensing and Energy Storage Devices, ACS Nano 2022, 16, 15-28, which is incorporated by reference herein and Supporting Information and videos at https://pubs.acs.org/doi/10.1021/acsnano.1c04197, which are incorporated by reference herein.

### 1.2. Problems in the Art

The benefits and challenges in effectively and efficiently fabricating high-resolution conductive circuits are well-known in the state of this technical art. The inventors have extensive work in this area. Examples are cited in the Bibliography of ACS Nano 2022, 16, 15-28 cited above, and described in
Das, S. R.; Srinivasan, S.; Stromberg, L. R.; He, Q.; Garland, N.; Straszheim, W. E.; Ajayan, P. M.; Balasubramanian, G.; Claussen, J. C. Superhydrophobic Inkjet Printed Flexible Graphene Circuits via Direct-Pulsed Laser Writing. Nanoscale 2017, 9 (48), 19058-19065.
Hall, L. S.; Hwang, D.; Chen, B.; Van Belle, B.; Johnson, Z. T.; Hondred, J. A.; Gomes, C. L.; Bartlett, M. D.; Claussen, J. C., All-Graphene-Based Open Fluidics for Pumpless, Small-Scale Fluid Transport via Laser-Controlled Wettability Patterning. Nanoscale Horizons 2021, 6 (1), 24-32. https://doi.org/10.1039/d0nh00376j;
Hondred, J. A.; Johnson, Z. T.; Claussen, J. C., Nanoporous Gold Peel-and-Stick Biosensors Created with Etching Inkjet Maskless Lithography for Electrochemical Pesticide Monitoring with Microfluidics. J. Mater. Chem. C 2020, 8 (33), 11376-11388. https://doi.org/10.1039/D0TC01423K; and
Hondred, J. A.; Medintz, I. L.; Claussen, J. C., Enhanced Electrochemical Biosensor and Supercapacitor with 3D Porous Architectured Graphene via Salt Impregnated Inkjet Maskless Lithography. Nanoscale Horizons 2019, 4 (3), 735-746. https://doi.org/10.1039/C8NH00377G;
   each of which is incorporated by reference herein and are references [53], [54], [90], and [91], respectively, in the Bibliography of Nano 2022, 16, 15-28 cited above, incorporated by reference herein, and summarized infra.

Benefits of LIG as a technique of production of high resolution graphene-based patterns in or on a substrate of starting material have been recognized in this technical art. The inventors also have extensive work in this area. A few examples are cited in the Bibliography of Nano 2022, 16, 15-28 cited above, and described in—
Kucherenko, I. S.; Sanborn, D.; Chen, B.; Garland, N.; Serhan, M.; Forzani, E.; Gomes, C.; Claussen, J. C. Ion-Selective Sensors Based on Laser-Induced Graphene for Evaluating Human Hydration Levels Using Urine Samples. Adv. Mater. Technol. 2020, 5 (6), 1901037. https://doi.org/10.1002/admt.201901037;
Garland, N. T.; McLamore, E. S.; Cavallaro, N. D.; Mendivelso-Perez, D.; Smith, E. A.; Jing, D.; Claussen, J. C. Flexible Laser-Induced Graphene for Nitrogen Sensing in Soil. ACS Appl. Mater. Interfaces 2018, 10 (45), 39124-39133. https://doi.org/10.1021/acsami.8b10991;
Zachary T. Johnson, Kelli Williams, Bolin Chen, Robert Sheets, Nathan Jared, Jingzhe Li, Emily A. Smith, and Jonathan C. Claussen. Electrochemical Sensing of Neonicotinoids Using Laser-Induced Graphene. ACS Sens. 2021, 6, 3063-3071;
Raquel R. A. Soares, Robert G. Hjort, Cicero C. Pola, Kshama Parate, Efraim L. Reis, Nilda F. F. Soares, Eric S. McLamore, Jonathan C. Claussen, and Carmen L. Gomes. Laser-Induced Graphene Electrochemical Immunosensors for Rapid and Label-Free Monitoring of Salmonella enterica in Chicken Broth, ACS Sens. 2020, 5, 1900-1911; each of which is incorporated by reference herein.

For example, techniques for creation of the patterns with a computer-controlled laser allow direct fabrication of patterns without lithography or masks, and without secondary steps such as chemical post-pattern processing.

Work by others in LIG patterning is described in
Li, Yilun, Duy Xuan Luong, Jibo Zhang, Yash R. Tarkunde, Carter Kittrell, Franklin Sargunaraj, Yongsung Ji, Christopher J. Arnusch, and James M. Tour. 2017. “Laser-Induced Graphene in Controlled Atmospheres: From Superhydrophilic to Superhydrophobic Surfaces.” Advanced Materials 29 (27): 1700496. https://doi.org/10.1002/adma.201700496;
Luong, Duy Xuan, Kaichun Yang, Jongwon Yoon, Swatantra P. Singh, Tuo Wang, Christopher J. Arnusch, and James M. Tour. 2019. “Laser-Induced Graphene Composites as Multifunctional Surfaces.” ACS Nano 13 (February): 2579-86. https://doi.org/10.1021/acsnano.8b09626;
Nasser, Jalal, Jiajun Lin, Lisha Zhang, and Henry A. Sodano. 2020. “Laser Induced Graphene Printing of Spatially Controlled Super-Hydrophobic/Hydrophilic Surfaces.” Carbon 162 (June): 570-78. https://doi.org/10.1016/j.carbon.2020.03.002; and
Duy, Luong Xuan, Zhiwei Peng, Yilun Li, Jibo Zhang, Yongsung Ji, and James M. Tour. 2018. “Laser-Induced Graphene Fibers.” Carbon 126 (January): 472-79. https://doi.org/10.1016/j.carbon.2017.10.036
   which are references [59], [60], [61], and [62], respectively, in the Bibliography of Nano 2022, 16, 15-28 cited above, incorporated by reference herein, and summarized below.

A few methods of others have been proposed to create hydrophobic LIG, such as lasing polyimide in an inert gas chamber [59] (Li et al. 2017), and chemical modification of an LIG surface by forming a PDMS composite [60] (Luong et al. 2019). However, these methods either require a controlled inert gas environment which is not scalable or introduction of other chemicals which increases fabrication steps. Recently, Sodano's group reported wettability patterning of LIG by tuning the pulse density of the laser with no chemical modification [61] (Nasser et al. 2020). However, hydrophobic LIG produced by low DPI (dots per inch) typically suffers from high electrical resistance (300-3000 Ωsq-1) and a mechanically fragile surface due to insufficient energy deposition into the substrate to fabricate the LIG, and insufficient conversion from fiber to sheet shape [62] (Duy et al. 2018). Controlled wettability of graphene with high electrical conductivity and mechanical robustness is highly desirable for a multitude of applications including electrochemical sensors, electrical supercapacitors, and open microfluidics; among others. References are to citations in the Bibliography of Nano 2022, 16, 15-28 cited above, incorporated by reference herein, and summarized below.

Here, we developed a straightforward in-situ second lasing method to create hydrophobic LIG. This method allows the formation of a highly conductive (15-30 Ωsq-1) base LIG layer, followed by another lasing pass at lower fluence to microstructure the LIG surface layer in order to achieve the desired high conductivity and high hydrophobicity. The second lasing creates a hydrophobic surface independent of what laser setting was used in the first lasing, which gives more freedom of tuning the physical (structure and morphology), chemical (functional groups), and electrical (resistance) properties of the resultant LIG surface. Laser fluence describes the energy delivered per unit (or effective) area. Within the community of laser scientists and technicians, it is very common to define fluence in units of J/cm². A discussion of lower versus higher fluence CO₂ lasers can be found at Jung, J. Y. et al, Lower-Fluence, Higher-Density versus Higher-Fluence, Lower-Density Treatment with a 10,600-nm Carbon Dioxide Fractional Laser System: A Split-Face, Evaluator-Blinded Study, Dermatologic Surgery 36/12: 2022-9, incorporated by reference herein. Laser fluence and energy density is also discussed at US20210171351A1, to inventors Tour et al., entitled “Method for printing objects having laser-induced graphene (LIG) and/or laser-induced graphene scrolls (LIGs) materials”, incorporated by reference herein.

Additionally, an all LIG-based multiplex sensing system that measures nitrate, potassium, ammonium, and organophosphate levels is reported for the first time.

The Introduction section of Nano 2022, 16, 15-28 cited above discusses in detail work in this area and problems and deficiencies in the state of the art.

The inventors have recognized there is room for improvement in this art. For example, while attempts have been made to tune wettability of LIG patterns, those attempts typically also alter conductivity, including in counter-productive ways. Also, some attempts at LIG do not allow production of morphologies that would be beneficial functionally or for economy and efficiency in fabrication.

As is appreciated by those skilled in this technical art, there are a number of factors that must be considered when designing and fabricating patterns of graphene on a substrate in an efficient and effective matter. Some of those factors can be competing or antagonistic with one another. For example, as mentioned above, tuning wettability of graphene for a given application or use may detrimentally affect conductivity of the graphene for the application or use. Another example is that tuning any of morphology, conductivity, and/or wettability of graphene for a given application or use may conflict with any of the others of morphology, conductivity, and wettability for the application or use, or functionalization of the graphene for that application or use. As such, there are technological hurdles and uncertainties regarding these factors for every application and use. Achieving a desired result for one of the factors may not achieve the result for the others.

And, as will be further discussed below, there are technological hurdles and uncertainties regarding how to fabricate such graphene-based patterns in effective, efficient, and scalable fashion. Attempts have been made which require multiple steps and multiple systems in fabrication which is antagonistic which efficiency of time, resources, and cost of fabrication, including fabrication of many patterns or complex patterns. For example, some attempts require pre- or post-patterning processes that require different sub-systems than the patterning sub-system. This can be challenging to efficient fabrication of just one patterning, and particularly of many patternings.

For example, a technique for creating superhydrophobic graphene as disclosed in Das, S. R.; Srinivasan, S.; Stromberg, L. R.; He, Q.; Garland, N.; Straszheim, W. E.; Ajayan, P. M.; Balasubramanian, G.; Claussen, J. C. Superhydrophobic Inkjet Printed Flexible Graphene Circuits via Direct-Pulsed Laser Writing. Nanoscale 2017, 9 (48), 19058-19065 cited above, is diagrammatically illustrated at FIG. 1A. While it discloses superhydrophobic graphene, it requires a method 10 which utilizes multiple steps 12, 14, and 16 by multiple sub-systems 13 and 15 to do so. This is not conducive to efficient fabrication and scalability. Graphene patternings are created by an inkjet printing system 13 using previously formulated graphene ink onto a substrate (step 12). A laser system 15 is then scanning on the printed pattern to anneal the pattern to change its properties (step 14). Post-patterning processing (step 16) with a third system 17 is used.

Another example 20 is illustrated at FIG. 1B. From Hondred, J. A.; Stromberg, L. R.; Mosher, C. L.; Claussen, J. C. High-Resolution Graphene Films for Electrochemical Sensing via Inkjet Maskless Lithography. ACS Nano 2017, 11 (10), 9836-9845 cited above, previously-formulated graphene is spin-coated over a substrate (Step 22) by system 23. A laser scribing system 25 then patterns the graphene coating (step 24). Again, this is antagonistic with scability. It is challenging to fabricate multiple graphene patterns over a scalable substrate when having to use multiple steps and systems.

Thus, the inventors have identified important technological problems in the state of the art.

### 2. SUMMARY OF THE INVENTION

### 2.1. Objects, Features, and Advantages

It is a principal object, feature, and advantage of the present invention to provide methods, apparatus, and systems which improve over or solve problems and deficiencies in the state of the art.

Other objects, features, and/or advantages of the present invention are to provide apparatus, methods, and systems which include one or more of:
a. allow efficient and effective fabrication of LIG structures for a wide variety of uses and applications, including but not limited to open surface microfluidics, electrodes, sensors, circuits, and combinations of any of the foregoing;
b. allow tuning of structural, conductive, chemical, and wetting properties, individually and collectively, of LIG structures or portions thereof according to need or desire;
c. allow effective and efficient fabrication of such LIG structures at a wide range of scales.

Further objects, features, and advantages will become apparent with reference to ACS Nano 2022, 16, 15-28 and its Supporting Information cited above, and the following descriptions.

### 2.2. Aspects of the Invention

Aspects of this invention introduce a one-step, mask-free process to create, pattern, and tune laser-induced graphene (LIG) with a ubiquitous CO2 laser or other laser. Non-limiting examples of other lasers include UV lasers, YAG lasers, and fiber lasers. Aspects of the invention may work with any laser that has controllable energy density. The laser parameters are adjusted to create LIG with different electrical conductivity, surface morphology, and surface wettability without the need for post chemical modification. This can be done with a single lasing. By optionally introducing a second (or third, fourth, or more) lasing(s), the LIG characteristics can be changed in just the same one step of using the laser scribing without other machines or sub-systems. One example is a second lasing with the same laser sub-system at low laser power, wherein the wettability of the LIG can be significantly altered. Such films presented unique superhydrophobicity owing to the combination of the micro/nanotextured structure and the removal of the hydrophilic oxygen-containing functional groups. The ability to tune the wettability of LIG while retaining high electrical conductivity and mechanical robustness allows rational design of LIG based on application. In another non-limiting example, such definitive control over material properties enables the creation of such things as LIG-based integrated open microfluidics and electrochemical sensors that are capable of splitting a single water sample along four multifurcating paths to three ion selective electrodes (ISEs) for potassium (K+), nitrate (NO3−), and ammonium (NH4+) ion monitoring and to an enzymatic pesticide sensor for organophosphate pesticides (parathion) monitoring. In an additional non-limiting example, improved capacitance is achieved by controlling the wettability of LIG electrode which is selected based on the type of electrolyte used for the fabrication of supercapacitor. Superhydrophobic and superhydrophilic LIG surfaces created by the rational design of surface wettability not only opens the way for low-cost microfluidics but also benefits a multitude of applications that involve interface chemistry such as electrochemical sensing, energy storage, desalination, and oil/water separation. Nano 2022, 16, 15-28 cited above and its Supporting Information describe examples of this technology and are attached. Some key points regarding the technology are:
1. Aspects of the invention demonstrate how one can tune the properties of electrical conductivity, surface wettability, and surface morphology (nano/microstructuring) of laser induced graphene (LIG) created with a laser. This all can be performed with same laser in an open-air environment. As mentioned in the Section entitled “INTRODUCTION” of Nano 2022, 16, 15-28 cited above, others cannot control LIG on a surface for all of these properties in an open air environment. Performing these steps in an open-air environment is important because it enables a more scalable fabrication protocol and hence less expensive fabrication protocol. The LIG patterns are created directly from the carbonization of the substrate and patterned thru CAD design without the need for electrode synthesis materials (e.g., inks, or paste) to pattern the material onto a substrate.
2. Currently, few processes are able to control the wettability of LIG. Most are limited to secondary postprocessing such as chemical coating or under controlled inert gas environment which is either time consuming or not scalable. Aspects of the current method that directly control the wettability of LIG at ambient conditions can result in tunability, inter alia, of the electrical conductivity and mechanical robustness of the film (e.g., 300-3000 ohms/sq or other amounts or ranges).
3. We demonstrate, for the first time, the concept of monitoring both ions and pesticides on the same sensor platform. In particular we measure nitrate (NO3−), potassium (K+), ammonium (NH4+) ions as well as organophosphate pesticides (i.e., parathion) with ion selective electrodes (ISEs) patterned by LIG. The results were outstanding for nitrate, potassium, and ammonium as the ISEs displayed near-Nernstian sensitivities with approximately four orders of magnitude of sensing range and low detection limits (10-4.97 M, 10-4.71 M, and 10-4.67 M for the K+, NO3−, and NH4+ ISEs, respectively), while the pesticide sensor exhibited the lowest limit of detection (LOD) (15.4 pM) for an electrochemical parathion sensor known to date
4. In one aspect, this invention can be applied in a system that includes using a low-cost substrate (e.g., polyimide) and CO2 laser (e.g., 75 W) to fabricate the LIG with controlled wettability
5. Aspects of this process have been demonstrated to enhance the electrochemical activity of an organophosphate biosensor that can detect parathion (pM concentration) at levels required by regulatory agencies.
6. Additionally, this process showed to extend the longevity of an ion selective electrode from weeks to months.

One aspect of the invention is a method of fabricating an LIG pattern by tuning its wettability and/or one or more other of its characteristics by control of laser scribing parameters for the pattern. In one example, wettability is tuned to be hydrophobic or superhydrophobic. In another example, wettability is tuned to be hydrophobic or to near or at super hydrophobic, or to hydrophilic or to near or super hydrophilic. One non-limiting example is an interdigitated micro supercapacitor circuit where, in some configurations, hydrophobic interdigitated electrodes (IDEs) are desired, or in some configurations hydrophilic IDEs are desired. Laser scribing parameters can be controlled to produce the desired wettability of the IDEs. Additionally, laser scribing parameter control can be balanced with other desired end properties of the LIG pattern. In one non-limiting example, electrical conductivity and/or surface morphology can be tuned, as desired, along with surface wettability. This aspect of the invention can be applied in analogous ways to other end uses. Nano 2022, 16, 15-28 and its Supporting Information cited above refer to some. This aspect of the invention can be applied also to end uses such as indicated in:
Kucherenko, I. S.; Sanborn, D.; Chen, B.; Garland, N.; Serhan, M.; Forzani, E.; Gomes, C.; Claussen, J. C. Ion-Selective Sensors Based on Laser-Induced Graphene for Evaluating Human Hydration Levels Using Urine Samples. Adv. Mater. Technol. 2020, 5 (6), 1901037. https://doi.org/10.1002/admt.201901037;
Garland, N. T.; McLamore, E. S.; Cavallaro, N. D.; Mendivelso-Perez, D.; Smith, E. A.; Jing, D.; Claussen, J. C. Flexible Laser-Induced Graphene for Nitrogen Sensing in Soil. ACS Appl. Mater. Interfaces 2018, 10 (45), 39124-39133. https://doi.org/10.1021/acsami.8b10991;
Zachary T. Johnson, Kelli Williams, Bolin Chen, Robert Sheets, Nathan Jared, Jingzhe Li, Emily A. Smith, and Jonathan C. Claussen. Electrochemical Sensing of Neonicotinoids Using Laser-Induced Graphene. ACS Sens. 2021, 6, 3063-3071;
Raquel R. A. Soares, Robert G. Hjort, Cicero C. Pola, Kshama Parate, Efraim L. Reis, Nilda F. F. Soares, Eric S. McLamore, Jonathan C. Claussen, and Carmen L. Gomes. Laser-Induced Graphene Electrochemical Immunosensors for Rapid and Label-Free Monitoring of Salmonella enterica in Chicken Broth, ACS Sens. 2020, 5, 1900-1911.

Another aspect of the invention is a method of fabricating an LIG pattern with variation in wettability for different portions of the pattern by control of laser scribing parameters for the different portions. In one example, wettability of at least one portion of the pattern is tuned to be hydrophobic or superhydrophobic (and/or other characteristics such as electrical conductivity or surface morphology are tuned), and wettability (and/or other characteristics such as electrical conductivity or surface morphology) of at least one other portion of the pattern is/are tuned to be hydrophilic, super hydrophilic or ultra hydrophilic by a subsequent second lasing of those portions of the original first lased patterning. Further tuning can be achieved, if desired, by third, fourth, or more lasings; at either portions of the first lasing or portions of any subsequent lasing.

These and other objects, features, aspects, or advantages of the invention will become more apparent with reference to Nano 2022, 16, 15-28 and its Supporting Information cited above. As will be appreciated, aspects of the invention can be applied to different graphene-precursor substrates, different end applications or uses including through different functionalizations of portions or all of the LIG patternings, all with a one step or one sub-system patterning of the graphene precursor substrate.

### 3. BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1A is a diagram illustrating a multiple-step fabrication technique of patterned graphene from the state of the art.

FIG. 1B is a diagram illustrating another multiple-step fabrication technique of patterned graphene from the state of the art.

FIG. 2A is a diagram illustrating a generalized embodiment of a single step fabrication of LIG patterned and tuned graphene with a laser scribing system according to one or more aspects of the present invention.

FIG. 2B is a diagram of the combination of general components and methods of one example of the generalized embodiment of FIG. 2A.

FIG. 2C is a diagram of one example of the basic components of one example of a laser scribing system such as can be used with the fabrication method of FIGS. 2A and B.

FIG. 2D is a diagram of one example of a scalable system for mass production of tuned LIG patternings such as might be used with the generalized embodiment of FIGS. 2A-C.

FIGS. 3-18, are illustrations related to a specific embodiments according to the present invention from Nano 2022, 16, 15-28 cited above; namely:

FIGS. 3A, 3B, 3C, and 3D1-4. Fabrication scheme and the effect of laser pulse density on the electrical, electrochemical, and wetting behavior of the laser-induced graphene (LIG). (FIG. 3A) Schematic of the LIG fabrication. The effect of density per inch (DPI) on the (FIG. 3B) sheet resistance, (FIG. 3C) electrochemical activity based on cyclic voltammetry curves, and (FIGS. 4D1-4) microstructure and surface wettability of LIG created with a single lasing (LIG-SL) shown via SEM imaging and water contact angle measurements, respectively. The inset of SEM images shows the single water droplet (5 μL) on corresponding LIG surface.

FIGS. 4A1-8, 4B, 4C, 4D, 4E, 4F and 4G. Characterization of LIG properties after the double lasing (DL) process: (FIGS. 4A1-8) the SEM images of LIG-DL created at different double lasing power (1% to 7%) with 200 μm scale bar, and their corresponding (FIG. 4B) sheet resistance, (FIG. 4C) Cyclic voltammetry characterization of LIG-DL samples within ferricyanide mediator solution (4 mM Fe(CN)63- and 0.1 M KCl), and (FIG. 4D) advancing and receding water contact angles (CA). (FIG. 4E) Small-angle X-ray scattering (SAXS) spectrum of polyimide (PI) and LIG-SL from single lasing (SL) at 15% speed, 7% power. (FIG. 4F) Raman spectrum comparing LIG-SL and LIG-DL, and (FIG. 4G) XPS survey spectra comparing LIG-SL and LIG-DL.

FIGS. 5A-D. Schematic of the all in one open-microfluidics multiplex biosensing platform fabrication and functionalization for ion and pesticide sensing.

FIGS. 6A-L. The open circuit potential response of the (FIG. 6A) potassium ion-selective electrode (K+ ISE), (FIG. 6B) nitrate ion-selective electrode (NO3− ISE), and (FIG. 6C) ammonium ion-selective electrode (NH4+ ISE) to KCl, KNO3, and NH4Cl solutions, respectively, within the concentration range from 10-6 M to 10-2 M. The corresponding (FIGS. 6E-G) calibration plots, and (FIGS. 6I-K) selectivity test with 2 mM of fixed interference ions. Electrochemical response of the pesticide sensor. (FIG. 6D) The current vs. time response to different concentrations of parathion, (FIG. 6H) corresponding calibration plot, and (FIG. 6L) selectivity test of acetylcholinesterase sensor comparing atrazine, dicamba, glyphosate, thiamethoxam, dinotefuran, imidacloprid, clothianidin, paraoxon, and parathion. Error bars represent standard deviation with n=3.

FIGS. 7A-K. (FIG. 7A) Scheme of the laser-induced graphene micro supercapacitor (LIG-MSC) and photo of LIG-MSC-SL. (FIGS. 7B-C) Cyclic voltammetry (CV) curves of LIG-MSC-single lasing (LIG-MSC-SL) and LIG-MSC-double lasing (LIG-MSC-DL) at scan rates of 10, 20, 50, 100, 200 mV/s. (FIGS. 7D-E) Galvanostatic charge-discharge (GCD) curves of LIG-MSC-SL and LIG-MSC-DL at current densities of 0.1, 0.2, 0.5, 1, 2, 5 mA/cm2. The comparison of electrochemical performance between LIG-MSC-SL and LIG-MSC-DL, (FIG. 7F) CV curves at a scan rate of 100 mV/s; (FIG. 7G) GCD curves at a current density of 1 mA/cm2; (FIG. 7H) specific capacitance calculated from GCD curves; (FIG. 7I) Capacity retention under 5000 GCD cycles at a current density of 1 mA/cm2. Ragone plot showing the (FIG. 7J) areal and (FIG. 7K) volumetric energy and power density of the devices.

FIGS. 8-18, and any sub-parts, are illustrations supplementing those of FIGS. 3-7 of Nano 2022, 16, 15-28 cited above and can be found at https://pubs.acs.org/doi/10.1021/acsnano.1c04197, and are, namely:

FIGS. 8A-B. Fluid transport through the laser-induced graphene open microfluidic (LIG-OM). (FIG. 8A) The effect of track width on the fluid transport speed, inset shows the liquid (green fluorophore) was confined in the track. (FIG. 8B) an optical image shows the splitting of fluid (green fluorophore) from the center of the OM and reaching the sensing area. All data represents the average of 3 repetitions. Error bars represent standard deviation.

FIGS. 9A-B. (FIG. 9A) The XPS spectra of C 1s and (FIG. 9B) differentiated C KLL Auger regions.

FIG. 10. The effect of double lasing: the cross-sectional SEM images of laser-induced graphene by double lasing (LIG-DL) created at different double lasing power (1% to 7%). Scale bar 50 μm.

FIGS. 11A-B. The open circuit potential response of the nitrate ion selective electrodes (ISEs) with (FIG. 11A) single lased LIG electrode and (FIG. 11B) double lased LIG to KNO3 solutions within concentration range varying from 10-6 to 10-2 M. All data represents the average of 3 repetitions.

FIG. 12A-B. (FIG. 12A) Limit of detection (LOD) and (FIG. 12B) sensitivity of nitrate-ISE sensors on LIG-DL tested over 2 months. The plotted line represents the overall mean in both plots.

FIG. 13. Calibration plot for the nitrate ISEs to KNO3 solutions within concentration range varying from 10-6 to 10-2 M after 1 year of storage in air. Sensitivity: −60 to −68 mV/dec, limit of detection (LOD): 10-4.9 M. All data represents the average of 3 repetitions. Error bars represent standard deviation.

FIGS. 14A-B. (FIG. 14A) The apparatus used to perform the bending test with three rods with diameters of 5, 10 and 20 mm. (FIG. 14B) Difference in potential (sensitivity) measured after immersing NO3− ISEs in a known KNO3 solution, before and after many cycles for different bending conditions.

FIG. 15. Calibration plot for the pesticide sensor used in river water samples. Sensitivity: 7.1 mA/μM, limit of detection (LOD): 16.9 pM. All data represents the average of 3 repetitions. Error bars represent standard deviation.

FIGS. 16A-B. Galvanostatic charge-discharge (GCD) curves of laser-induced graphene micro supercapacitor (LIG-MSC). (FIG. 16A) Black curves show 3 cells connected in series; blue curves show single cell. (FIG. 16B) Black curves show 3 cells connected in parallel; blue curves show single cell.

FIG. 17. Comparison of CV curves for LIG-MSC-SL and LIG-MSC-DL in organic electrolyte (LiPF6 in in ethylene carbonate, dimethyl carbonate and diethyl carbonate, LiPF6 in EC/DMC/DEC=1:1:1 (v/v/v) 1.0 M) at a scan rate of 50 mV/s.

FIG. 18. High magnification SEM images of LIG with 0% double lasing power (top row) and 7% double lasing power (2nd row).

### 4. DETAILED DESCRIPTION OF EXEMPLARY EMBODIMENTS OF THE INVENTION

### 4.1. Overview

For a better understanding of the invention, examples of ways the invention can be made and used will now be described in detail. These examples are neither inclusive nor exclusive of all the forms and embodiments the invention can take.

### 4.2. Generalized Embodiment

As discussed in Nano 2022, 16, 15-28 and its Supporting Information cited above, at a generalized level an exemplary embodiment according to the invention allows high flexibility in design, fabrication, and functionalization of LIG patterning by control of laser fluence relative the patterning or portions thereof. This allows open air fabrication. This allows tuning of wettability of patterning or portions thereof according to need or desire in a highly scalable fashion, but also in coordination of desired electrical conductivity and/or surface morphology. As such, it solves problems in the art relating to the ability to control all of these parameters for a given application of the LIG patterning.

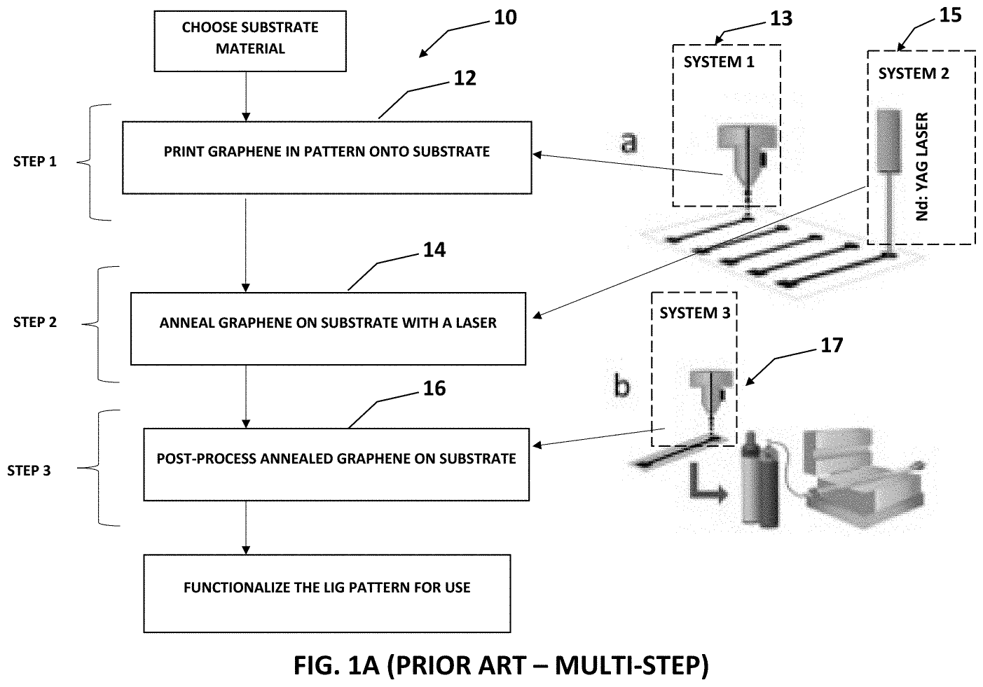

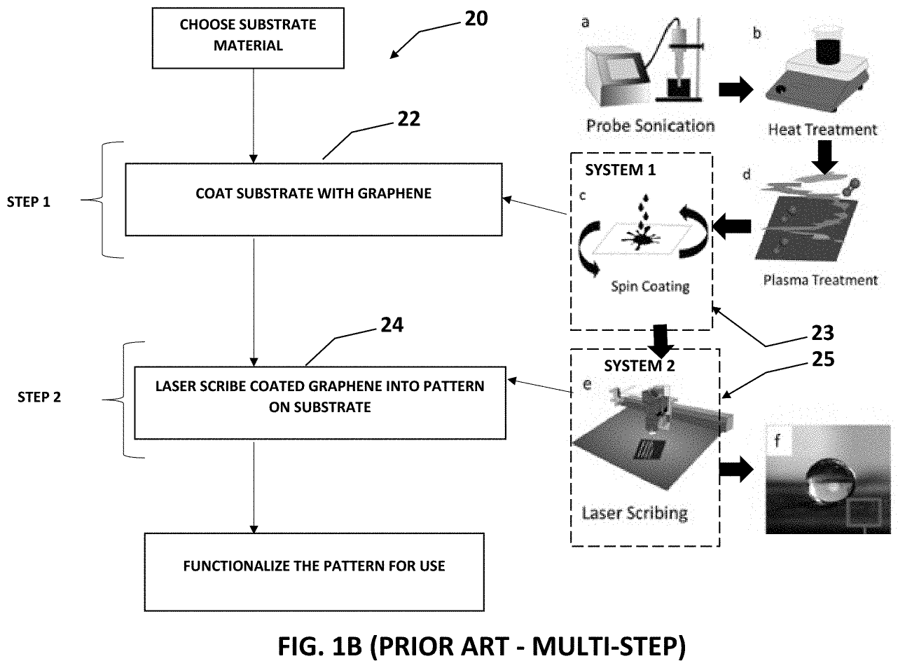

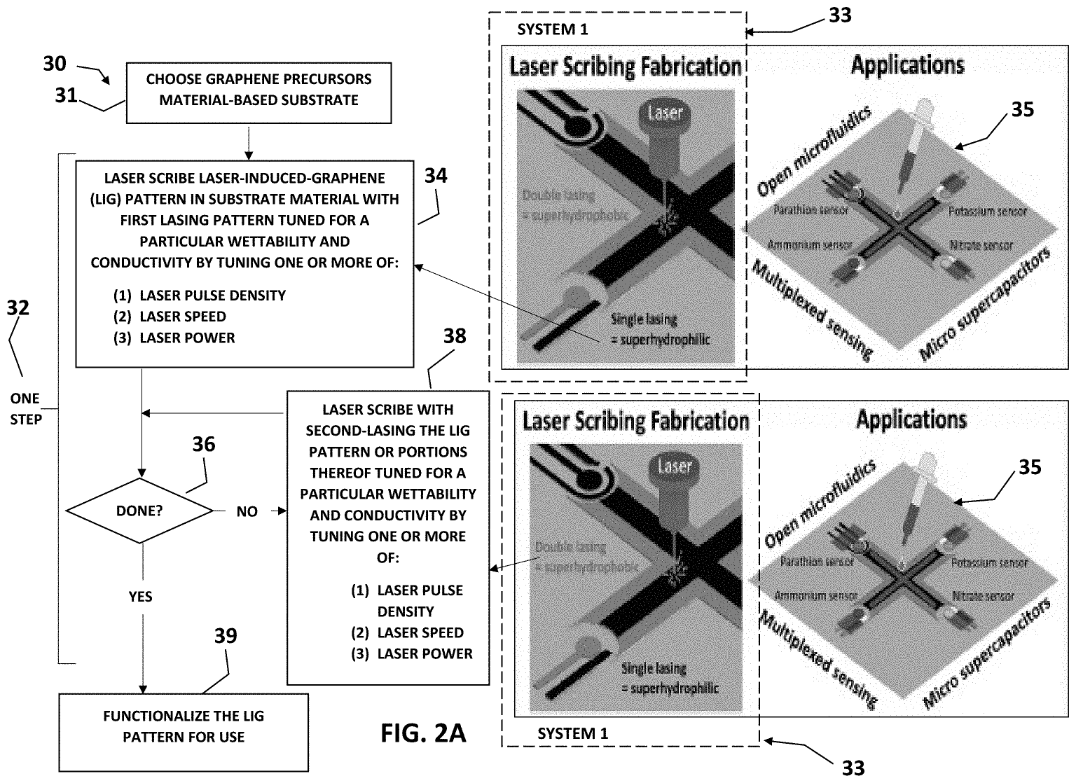

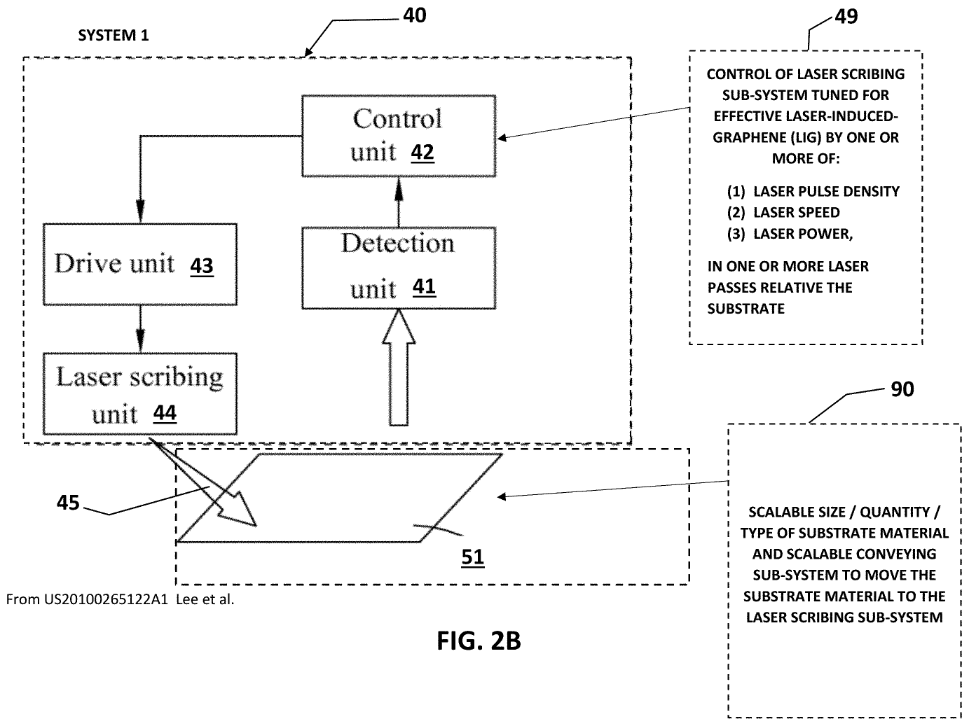

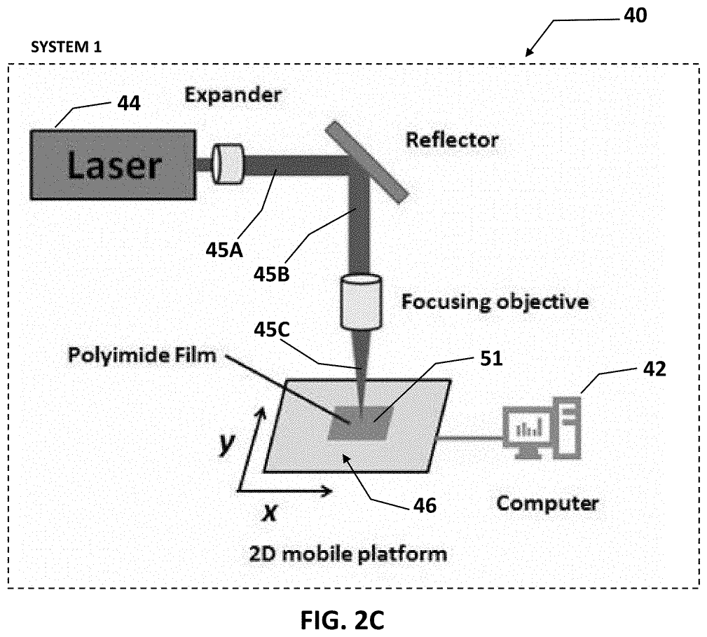

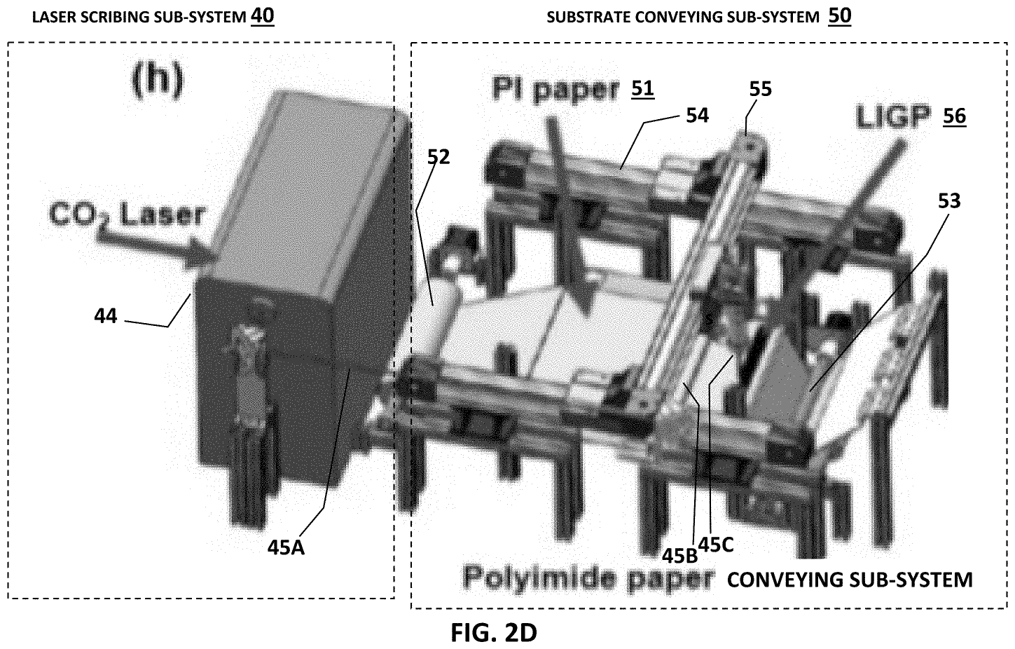

With reference to FIGS. 2A-D, a generalized embodiment 30 according to the invention is illustrated. With comparison to FIGS. 1A and 1B, it can be seen that embodiment 30 features what is called a “one-step” fabrication technique 32 as compared to the multi-step fabrication techniques of FIGS. 1A and 1B. The “one-step” refers to the using a single “system 1” laser scribing subsystem 33 to lase a pre-programmed pattern or patterns on the surface of a substrate that includes a graphene precursor. By this single step, single system 32/33, a variety of LIG patternings can be created for different end applications or uses. This is without other steps such as printing or coating graphene on the substrate, annealing, or other steps with other sub-systems.

A substrate with a graphene precursor is first selected (step 31). One non-limiting example is polyimide. A laser scribing sub-system scans a focused laser over the substrate in a pre-programmed pattern. With control of laser power and fluence, the surface of the substrate is carbonized by generating laser-induced graphene (LIG) from the substrate in the pattern scanned by the laser. Example of other graphene precursor materials for substrates can be found at US20210171351A1, to inventors Tour et al., entitled “Method for printing objects having laser-induced graphene (LIG) and/or laser-induced graphene scrolls (LIGs) materials”, incorporated by reference herein, listing as examples that the graphene precursor material can include a polymer, and the polymer can be selected from a group consisting of polymer films, polymer fibers, polymer monoliths, polymer powders, polymer blocks, optically transparent polymers, homopolymers, vinyl polymers, chain-growth polymers, step-growth polymers, condensation polymers, random polymers, ladder polymers, semi-ladder polymers, block co-polymers, carbonized polymers, aromatic polymers, cyclic polymers, doped polymers, polyimide (PI), polyetherimide (PEI), polyether ether ketone (PEEK), polyamide (PA), polybenzoxazole (PBO), polyaramids, and polymer composites and combinations thereof. Other graphene precursor materials are known, including but not limited to various aromatic polymers, lignin-containing materials, cellulose-based materials, and non-polymeric sources of carbon. As explained in US20210171351A1, the graphene precursor material could be in a variety of sizes and form factors. One example is a roll of flexible graphene precursor material. This would allow high-throughput fabrication by roll-to-roll manufacturing or other techniques that unroll the material and allow a laser scribing subsystem 33 to generate LIG patterns on any portion of the roll whether the roll in stationary or moving relative the laser scriber 33. This is one non-limiting way in which a scalable amount of graphene precursor material can be processed according to aspects of the present invention. Others are, of course, possible and known by those skilled in the art.

Next, the graphene precursor material or substrate is laser scribed to generate LIG patterning(s) on its surface, wherein the laser of the laser scribing subsystem 33 is tuned for a particularly wettability and one or more other material factors (e.g. a desired level or range of electrical conductivity and/or a material robustness) by control of laser parameters such as pulse density or fluence, laser speed and laser power (step 34). As indicated at FIG. 2A, a first lasing at the selected laser parameters can generate an LIG pattern for end use or application. One example is a hydrophilic or superhydrophilic path or trace that could be used for a variety of functions. Several non-limiting examples are an open microfluidic path, an electrical connection or path, or both; or an electrode or part thereof for an electrical sensor, circuit, or device (e.g., capacitor or supercapacitor). See applications at ref no. 35. The selection of graphene precursor material and single sub-system, single step laser scribing tuned to generate LIG of certain characteristics with a single lasing allows efficient, effective, scalable fabrication of a variety of LIG-based patternings. As can be appreciated, the pattern could be continuous or could have two or more separated portions or sections of LIG from the graphene precursor material surface. The width and other characteristics of the pattern can be varied according to the laser beam width and/or by moving the laser beam or the substrate relative to each other to make pattern widths or shapes wider than the laser beam width. And the pattern could be just one or could be many either the same as each other or with one or more differences between some and others. This further allows with one step, one system highly scalable fabrication. The substrate does not have to be moved to another system or be processed by another system.

As shown further in FIG. 2A, one aspect according to this embodiment is that ability for additional lasings of the same substrate with the same laser scribing sub-system. For example, control of the method and system 30 could be programmed to conduct a first lasing 34 with selected laser parameters tuned for a desired LIG pattern, and then check if any subsequent lasings of any part of the substrate, including any portion or portions of the first lasing LIG pattern, is desired (step 36).

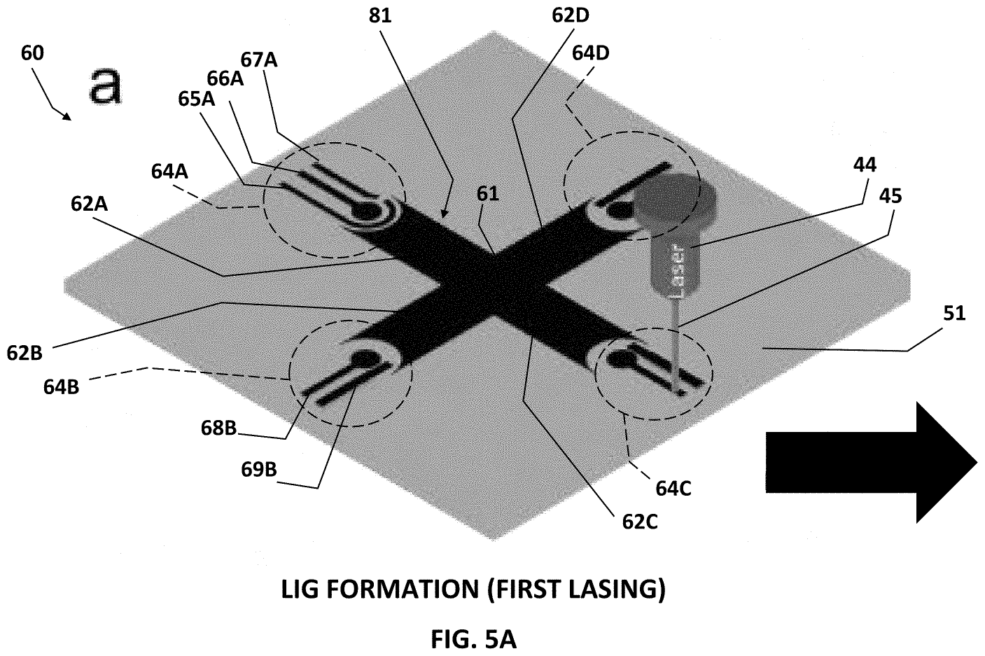

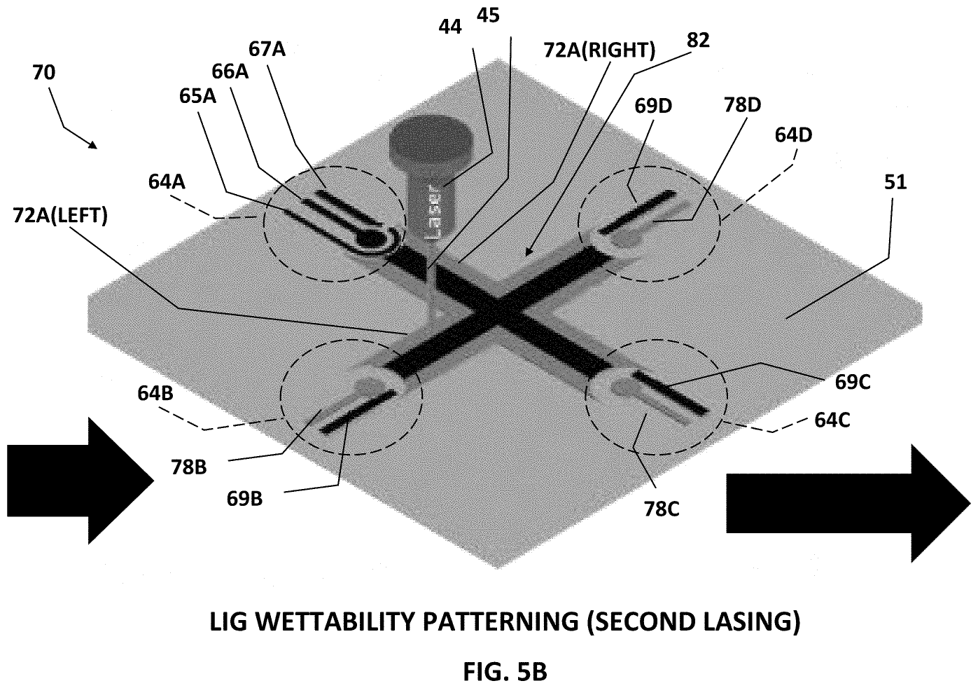

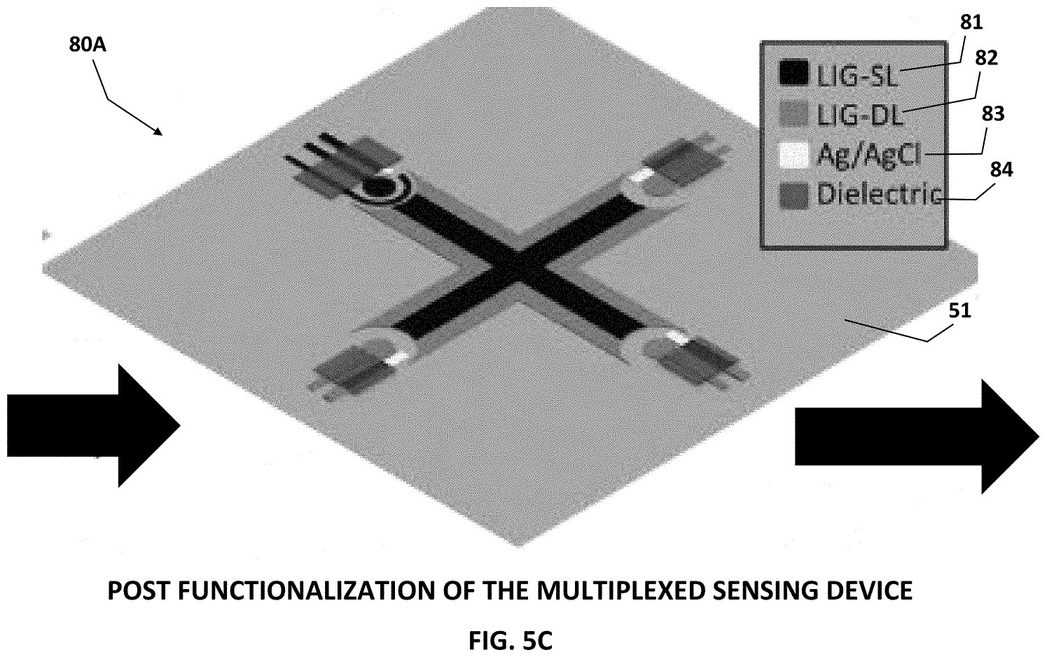

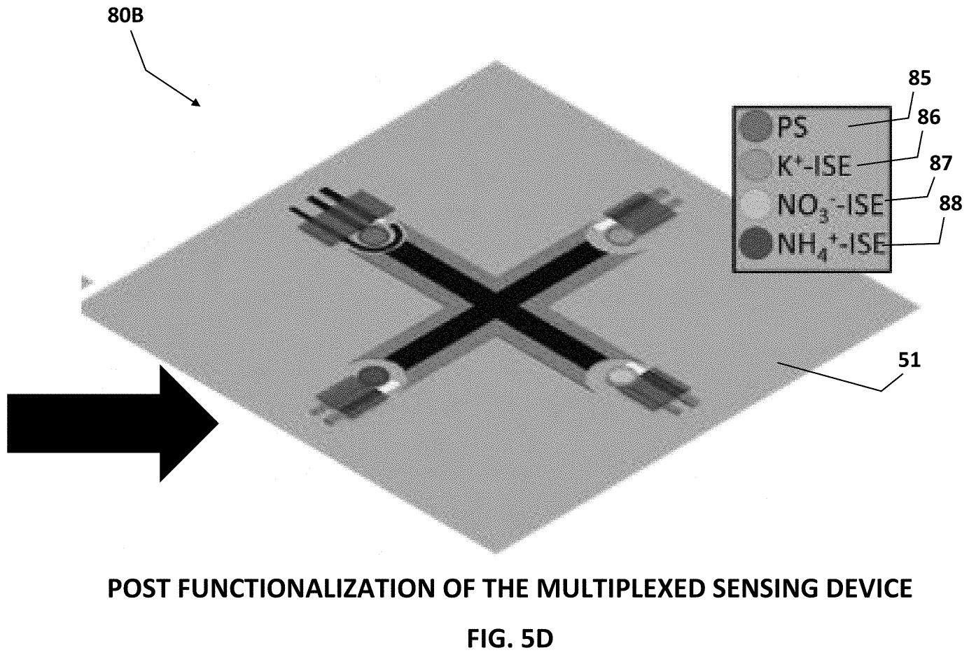

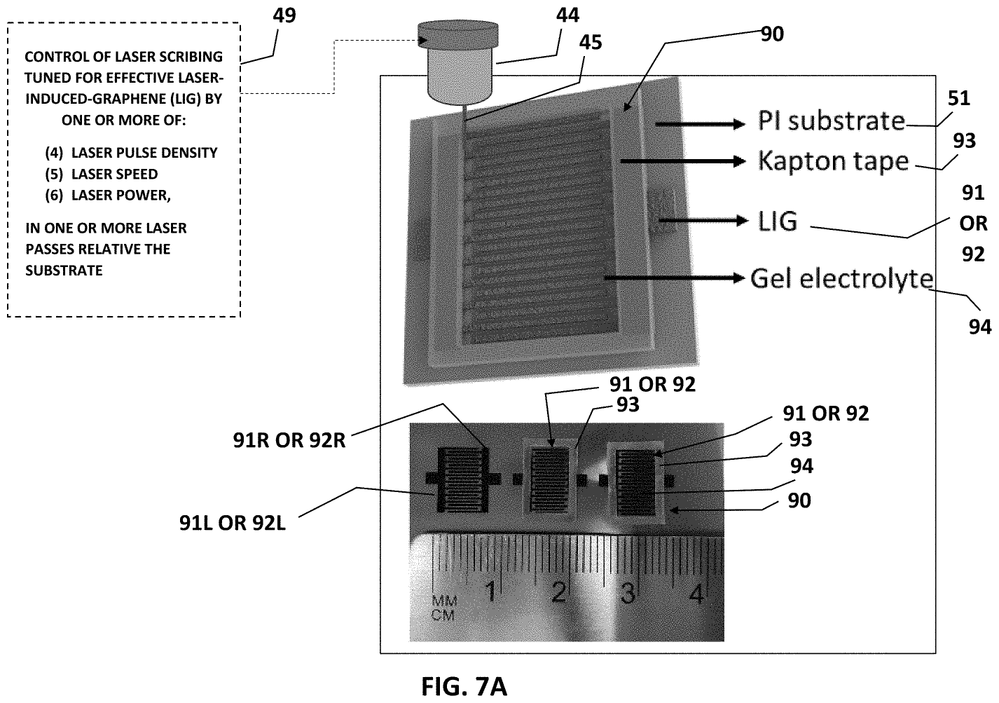

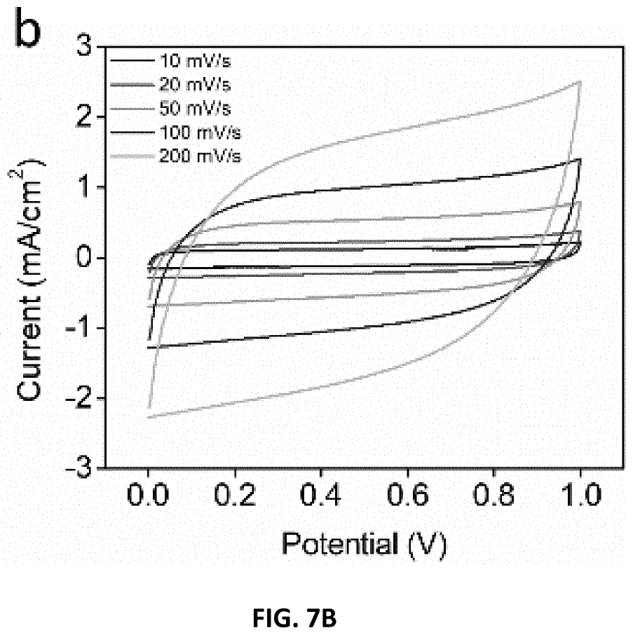

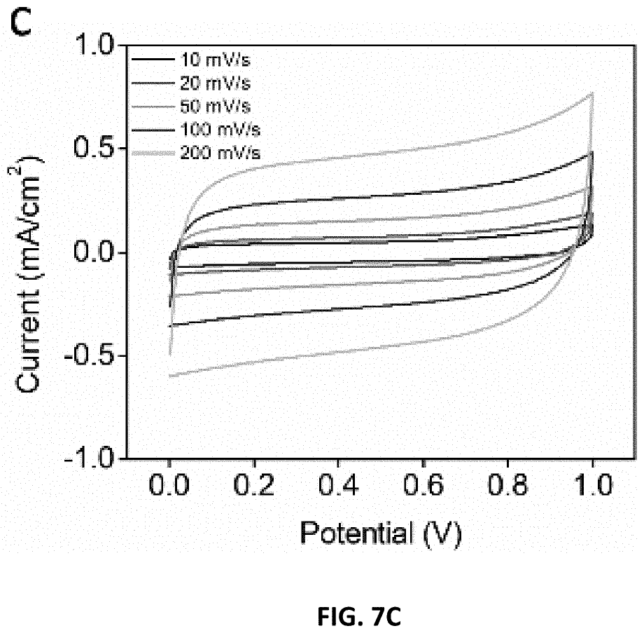

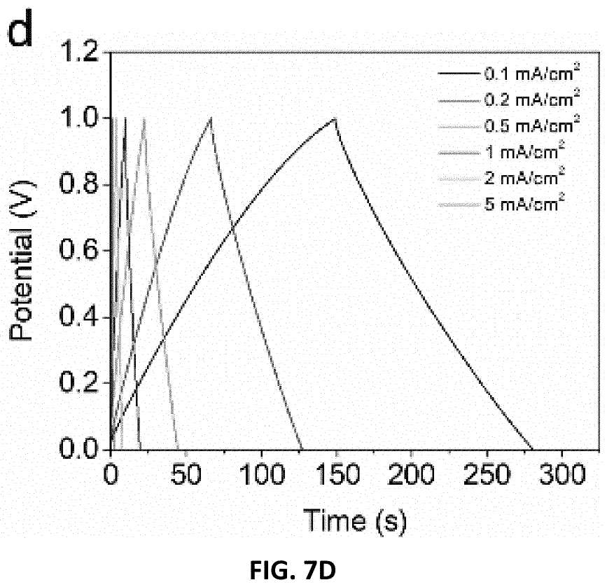

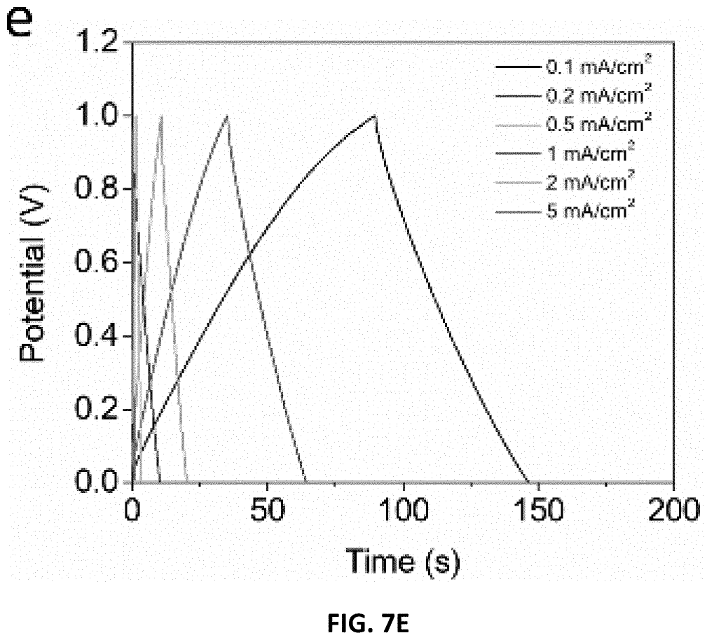

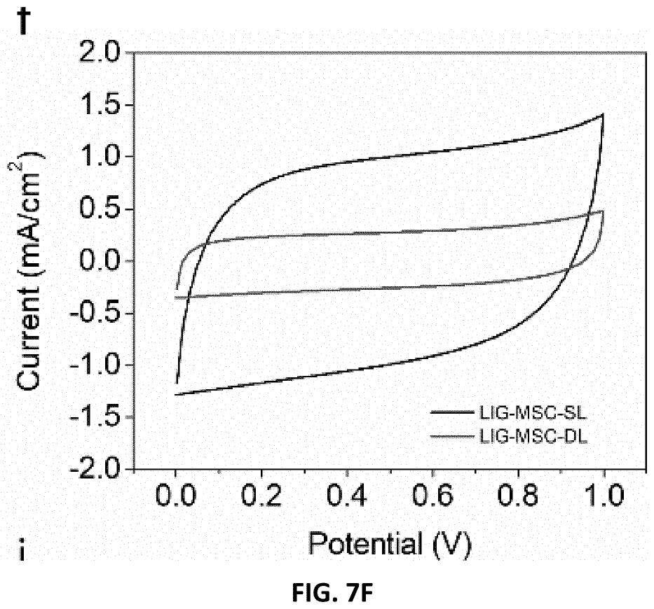

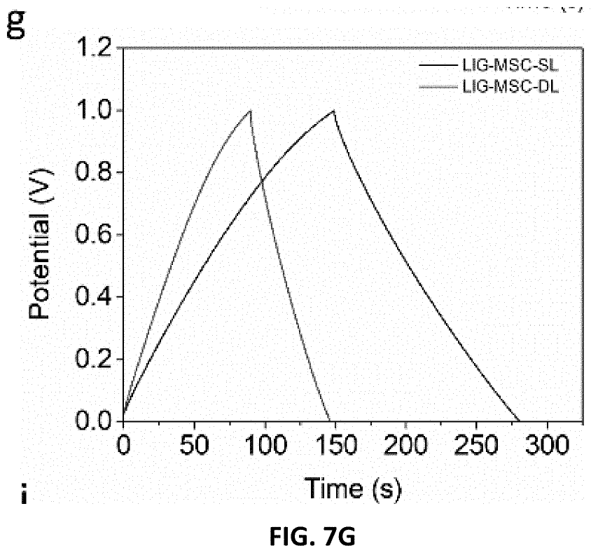

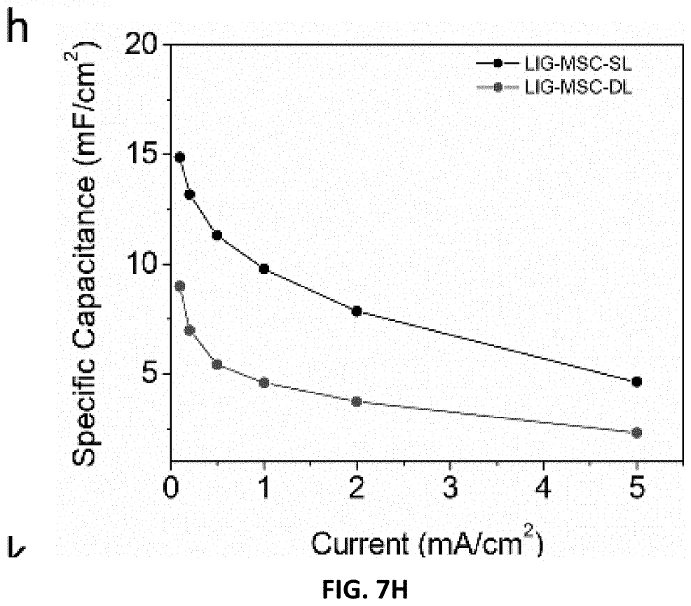

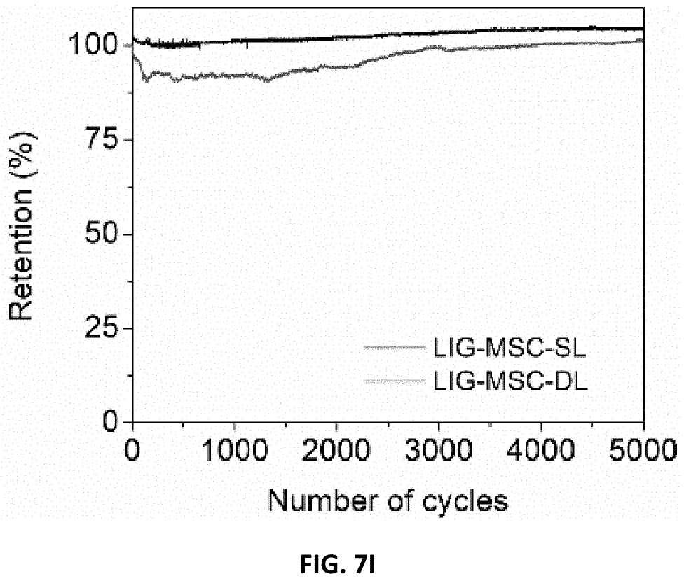

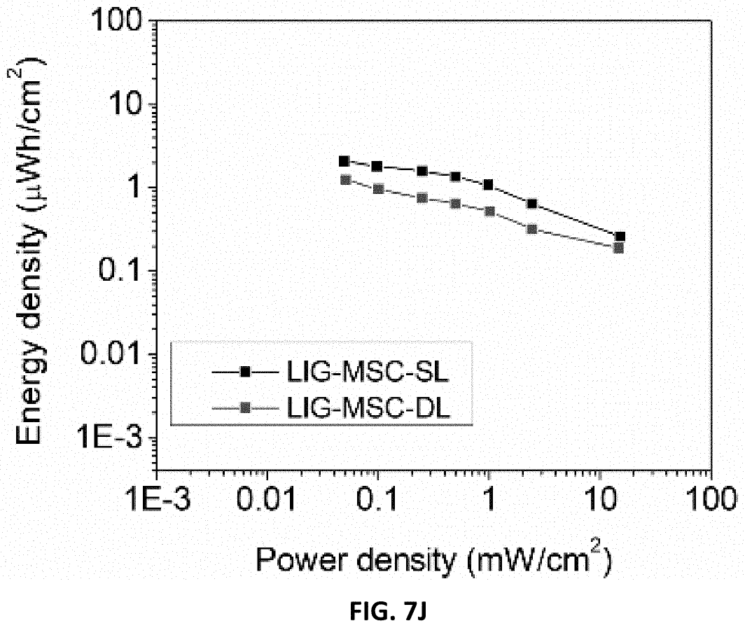

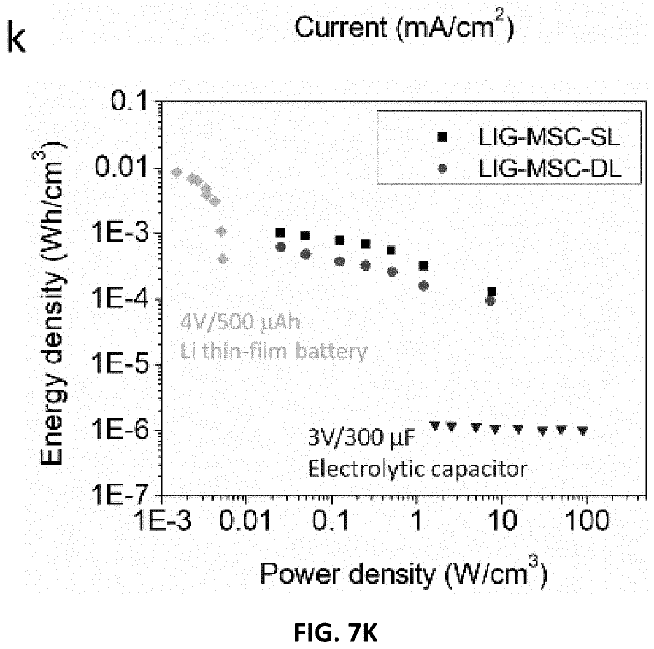

If not, the method 30 proceeds to functionalization of the first lasing LIG pattern (step 39). An example of functionalization would be to add a dielectric (e.g., ref. no. 84 in FIG. 5C) or electrolyte (e.g., ref. no. 94 in FIG. 7A) over portions or all of the first LIG lasing such as to functionalize the LIG lasing as an electrode-based sensor or as a supercapacitor, as will be discussed in specific examples below. These are non-limiting examples.

If an additional lasing is desired, the laser scribing sub-system can be programmed to direct the laser in a second pattern or to specific locations on the substrate (step 38) after a preceding lasing. Again, the laser parameters can be tuned according to need or desire. As will be explained below, non-limiting examples of second lasings include over the side walls or margins of a first hydrophilic or superhydrophilic LIG path to convert the first LIG lasing to hydrophobic or superhydrophobic sidewalls to create an open microfluidic path that influences fluid to move along the remaining exposed hydrophilic or superhydrophilic LIG path with the second lasing creating hydrophobic or superhydrophobic sidewalls to retain and help that fluid transport along the exposed hydrophilic or superhydrophilic LIG path. Another example is to create the shape of an electrode or portion thereof with a first LIG lasing, but then modify it or a portion of it with a second lasing (e.g., changing it from hydrophilic or superhydrophilic to hydrophobic or superhydrophobic). The single or multi-lasing patterning(s), when completed, can then be appropriately functionalized (step 39).

Of will be appreciated, these are non-limiting examples of single lasing patterning and double-lasing patterning. Other end uses or applications are of course possible. And the number of lasings can be one, two, or more, depending on need or desire. As shown in FIG. 2A, method 30 provides scalability of fabrication as well as fine-tuning of the LIG characteristics with the same single-step, single system LIG patterning sub-system. Non-limiting examples of fine-tuning with subsequent lazing passes include changing portions of hydrophilic or superhydrophilic first lasing LIG to hydrophobic or superhydrophobic LIG and/or maintaining or changing conductivity, and/or maintaining or changing mechanical robustness. In one specific example, the ability to tune wettability of portions of LIG while at the same time tuning conductivity provides a technical solution to generating LIG with tunable structure, conductivity, and/or wettability for such things as open microfluidics for electrochemical sensing and energy harvesting or storage with single step, single subsystem patterning(s) as opposed to multistep, multisystem techniques.

FIGS. 2B-D illustrate examples of how to make and use method 30 according to a generalized embodiment of the invention. Variations obvious to those skilled in the art are, of course, possible.

A system 40 to carry out method 30 of FIG. 2A can include a detection unit 41 to sense presence and position of a graphene precursor material 51, as well as operating parameters of a laser scribing unit 44 that is operatively configured to generate and direct a laser beam 45 to the material 51. A control unit 42 and drive unit 43 can either be separate or a part of laser scribing unit 44. Control unit 42 can be programmed, as is well-known to those skilled in the art, to control/drive laser beam 45 of laser scribing unit 44 relative to a surface of material 51 in at least the 2D plane of material 51. This can be by movement of beam 45 relative material 51, movement of material 51 relative beam 45, or both so that beam 45 can intersect and generate LIG at any location across material 51. Detection unit 41 could also include components and sensors to provide feedback to control unit 42 regarding processing parameters during lasing of material 51 by laser scribing unit 44. Non-limiting examples could include detecting location of material 51 relative laser beam 45, laser speed, fluence, or power, and other parameters. Many commercially-available systems 40 have such detection functions.

FIG. 2B shows diagrammatically that control unit 44 can at least by programmed to control (see ref. no. 49) during each lasing laser pulse density or fluence, laser speed, and laser power correlated with the position of laser beam 45 on material 51. As such, scalability and efficiency of fabrication of one or many LIG patterns on material 51 is possible by changing the programming of control unit 42 for different LIG patterning(s) at tuned laser parameters. This, again, allows the technological solution of using a one-step, one system (laser scribing) in one or multiple lasings relative the same material 51 to control one or more LIG characteristics. This can be in ambient or open air environments, and avoids need of other steps and systems, which can make scalability difficult or even impossible.

FIG. 2B also diagrammatically shows (see ref. no. 90) that system 40 can include a variety of techniques or sub-systems to handle and convey graphene precursor material 51 to the laser scribing unit 44. This includes relatively small, discrete pieces of material 51 or larger (or much larger) pieces, rolls, sheets, panels, or sections of material 51. This, again, contributes to scalability of system 40. It can work for individual pieces of material 51 over a range of sizes from small (millimeter scale or less length and width) to large (meter scale or more length and width). Obtaining commercially any of such scales of material 51, as well as sub-systems to convey it to a laser scribing unit 44, are commercially available and well known to those skilled in the art. Examples include XY positioners or tables for individual planar pieces of material 51 and such things as roll-to-roll processing for flexible material 51 or material handling used in microelectromechanical systems (MEMS).

FIG. 2C is a diagrammatic illustration of the basic LIG process such as used in method 40. A suitable laser 44 generates a laser beam 45 that has a first portion 45A typically directed through optical components, is redirected in another portion 45B to a focusing objection lens, which then produces an adjustably focused portion 45C at material 51. Control unit 42 (e.g. a computer or computer controller) can control movement of material 51 relative to focused beam portion 45C (e.g. by an X-Y positioner or other adjustable platform) to allow almost unlimited options in how laser portion 45C can be scanned over a surface of material 51 to create almost any LIG patterned shape, whether the pattern is a continuous shape or in individual segments or portions, and whether the LIG is processed by a single lasing or multiple lasings, and whether just one pattern is created on material 51 or many patterns whether or not all are the same or whether at least some differ.

FIG. 2D is an illustration of one non-limiting technique of supplying a large quantity of flexible material 51 to a laser scribing sub-system 40 (with a laser scribing unit 44 for LIG patterning) by a substrate conveying sub-system 50. Such conveying systems 50 are commercially available and can, themselves, be scaled relative to how large of rolls of flexible material 51 they can handle. As shown, a roll of material 51 has a portion unrolled between rotatably journalled roll first end 52 and second roll end 53 along a conveying sub-system frame 54 to present one side of material 51 in a flattened plane. An actuator can rotate at least one of the roll ends 52 and 53 to move material 51 along frame 54. In this example, an X-Y positioner 55 has two controllable carriages, one that allows longitudinal movement along frame 54 between roll ends 52 and 53, and a second carriage that is both carried on the first carriage and can move laterally on the first carriage between opposite lateral sides of frame 54. As shown in FIG. 2D, a 90 degree mirror or optic on the first carriage is aligned with laser beam portion 45A generated in laser scribing unit 44 regardless of the position of the first carriage along frame 54, and redirects the laser beam portion 45A in a second beam portion 45B to another 90 degree mirror or optic on the second carriage, which directs beam portion 45B in a focused beam portion 45C downward to the surface of material 51. As such, computer control of the X-Y positioner and the roll of material 51 between roll ends 52 and 53 allows programmed movement of laser beam portion 45C relative the facing surface of material 51 for at least most of the roll of material 51. LIG patternings 56 can be generated in almost any shape and then rolled up for storage. By well-known MEMs processing, the LIG patterned roll can then by unrolled for functionalization or dicing up of individual patterns. As is well known to those skilled in the art, a variety of other commercially-available sub-systems 50 are available to convey or translate pieces, rolls, sheets, plates, etc. of material 51 relative to a laser scribing beam. FIG. 2D is but one example to illustrate one non-limiting way to present a relatively large scalable roll of flexible graphene precursor material 51 to a computer-controlled laser scriber.

As further discussed in Nano 2022, 16, 15-28 and its Supporting Information cited above, an embodiment like described above can be tailored for specific end uses or applications. This allows specific non-limiting applications such as open surface microfluidics, electrodes of different types, and other patterning or circuits taking advantage of characteristics of graphene but with tunable wettability. In one specific example embodiment, the LIG patterning is entirely generated by a first lasing at a first laser fluence and speed that is pre-selected to produce desired LIG wettability, morphology, and conductivity for a given application. One example is a micro supercapacitor. The wettability of the interdigitated electrodes of the micro super capacitor can be selected to be at least hydrophobic (and up to near or at super hydrophobic) or at least hydrophilic (or up to near or at super hydrophilic), depending on how the LIG patterning are functionalized into a micro super capacitor.

Another example is an electrochemical sensor. The LIG patterning are created to provide not only fluid transport of an analyte via open surface microfluidics, but also at least one electrode-based sensor along or at a termination point of the open surface microfluidics. A first lasing can generate the general LIG patterning. A second lasing over selected portion(s) of the first lasing, can change the LIG parameters including wettability. One example is to create a hydrophilic open surface track with the first lasing and improve fluid transport along the track by creating hydrophobic sidewalls along the track with a second lasing.

Still further, another embodiment illustrates how the LIG patterning can facilitate flow division of open surface microfluidics so that a single analyte sample can be directed to plural sensors. The sensors can be of different types by virtue of the tuning of LIG parameters with control of laser fluence at each sensor and/or how the electrode-based sensors are functionalized.

Thus, this generalized embodiment achieves at least one or more of the objects, features, advantages, or aspects of the invention as described herein.

It will be appreciated by those skilled in the art that the invention can be implemented in a variety of forms and embodiments. For example, the LIG patterning and the first and any second lasing can be of a wide variety of form factors. They can be generated by computer-assisted-drawings (CAD) that inform components that move the laser or the substrate relative the laser according to the CAD plan. This can be highly accurate and scalable with high resolution, including down to microfluidic (e.g., in the micron resolution range or smaller scale). Those skilled in the art will appreciate such variations, options, and alternatives in the context of the accompanying descriptions and the incorporated by reference sources herein.

For example, certain of the references cited herein discuss such options, variations, and alternatives to some but not all the steps of the methods according to the present invention. The following specific embodiments provide specific non-limiting examples of how the invention can be made and used.

### 4.3. Specific Embodiments

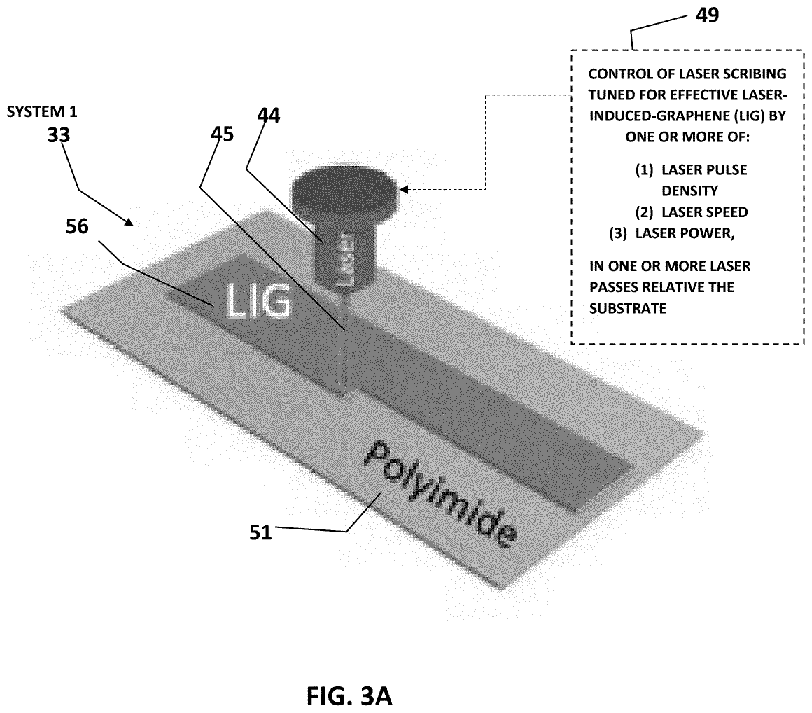

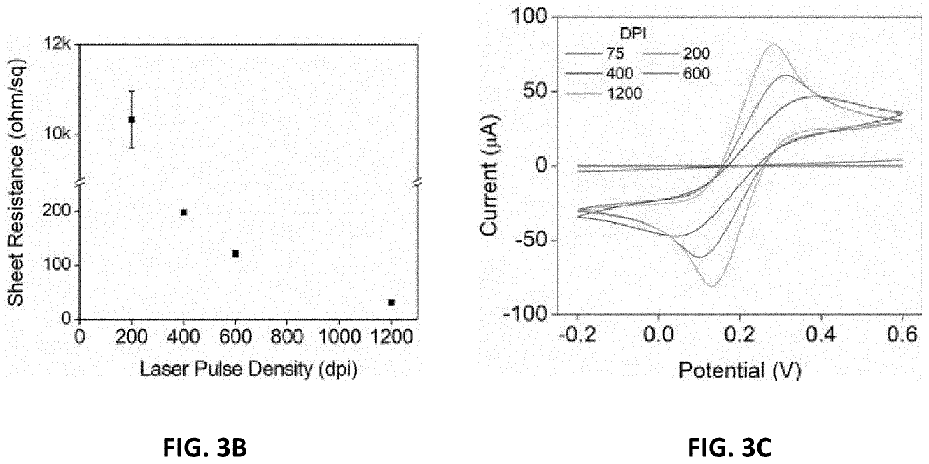

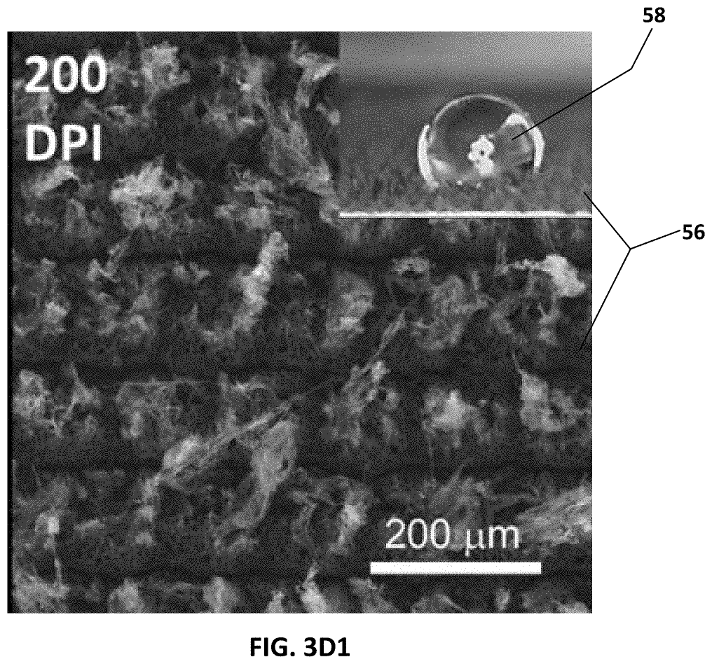

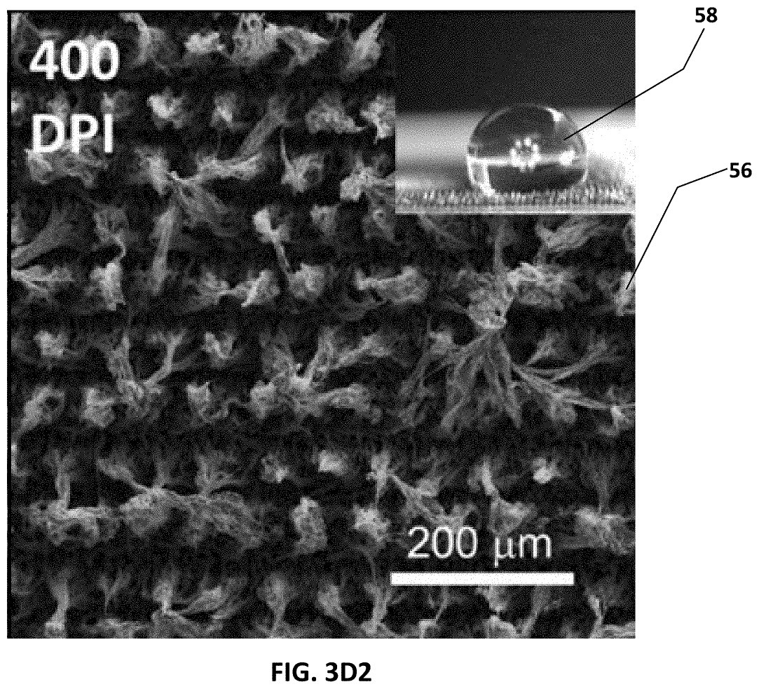

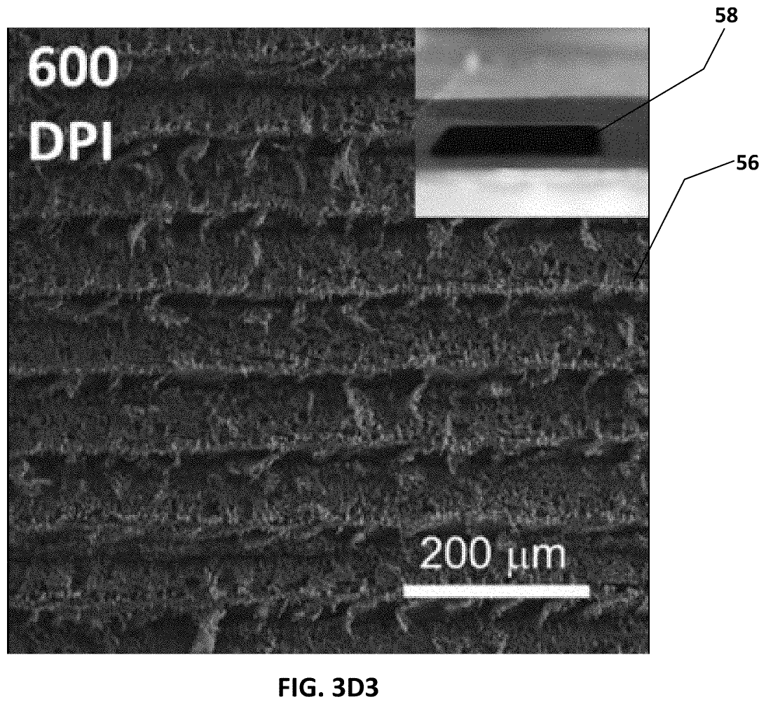

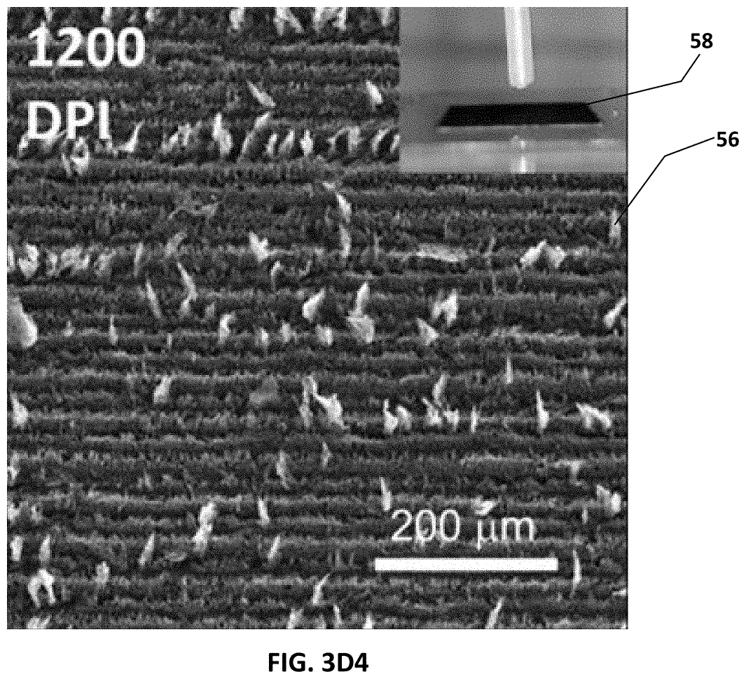

With particular reference to Nano 2022, 16, 15-28 and its Supporting Information cited above, and their FIGS. 3-7 (and subparts) and 8-18 (and subparts), specific exemplary embodiments according to one or more aspects of the invention are set forth in detail. Nano 2022, 16, 15-28 and its Supporting Information cited above are both incorporated by reference into this description in their entireties. Citations in the descriptions herein indicated by superscripts are to the bibliography included later.

As will be appreciated by those skilled in the art, the examples of Nano 2022, 16, 15-28 and its Supporting Information cited above are non-limiting ways to make and use the invention. Aspects of the invention can be applied in analogous ways to other end uses. Non-limiting examples include the LIG patternings of:
Kucherenko, I. S.; Sanborn, D.; Chen, B.; Garland, N.; Serhan, M.; Forzani, E.; Gomes, C.; Claussen, J. C. Ion-Selective Sensors Based on Laser-Induced Graphene for Evaluating Human Hydration Levels Using Urine Samples. Adv. Mater. Technol. 2020, 5 (6), 1901037. https://doi.org/10.1002/admt.201901037;
Garland, N. T.; McLamore, E. S.; Cavallaro, N. D.; Mendivelso-Perez, D.; Smith, E. A.; Jing, D.; Claussen, J. C. Flexible Laser-Induced Graphene for Nitrogen Sensing in Soil. ACS Appl. Mater. Interfaces 2018, 10 (45), 39124-39133. https://doi.org/10.1021/acsami.8b10991;
Zachary T. Johnson, Kelli Williams, Bolin Chen, Robert Sheets, Nathan Jared, Jingzhe Li, Emily A. Smith, and Jonathan C. Claussen. Electrochemical Sensing of Neonicotinoids Using Laser-Induced Graphene. ACS Sens. 2021, 6, 3063-3071;
Raquel R. A. Soares, Robert G. Hjort, Cicero C. Pola, Kshama Parate, Efraim L. Reis, Nilda F. F. Soares, Eric S. McLamore, Jonathan C. Claussen, and Carmen L. Gomes. Laser-Induced Graphene Electrochemical Immunosensors for Rapid and Label-Free Monitoring of Salmonella enterica in Chicken Broth, ACS Sens. 2020, 5, 1900-1911.

Others are, of course, possible, in that one or multiple lasings according to aspects of the invention can be used in tuning the properties or characteristics of the LIG patterning, or portions thereof, used in those end uses or functionalizations.

The integration of microfluidics and electrochemical cells is at the forefront of emerging sensors and energy systems; however, a fabrication scheme that can create both the microfluidics and electrochemical cells in a scalable fashion is still lacking. We present a one-step, mask-free process to create, pattern, and tune laser-induced graphene (LIG) with a ubiquitous CO₂ laser. The laser parameters are adjusted to create LIG with different electrical conductivity, surface morphology, and surface wettability without the need for postchemical modification. Such definitive control over material properties enables the creation of LIG-based integrated open microfluidics and electrochemical sensors that are capable of dividing a single water sample along four multifurcating paths to three ion selective electrodes (ISEs) for potassium (K⁺), nitrate (NO₃⁻), and ammonium (NH₄⁺) monitoring and to an enzymatic pesticide sensor for organophosphate pesticide (parathion) monitoring. The ISEs displayed near-Nernstian sensitivities and low limits of detection (LODs) (10-5.01 M, 10-5.07 M, and 10-4.89 M for the K⁺, NO₃⁻, and NH₄⁺ ISEs, respectively) while the pesticide sensor exhibited the lowest LOD (15.4 pM) for an electrochemical parathion sensor to date. LIG was also specifically patterned and tuned to create a high-performance electrochemical micro supercapacitor (MSC) capable of improving the power density by 2 orders of magnitude compared to a Li-based thin-film battery and the energy density by 3 orders of magnitude compared to a commercial electrolytic capacitor. Hence, this tunable fabrication approach to LIG is expected to enable a wide range of real-time, point-of-use health and environmental sensors as well as energy storage/harvesting modules.

Pumpless paper microfluidics have emerged as one of the most prominent tools to provide inexpensive and effective fluid transport for in-field or point-of-care sensors including those associated with disease diagnostics,¹⁻⁵ environmental monitoring,^{6,7} food safety,⁸ and water testing.⁹ However, paper microfluidics are hindered by issues of biofouling and premature saturation which can significantly impede the sensitivity, detection limit, and accuracy of sensors as less than 50% of the total sample volume within the paper microfluidic typically reaches the detection zone.^{10,11} A promising alternative to paper microfluidics is the recent development of pumpless on-surface fluid transport technologies known as open microfluidics.

Open microfluidics or open-surface microfluidics permit fluid transport across a surface not confined by four channel walls and without the need for absorption through a matrix such as cellulose.^{12,13} Researchers have developed sophisticated techniques to manipulate single droplets of samples and reagents through the application of electrical fields (i.e., digital microfluidics) or magnetic fields (i.e., magnetic digital microfluidics) with open-surface microfluidics.¹⁴⁻¹⁷ These techniques permit exquisite control over chemical reactions and biological analysis; however, they also require application of power and/or presample preparation with magnetic particles, which significantly increase operational complexity. What is needed for the majority of in-field biosensors is simply two main capabilities: (1) fluid transport to a detection zone to enable assay operation (e.g., lateral flow assays used in pregnancy, allergen, and pathogen detection kits)^{18,19} and (2) flow division to enable monitoring of multiple analytes from a single test sample or multiplexed sensing (e.g., metabolic biomarker monitoring in urine,²⁰ pathogen monitoring in food samples).²¹ Moreover, realizing these two sensor capabilities on a low-cost scalable platform will ensure its widescale implementation especially where cost margins are extremely low and price transmission is asymmetric in a vertical market such as in the food industry²² and where large data mapping is needed such as with monitoring fertilizer or pesticide runoff from farm fields to watersheds.^{23,24}

Researchers have begun to address the challenge of creating low-cost, pumpless open microfluidics capable of both unidirectional fluid flow and flow that is capable of dividing along multifurcating paths.^{25,26} One of the more promising avenues of research in this field is the development of technologies capable of capillary-force driven fluid transport using spatial gradients of defined surface wettability.^{27,28} Such microfluidics are generally created by developing narrowing, wedge-shaped hydrophilic tracks surrounded by superhydrophobic walls that permit movement of fluid along the tracks by net Laplace pressure.^{29,30} These open microfluidics eliminate the need for fluid to percolate through a porous matrix as is the case with paper microfluidics, and hence significantly reduces or completely eliminates channel saturation and biofouling. Moreover, the superhydrophobic sidewalls are inherently antifouling and therefore further reduce biomolecule adsorption on the channels, which can reduce the target analyte from reaching the detection zone of the biosensor.^{31,32} However, creating open microfluidics by tuning the wettability of surfaces typically requires complex and costly fabrication techniques including postchemical treatments, such as wax printing,^{2,33} photolithography with UV masks,^{28,34,35} chemical modification (self-assembly monolayer chemistry), deep reactive ion etching,^{36,37} or brush painting of a “fluorine” containing layer.³⁸⁻⁴⁰

The 2D carbon material known as graphene holds tremendous promise in creating low-cost, scalable open microfluidics in addition to myriad electronic applications owing to its advantageous material properties such as extremely high in-plane electrical and thermal conductivity, high specific surface area, and rich surface chemistry. Conventional methods to produce graphene including chemical vapor deposition are expensive and low-yielding processes as they require high temperatures (upward of 1000° C.), vacuum chambers, and/or cleanroom processing such as metal vapor deposition of precursor metals.^{41,42} However, recent methods to inkjet, aerosol, or screen print graphene flakes obtained from chemical exfoliation of bulk graphite offer a low-cost, scalable process to produce graphene circuits that exhibit a high degree of electrical conductivity (<100 Ωsq⁻¹), albeit lower than conventional graphene fabrication methods, that are useful for a variety of electronic devices.⁴³⁻⁴⁶ However, these graphene fabrication methods require postprint annealing techniques such as high temperature thermal annealing (˜200-400° C.),⁴⁷⁻⁴⁹ photonic annealing,⁵⁰ and laser annealing^{51,52} to carbonize ink binders such as ethyl or nitrocellulose, evaporate ink solvents, and reduce residual graphene oxide. Such multistep (i.e., print and then anneal) fabrication adds to the complexity and cost of the manufacturing process. Moreover, transforming the surface wettability of graphene to hydrophobic or near super-hydrophobic often requires post-treatment (spray coating, brush painting, dip coating) of a fluorine containing layer or patterning with a rapid-pulse laser⁵³ to achieve the desired wettability, which as a result adds to the complexity of the fabrication process.

Recently, more scalable techniques to create printed graphene open microfluidics that are capable of fluid transport and fluid division have been explored.⁵⁴ This research on graphene open microfluidics demonstrated unidirectional fluid transport and fluid division within a cross and tree pattern via superhydrophilic/superhydrophobic wettability patterning.⁵⁴ Indeed, this work represents a promising step forward in developing low-cost, scalable open microfluidics capable of overcoming the aforementioned hurdles associated with paper microfluidics. However, the manufacturing of these open microfluidics requires a two-step process, spin-coating graphene ink films followed by superhydrophobic patterning by scribing micron-sized grooves into the graphene with a CO₂ laser, and it remains unclear if graphene-based biosensors could be directly incorporated into these patterns.

Herein, we report a one-step, graphene-based fabrication technique that is capable of creating open microfluidics and the electrode components needed for electrochemical biosensing and energy storage modules all through a scalable CO₂ laser scribing technique. More specifically, this manuscript demonstrates how a laser scribing process can be used to convert polyimide into electrically conductive, hydrophilic graphene (i.e., laser-induced graphene (LIG)) that is used for the open microfluidic fluid tracks and the circuits for subsequent electrochemical sensing. Next, a lower power double lasing process is introduced that can transform the surface wettability of the graphene to one that is near superhydrophobic and consequently is used to create the sidewalls to complete the open microfluidics. These fabrication techniques are then implemented to create an all LIG open microfluidic cross pattern that is capable of dividing a single fluid sample into four branches to four distinct, independently electrically addressable LIG biosensors. The fabricated hydrophobic/hydrophilic structure of the patterned LIG prevents uncontrolled fluid spreading and enables appropriate electrode functionalization based on application. The hydrophobic electrodes are then distinctly functionalized with ion-selective membranes for potassium (K⁺), nitrate (NO₃⁻), and ammonium (NH₄⁺) fertilizer ion sensing and hydrophilic electrodes with an enzyme for organophosphate pesticide sensing. Such a multiplexed biosensor system demonstrates how a single river water sample can be used to monitor fertilizer and pesticide runoff from point-of-use sites such as farm fields, golf courses, and lawns into watersheds, which consequently presents a significant environmental challenge around the world by contaminating aquatic communities⁵⁵ and drinking water supplies⁵⁶ while causing harm and destruction to beneficial insects and mammals.⁵⁷ Finally, the improved energy density of the developed micro supercapacitors is demonstrated through the creation of LIG-based interdigitated electrodes with distinct surface wettability. This controlled tuning of the LIG wettability improves the electrode-electrolyte interface, which is important for a wide range of energy applications such as batteries, water splitting catalysts, and solar water desalination systems.

Results and Discussion

Fabrication and Characterization of Laser-Induced Graphene (LIG). A CO₂ laser 44 was used to convert polyimide substrate 51 to laser-induced graphene (LIG) 56, and the resultant sheet resistance of graphene was measured as the density per inch (DPI) of the laser beam 45 of laser 44 of system 33 was adjusted (200, 400, 600, and 1200 DPI) (FIGS. 3A and 3B). FIG. 3B shows the sheet resistance of LIG created with a single lasing (LIG-SL) as a function of laser pulse density with speed and power fixed (15% speed; 7% power). The sheet resistance decreased greatly from over 10 kΩsq⁻¹ to less than 100 Ωsq⁻¹ with increased laser pulse density. This was attributed to the overlapped lasing at high DPI as we reported previously.⁵⁸ The electrochemical reactivity of the LIG 56, as monitored via cyclic voltammetry with the ferricyanide/ferrocyanide redox probe, continued to increase as the DPI increased and the peak-to-peak potential separation continued to decrease from 331 mV to 149 mV (FIG. 3C), demonstrating effective electron transfer kinetics. Next, scanning electron micrographs (SEMs) and water contact angle measurements demonstrated how variance in the DPI influenced the surface morphology and wettability of the LIG 56 (FIGS. 3D1-4—see standing water 58 in insets). The laser trace reduces with increased DPI and results in more uniform morphology with less height difference. The continuous sheetlike LIG was formed at higher DPI (600 and 1200 DPI) in contrast of isolated fiberlike LIG formed at low DPI (less than 600 DPI). The height of LIG was also decreased from 1 mm (200 DPI) to 25 μm (1200 DPI). It should be noted here that this height is the height of the LIG pattern 56 from the top of the graphene structures to the base of the graphene surface. The water contact angles are also reduced from 1270 (hydrophobic) to 0° (superhydrophilic). Such superhydrophilicity was attributed to lasing in ambient conditions where atmospheric oxygen can more readily oxidize the edge of the LIG with increasing DPI/laser energy.^{59,60}

It should be noted that a number of different techniques have been developed to create hydrophobic LIG including lasing in an inert gas chamber⁵⁹ and chemical modification of the LIG surface by forming a PDMS composite.⁶⁰ However, these methods typically require a controlled inert gas environment or the use of various chemical processes which are difficult to scale. Recently, Sodano's group reported wettability patterning of LIG by tuning the pulse density of the laser with no chemical modification.⁶¹ However, hydro-phobic LIG produced by low DPI typically suffered from high electrical resistance (300-3000 Ωsq⁻¹), sluggish electro-chemical redox behavior (FIGS. 3B and 3C), and a fragile surface due to the insufficient temperature required for LIG to undergo a fiber to sheet shape conversion.⁶² Hence, controlled wettability tuning of graphene with high electrical conductivity and mechanical robustness is desired for many applications including the biosensors and energy storage modules presented herein. See laser fluence control at ref. no. 49.

Here, we present a straightforward in situ second lasing method to create near superhydrophobic graphene. This method allows the formation of the highly conductive (15-30 Ωsq⁻¹) LIG base layer, followed by another lasing pass at lower fluence to alter the morphology of the LIG facial layer to achieve the desired electrical conductivity and surface wettability. The second lasing creates a near superhydrophobic surface regardless of what setting was used in the first lasing, which yields more freedom of tuning the physical (structure and morphology), chemical (functional groups), and electrical (resistance) properties. Hereafter, power, speed, and fluence will be reported as percentages. Nevertheless, the relationship between percent power, speed, and fluence for the CO₂ laser is characterized with a camera and a power meter to achieve a measurable correlation between the laser settings and the actual energy that is hitting the surface of the polyimide.

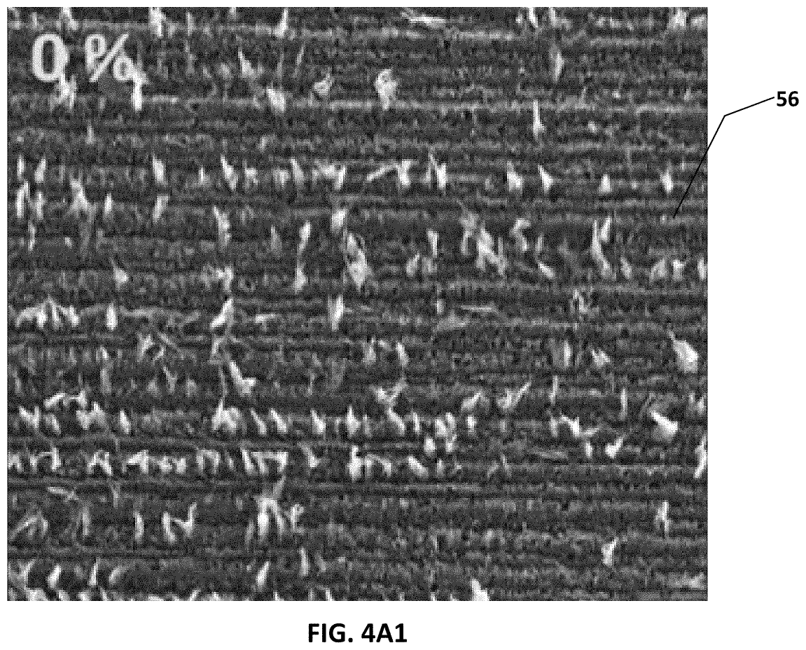

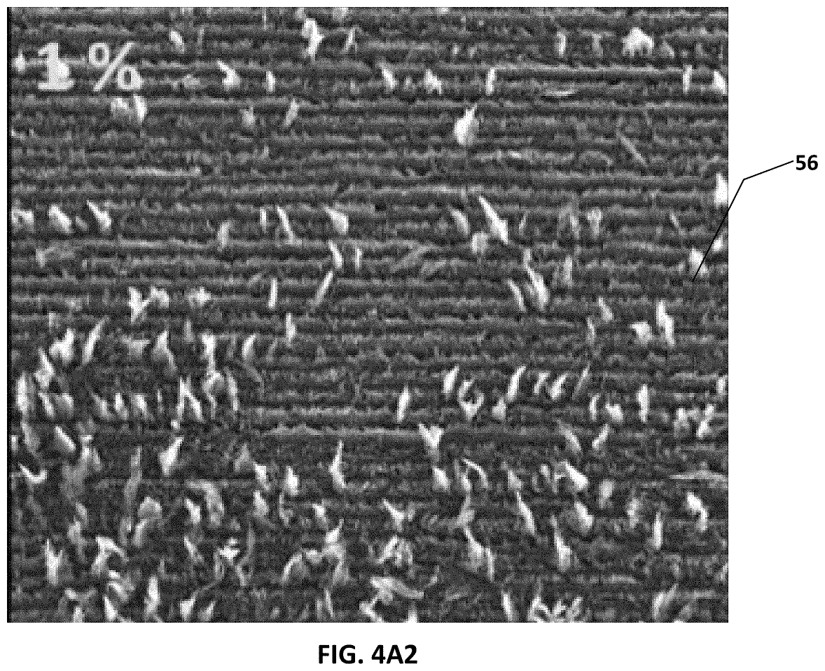

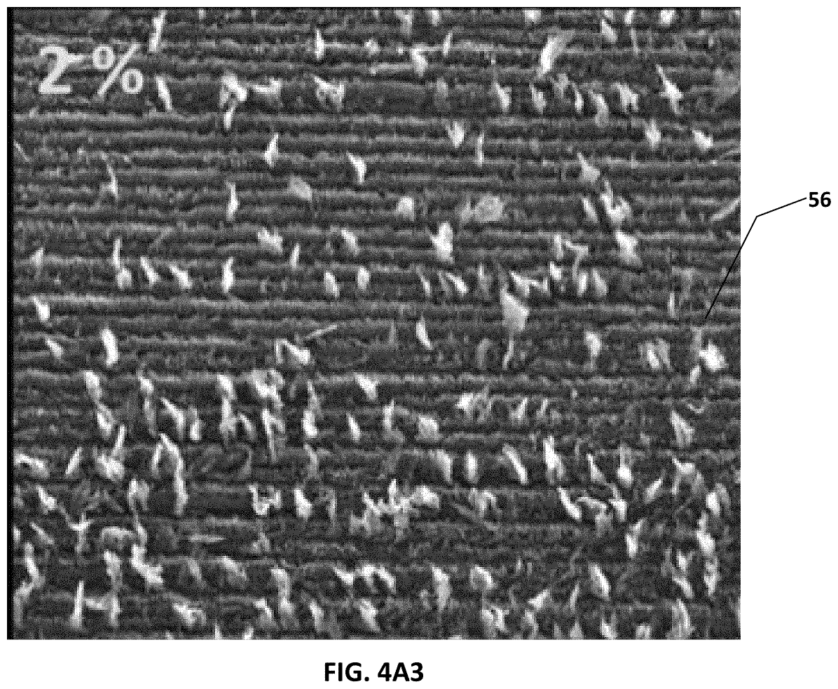

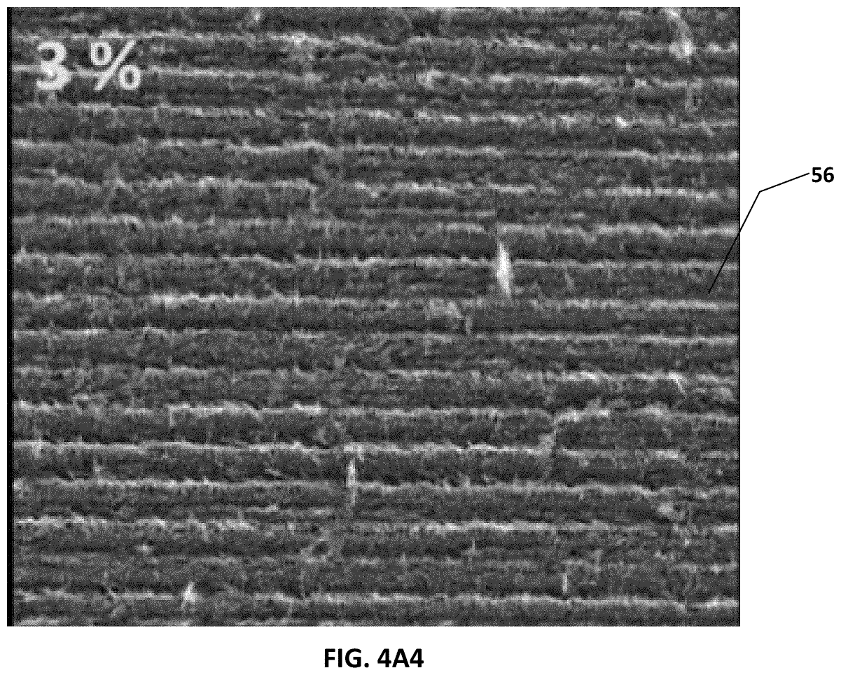

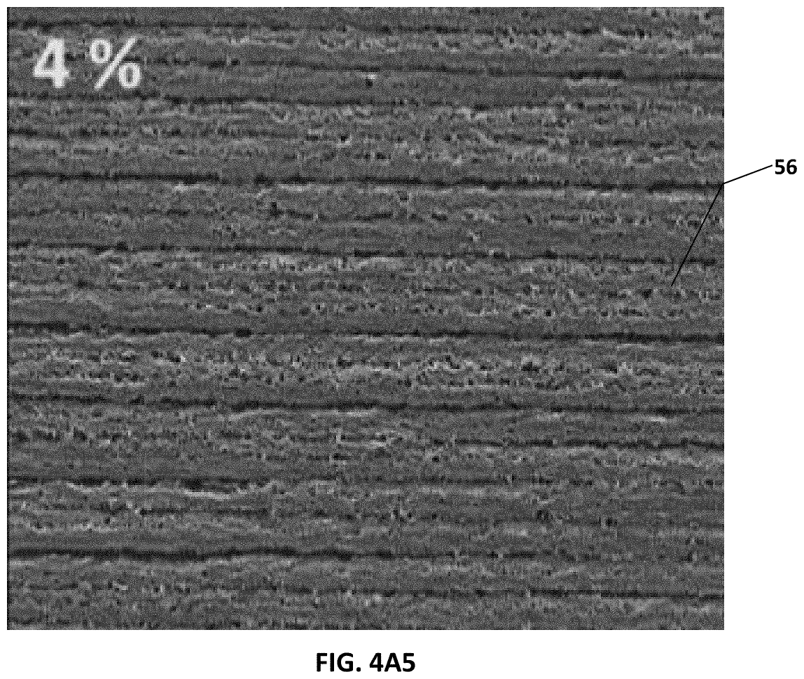

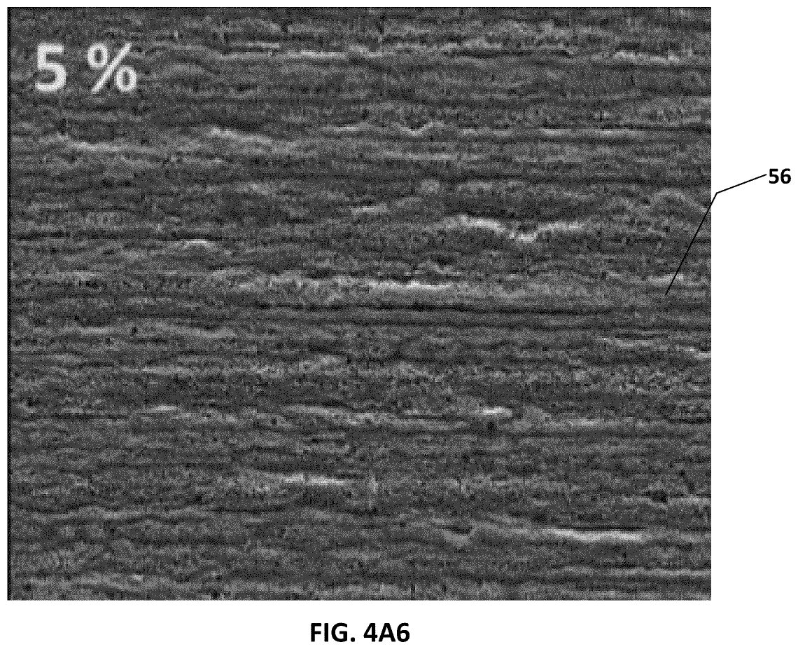

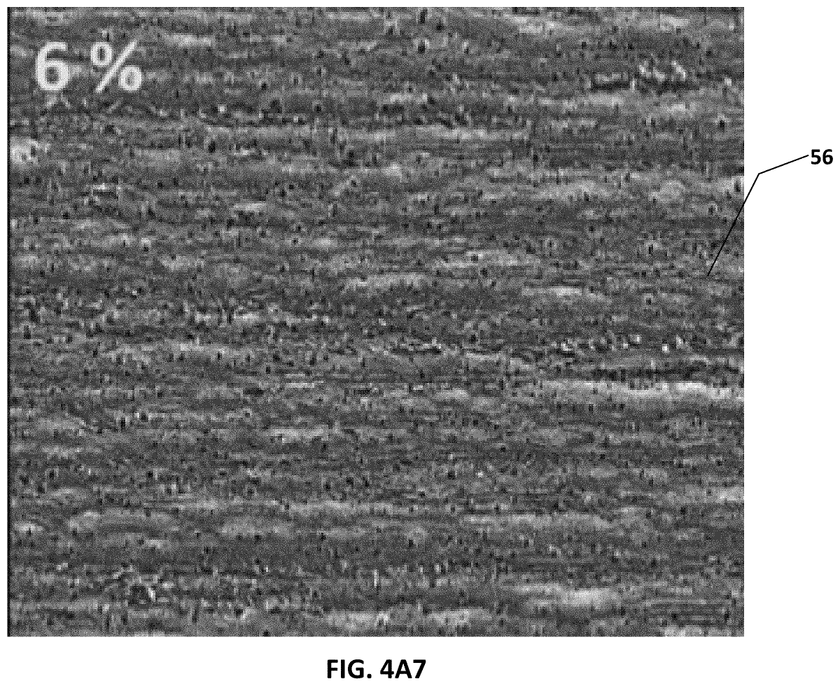

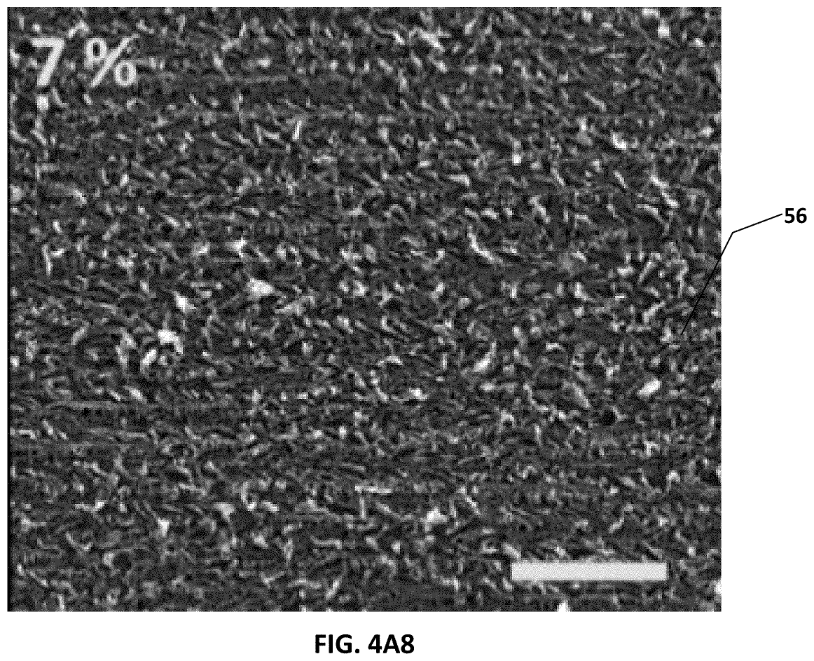

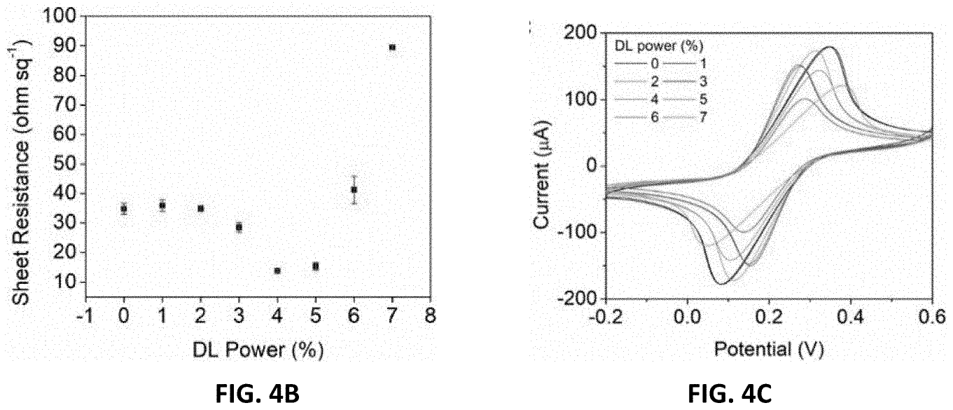

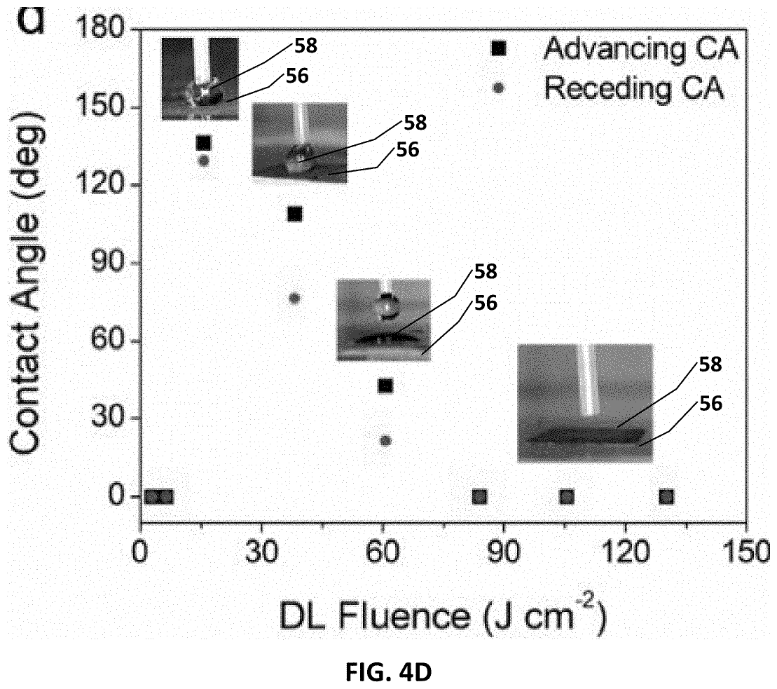

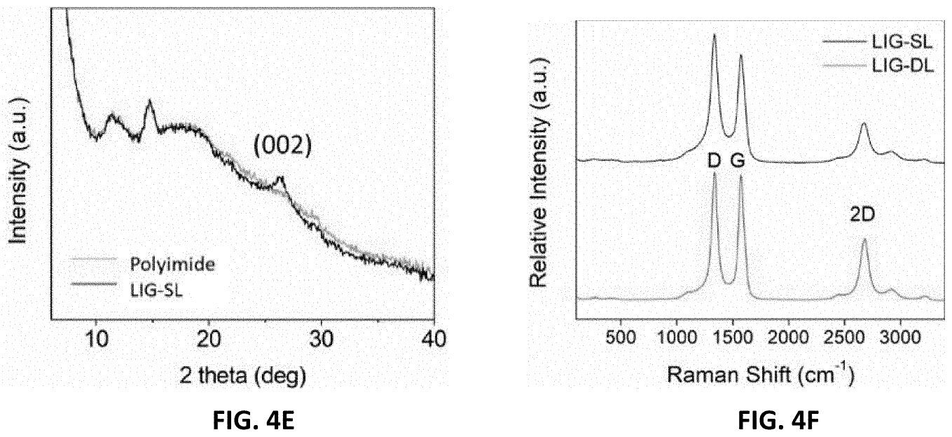

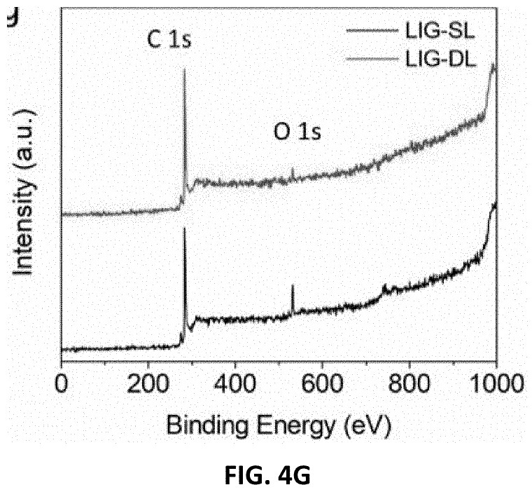

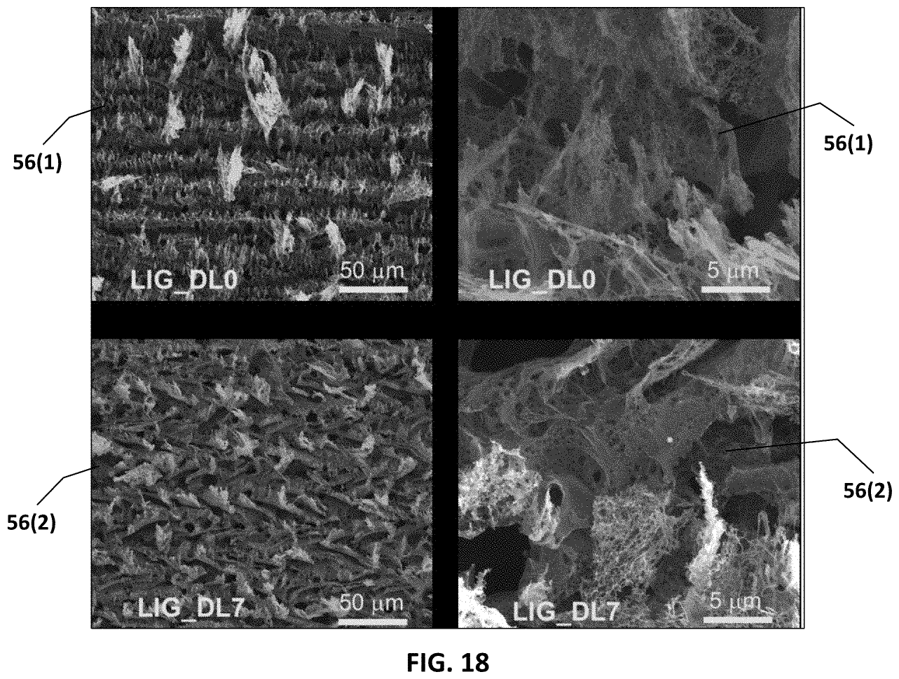

To study the effect of laser power on the LIG wettability, the laser power for double lasing (DL) was varied from 1% to 7% (corresponding to 3-130 J cm⁻²) with the rest of the parameters (speed, DPI, focal distance) unchanged. The double lasing alters the morphology of the LIG 56 as shown in FIGS. 4A1-8. Less surface protuberances are observed for DL power 3-6% samples compared to single lasing sample (0% DL power) and lower DL power samples (1-2% DL power). To clarify, high magnification images of LIG-DL created with 0% double lasing power and 7% double lasing power show the low hairlike surface perturbations at higher laser power than at lower laser power (FIG. 18). The sheet resistance of the LIG-DL with various DL power were taken at ambient condition (25° C.) on a Hall effect measurement system and plotted in FIG. 4B. The sheet resistance slightly decreased from 0% to 5% DL power, which could be attributed to the further reduction of LIG with the double lasing process, consequently improving electrical conductivity. However, the sheet resistance increased significantly with high DL power (7%), which could be attributed to the oxidation of LIG at high power. Moreover, these sheet resistance values represent the average readings from measurements along the lasing track and perpendicular to the lasing track. When measured separately, the sheet resistance reading perpendicular to the raster direction is about 25% higher than the parallel direction. FIG. 4C shows the cyclic voltammetry response of the corresponding LIG-DLs as working electrode versus Ag/AgCl in 0.1 M KCl containing 4 mM K₃[Fe(CN)₆]/K₄[Fe(CN)₆] at a scan rate of 50 mV/s. The peak currents decreased with the increased DL power from 0% to 3%, which could be attributed to the reduced contact between electrode surface and electrolyte due to the increased hydrophobicity of LIG-DL electrodes. However, above 4% DL power, the peak currents increase again due to the improved wetting. Interestingly, the peak-to-peak separation was reduced from 271 mV (0% DL power) to 149 mV (3% DL power) with the increased hydrophobicity, which indicates an improvement in electron transfer kinetics. Laser fluence between 15.67 and 60.73 J cm⁻² (3% and 5% DL power) leads to a change in the wettability change of the LIG surface. No change of wettability was observed on LIG-DL with a fluence less than 15.67 J cm⁻² (2% DL power). However, the LIG-DL turns hydrophobic when the fluence is greater than 15.67 J cm⁻², and a laser sparking on the polyimide/LIG surface was observed during the lasing process. With the increased fluence, the hydrophobicity decreased as the contact angle reduced from 143° at 3% DL power to 21.3° at 5% DL power, and when the fluence is greater than 84 J cm⁻² (6% DL power), the LIG-DL becomes superhydrophilic again (CA=0°, FIG. 4D insets). The contact angle hysteresis, a reflection of the activation energy required for movement of a droplet from one metastable state to another on a surface can be measured by the difference between advancing and receding contact angles.⁶³ For 3% DL power, hysteresis was relatively small (5.1°) compared to LIG-DL fabricated with 4% and 5% DL power (over 20°). To study the effect of fluence on the wettability of LIG, a fluence below 15.7 J cm⁻² and above 60.7 J cm⁻² was also applied, and no hydrophobic effect was observed. At low power, there was not sufficient energy to modify the LIG surface, and at high energy, strong oxidation is present which is similar to the LIG created by single lasing. Based on these results, we conclude that the speed 20% and power 3% is the most suitable setting for the double lasing process. Also, it should be noted these laser settings produced near superhydrophobic graphene (static water contact angle of ˜143°) that is used in the subsequent open microfluidics and electrochemical sensors presented in this manuscript. The resulting near superhydrophobic graphene surface is most likely due to the reduction in superficial oxygen species and the micro/nanostructuring of the graphene surface.⁵⁴ This near superhydrophobic graphene demonstrates a high degree of water droplet repulsion even 2 weeks after electrode synthesis (See Movie 1 of Supporting Information publicly available at https://pubs.acs.org/doi/10.1021/acsnano.1c04197). The micro supercapacitor, which will also be presented later in this manuscript, was prepared with LIG-SL as it offers better wetting surface properties between the electrode and aqueous electrolyte and greater capacitance.

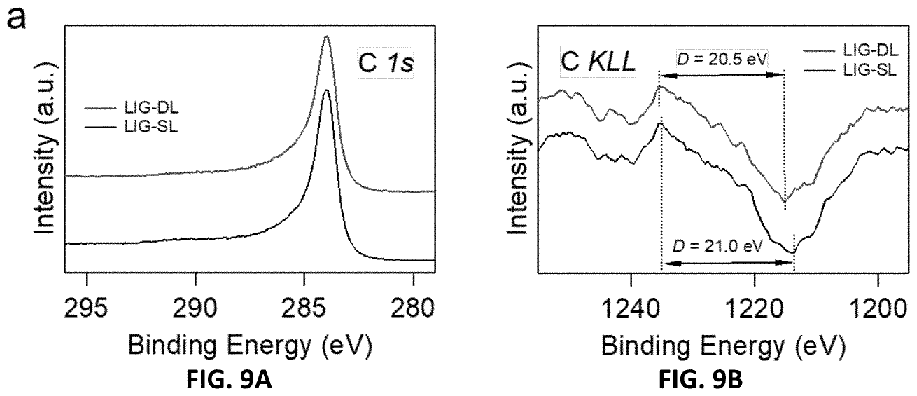

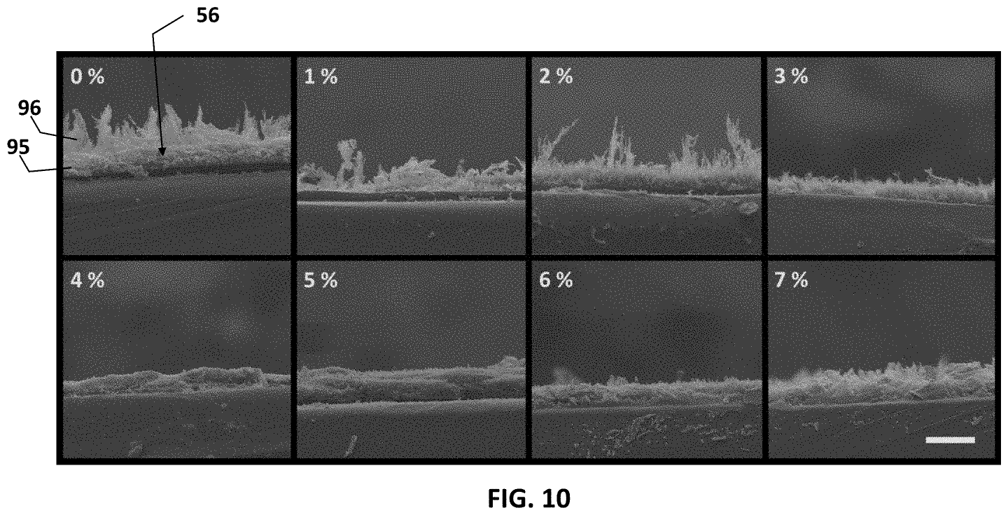

The wettability of a solid surface is strongly influenced by both the physical structure (or surface roughness) and surface chemistry. In general, the wetting of liquid on textured surfaces typically exhibit one of two states: (i) the Wenzel wetting state,⁶⁴ in which water is in full contact with the textured surface, or (ii) the Cassie-Baxter wetting state,⁶⁵ in which water is in contact with the peaks of the textured surface and air pockets are trapped in between. To further study the effect of double lasing, small-angle X-ray scattering (SAXS), Raman, and XPS analyses were conducted. From SAXS, the (002) reflection peak of graphitic crystal plane at 26.3° indicates the presence of stacked graphene layers after the lasing of polyimide (FIG. 4E).⁶⁶ There was not a peak at 26.3° on the unlased polyimide sample. Raman spectroscopy obtained from LIG also supports the presence of graphene (the presence of 2D peak). Three main peaks (D, G, and 2D) are present with the D peaks at ˜1350 cm⁻¹ due to the defects and bending, the G peak at ˜1580 cm⁻¹ indicative of sp²-bonded carbon atoms, and the 2D peak at ˜2700 cm⁻¹ characteristic of graphene, consequently indicating the presence of few-layered graphene (FIG. 4F). The hydrophobic LIG also has the expected peak position with a slightly higher D/G ratio (1.1±0.1 compared to 1.01±0.07) and a lower 2D/G ratio (0.38±0.05 compared to 0.51±0.03) due to the further bending of the LIG surface after double lasing. The high DPI and power offer higher degrees of laser irradiation which is critical for producing highly conductive graphene. However, such high temperature lasing in ambient air allows oxygen atoms to naturally react with the carbon atoms on the graphene that creates a variety of hydrophilic oxygen-containing functional groups (e.g., carboxyl, hydroxyl, and carbonyl) on the LIG surface. These oxygen-containing functional groups have an excellent affinity toward water droplets, which makes the single lasing sample superhydrophilic. This is evident from the XPS survey of LIG before and after double-lasing (FIG. 4G). Higher O is content is observed with the single lasing sample while the oxygen content decreased from 15.85% to 4.01% after the second lasing. The increased C—C peaks, which are well-known to be hydrophobic, lead to the increased hydrophobicity of the LIG-DL. The deconvoluted peak from the C is spectra of the as-prepared graphene oxide is attributed to C══C/C—C bonds (284.6 eV), epoxy (C—O)/hydroxyl (C—OH) bonds at 286.6 eV, carbonyl (C══O) bonds at 287.9 eV, and carboxyl (C(══O)—OH) bonds at 289.2 eV. From C1s spectra, the asymmetric shape of the main peak at 284.0 eV and the presence of the high binding energy pi-pi* satellite show that the C in both samples are mainly sp² type (FIG. 9A). This is confirmed by the D parameter analysis shown in the C KLL spectra (FIG. 9B). The separations between the maxima and minima in differentiated Auger spectra from both samples are close to that from sp² graphite. To further investigate such changes in hydrophobicity, cross-sectional SEM images (FIG. 10) were used to study physical structure of the LIG before and after double lasing. Both methods create a porous structure 95 with an increased film thickness, and numerous microfibers 96 with a diameter less than 1 mm were formed by double lasing. Such microstructures at different scales lead to the increased hydrophobicity of LIG. The synergistic effect of the microstructure surface and the hydrophobic property of the surface functional groups is critical for superhydrophobicity.^{54,67} The LIG-DL with 3% DL power presents hydrophobic behavior with an average static contact angle of 143° which is very close to superhydrophobic (static contact angle ≥145°)⁶⁸ without significantly affecting the electrical conductivity. We further demonstrate the impact of such wettability tuning of LIG by creating multiplexed biosensors as well as a flexible energy storage device.

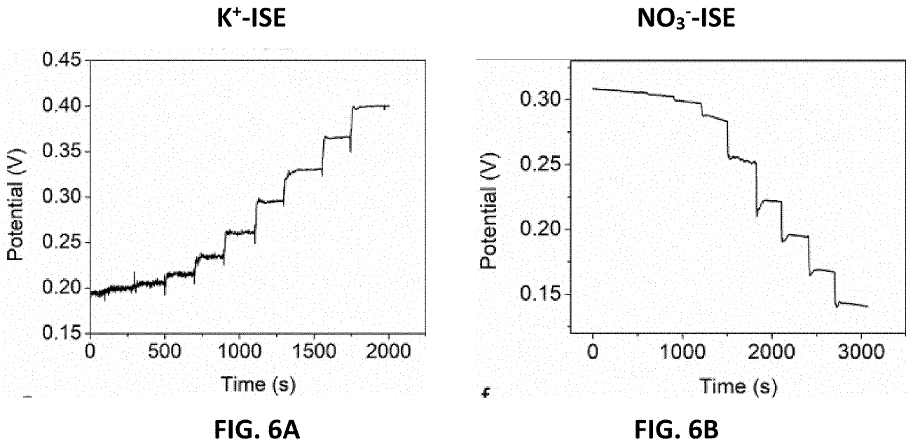

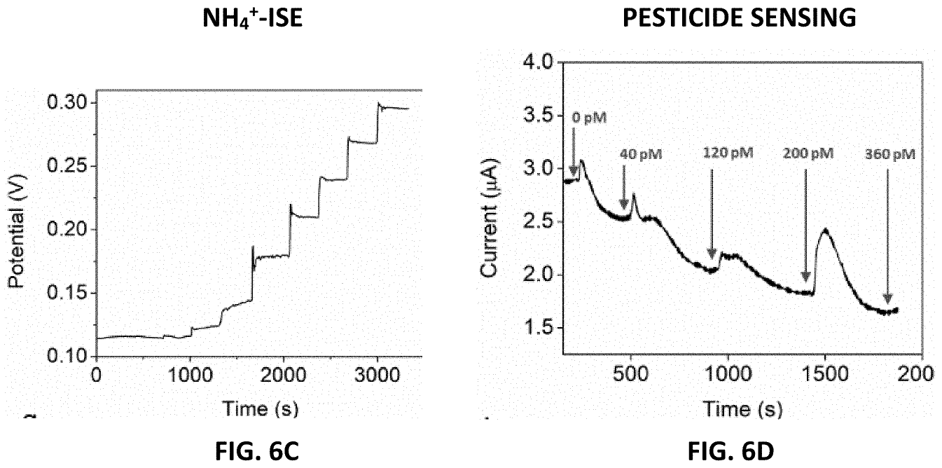

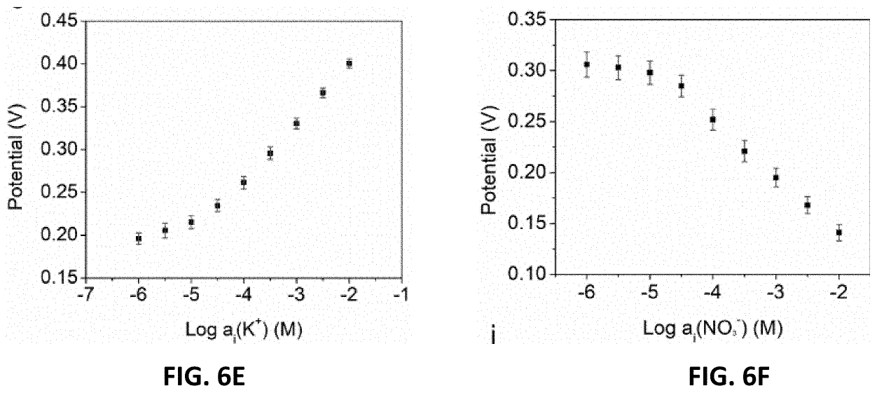

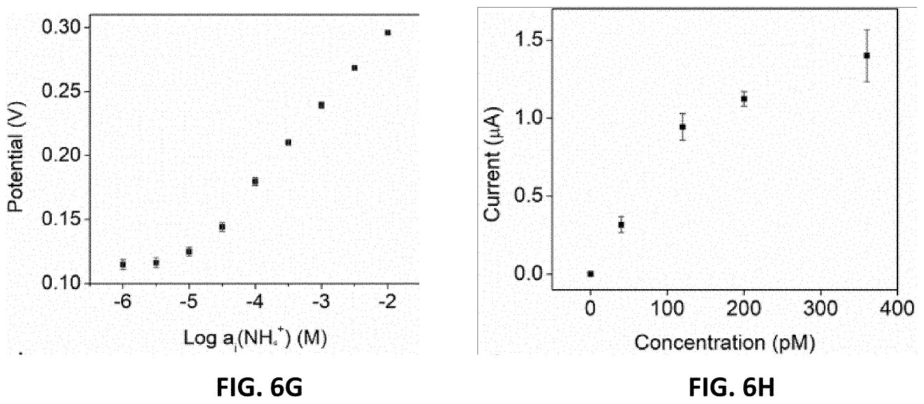

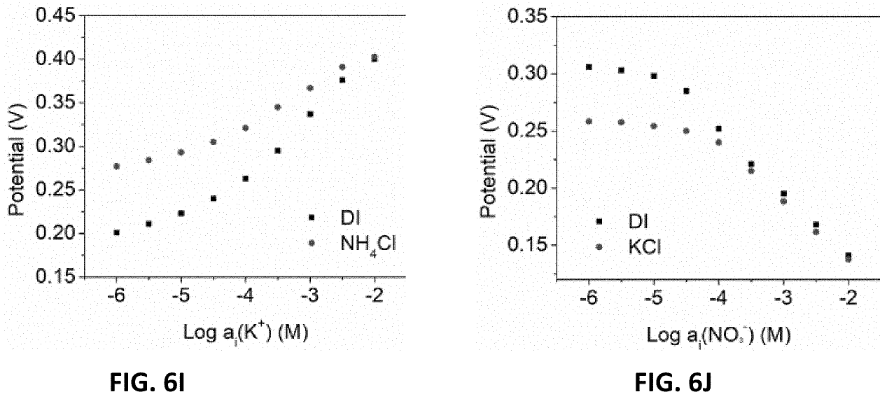

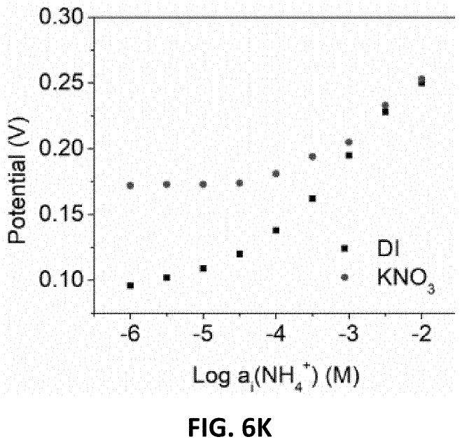

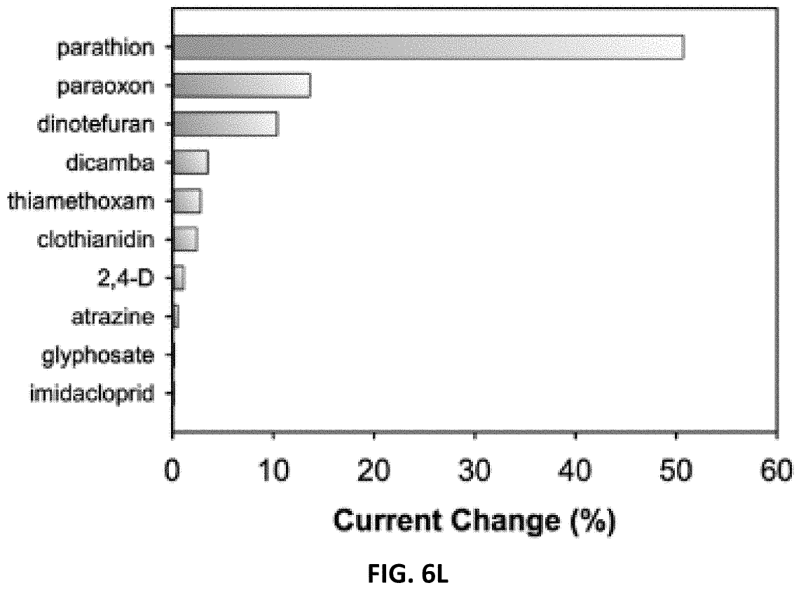

Design and Fabrication of LIG-Based Multiplexed Electrochemical Biosensors with Open Microfluidics. The wettability tuning of LIG, while retaining advantageous electrical properties, make it an ideal candidate for creating low-cost open microfluidics sensing devices. Graphene-based electrochemical sensors are inherently well-suited to monitor both small ions and large chemical compounds, owing to graphene's high surface area, fast electron transport, and rich surface chemistry.⁶⁹ Laser scribing has been used to directly obtain graphene nanomaterials from different substrates for fluid transport and energy applications⁷⁰⁻⁷³ The fabrication schematics of all the key components of the multiplexed sensing device: laser induced graphene-open microfluidics (LIG-OM), laser induced graphene-ion-selective electrode (LIG-ISE), and laser induced graphene-pesticide sensor (LIG-PS) are detailed in FIGS. 5A-D. The first lasing 81 (60 at FIG. 5A) converts polyimide 51 into superhydrophilic OM tracks 62A-D as well as the electrochemical sensors 64A-D. In this non-limiting example, there are four OM tracks 62A-D each emanating from a center common point 61. In this non-limiting example, sensor 64A has three electrodes 65A, 66A, and 67A; whereas sensors 64B-D have two electrodes 68 and 69 each. These patterns are easily created through the use of a computer aided design (CAD) file that is uploaded into a computer 42 that controls the laser 44 and its beam 45 (FIGS. 2A-C). The second or double lasing 82 (70 at FIG. 5B) selectively converts the lateral boundaries 72 (Left) and 72 (Right) of each OM track and electrodes for ISEs from superhydrophilic to near superhydrophobic (only left and right of track 72 are indicated for simplicity, but all tracks include them). The second or even a third or more lasing can convert one electrode 78 of each sensor 64B-D from superhydrophilic to near superhydrophobic if needed (e.g., in some ion selective working electrodes converting the graphene to hydrophobic can be better for binding of layers or materials to the graphene and avoids having to make the conversion in other ways or steps such as by chemical treatment). See multi-lased electrodes 78B, 78C, and 78D in this non-limiting example. Only This step is critical for ISEs to reduce water-layer formation which consequently limits sensor drift and increases sensor longevity.⁷⁴⁻⁷⁶ Four types of sensors are fabricated within the multiplexed sensing platform, namely, a potassium ion-selective electrode (K⁺ ISE) 86, a nitrate ion-selective electrode (NO⁻ ISE) 87, an ammonium ion-selective electrode (NH⁺ ISE) 88, and an enzymatic-based pesticide sensor 85, while a solid-state polyvinyl butyral (PVB)-based Ag/AgCl reference electrode is used in conjunction with all of the sensors.⁷⁷ The ISEs were created (post-functionalized at 80A and 80B of FIGS. 5C-D) by drop coating a polymetric ion-selective membrane that is distinctly selective to each of the mentioned ions onto the LIG-DL electrodes while the enzyme acetylcholinesterase (AChE) was cross-linked with glutaraldehyde and drop coated onto a LIG-SL electrode for the detection of organophosphate pesticides (parathion) (see the Experimental Section below). A video demonstrates how a fluid sample (water containing green fluorophore for visualization) a pipettor divides and moves to the four sensors at the ends of the open microfluidic track (See Movie 2 of Supporting Information publicly available at https://pubs.acs.org/doi/10.1021/acsnano.1c04197). The open circuit potential (OCP) response of the K⁺ ISE, NO₃⁻ ISE, and NH₄⁺ ISE to KCl, KNO₃, and NH₄Cl solutions, respectively, within the concentration range varying from 10⁻⁶ M to 10⁻² M, were acquired in deionized water (DI) (see FIGS. 6A-D and FIGS. 6E-G). All ISEs show near-Nernstian behaviors with sensitivities of 60.87 mV/dec, −57.87 mV/dec, and 51.66 mV/dec for K⁺, NO₃⁻, and NH₄⁺, respectively. The limit of detection (LOD) of each ISE is also calculated to be 10_{-5.01} M, 10^{-5.07} M, and 10^{-4.89} M for K⁺, NO₃⁻, and NH₄⁺, respectively (FIGS. 6I-K). The high selectivity of a potentiometric sensor is a key factor to ensure the practical applications of ISEs in complex sample matrixes. For this purpose, cross interference among the selected ions was tested by using the fixed interference method (FIM) where the concentration of the target analyte ion is varied in a background of a fixed concentration (2 mM) of chosen interference (FIGS._6I-K).⁷⁸ These LIG-based sensors show comparable sensitivity and selectivity to other carbon-based solid contact ISEs (Table 1).^{58,69,79-81}

TABLE 1
Performance summary of the potassium (K⁺), nitrate (NO₃⁻),
and ammonium (NH₄⁺) ion selective electrodes (ISEs) fabricate using
LIG-DL. Values given are averages of three replicates ± standard deviations.

| | | Detection | Standard Potential | | |
|---|---|---|---|---|---|
| | Sensitivity | Limit | E⁰ | | |
| ISE | (mV/dec) | (M) | (mV) | Selectivity Coefficients | |
| K⁺ | 60.87 ± 0.41 | 10^{-5.01±0.02} | 521.40 ± 39.10 | logK_{i,NH}_{₄}_{⁺}^{pot} | −1.2 ± 0.1 |
| NO₃⁻ | −57.87 ± 1.43 | 10^{-5.07±0.01} | 39.75 ± 13.14 | logK_{i,Cl}_{^{−}}^{pot} | −2.0 ± 0.2 |
| NH₄⁺ | 51.66 ± 3.06 | 10^{-4.89±0.08} | 369.50 ± 35.35 | logK_{i,K}_{⁺}^{pot} | −0.7 ± 0.2 |

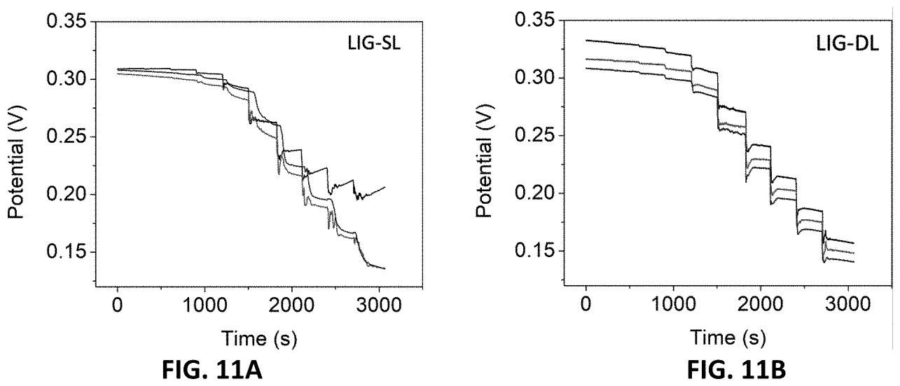

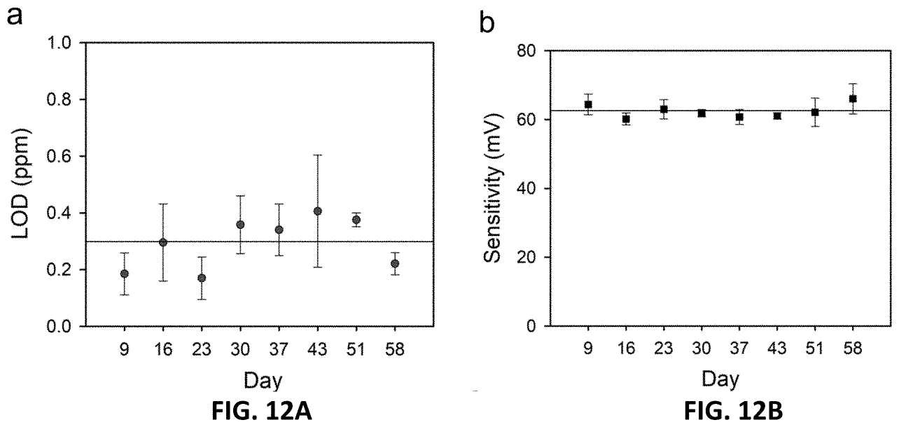

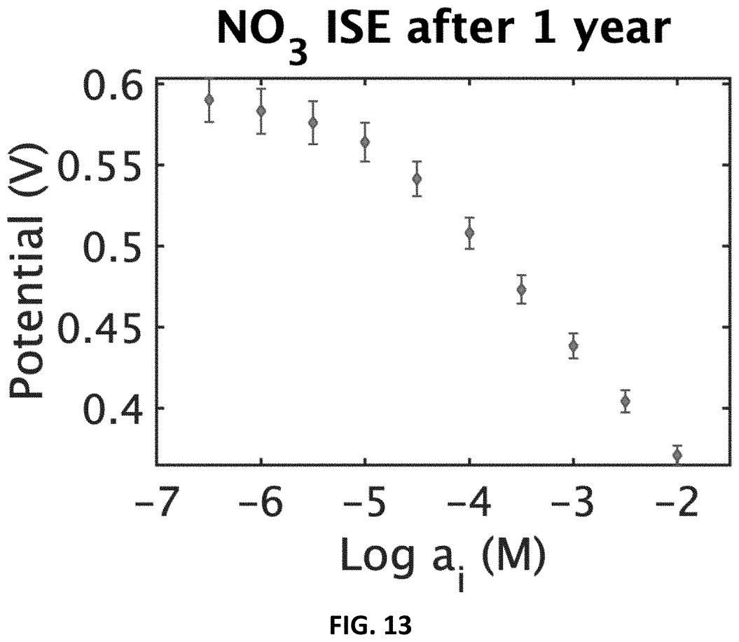

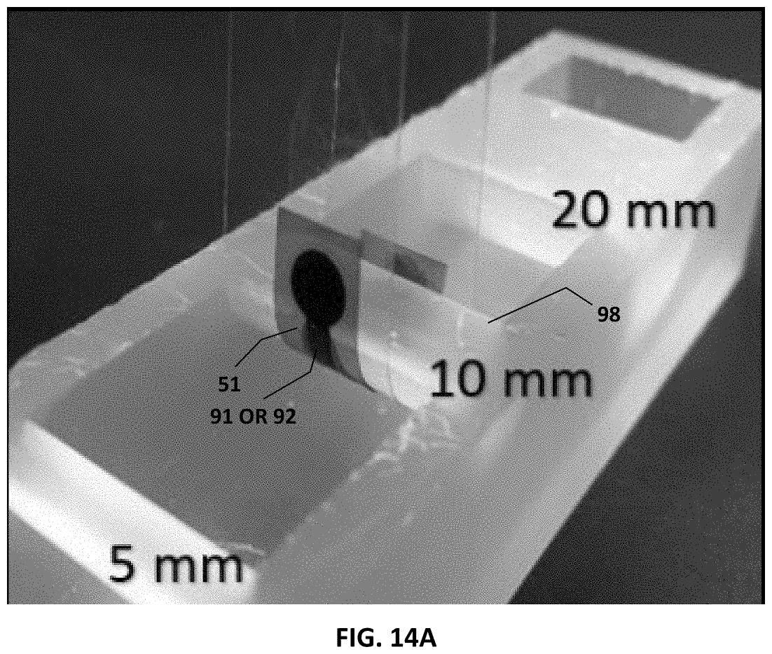

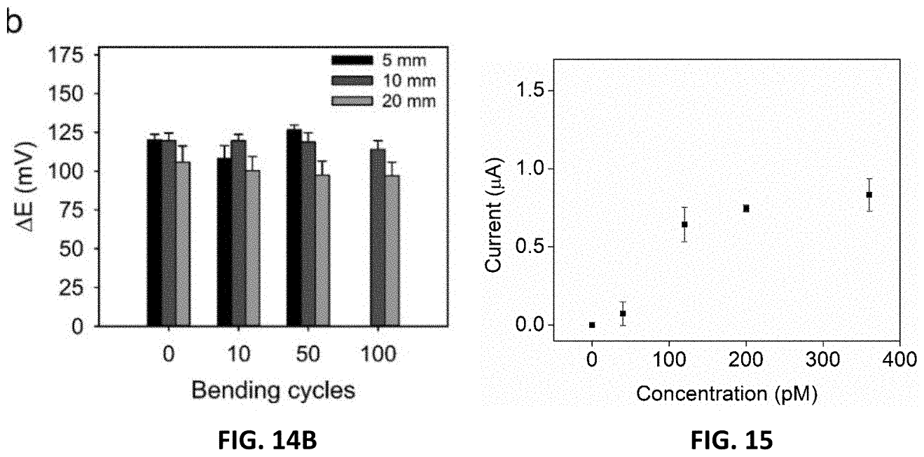

By tuning the wettability of LIG from super-hydrophilic to near superhydrophobic, the formation of a water layer was significantly suppressed, thus leading to reduced sensor to sensor variations (FIGS. 11A-B). In fact, the LIG-DL nitrate ion selective sensors displayed a negligible change in the limit of detection and sensitivity after repeated weekly testing for 2 months (FIGS. 12A-B). The same LIG-DL nitrate ion selective sensors also displayed a negligible change in sensitivity after 1 year in dry, ambient storage (FIG. 13). It should be noted that for solid contact ion selective electrodes, water from measurement samples can migrate into the interface between the polymeric sensing layer and the transduction layer, which in this case is the developed LIG electrode.⁷⁴ This water layer then accumulates ions, reaching a new equilibrium concentration with each sample test and can lead to selectivity, stability, and drift issues in the ISE response.⁸² The strain resistance of LIG-ISE fabricated as LIG-DL was performed by measuring the response of the NO⁻ ISE to KNO₃ (1 mM) under three different bending conditions, 10, 50, and 100 cycles (FIGS. 14A-B).⁸³ The difference in potential measured in nitrate solution was evaluated before and after bending the sensors on rods with diameters of 5 mm, 10 mm, and 20 mm. The only curvature that showed a significant difference between cycles (p=0.003) was the rod 98 of 5 mm. For this rod, the sensors were disabled after 100 cycles, the most drastic condition tested. Nevertheless, even for this harshest bending condition, the sensors could endure up to 50 cycles. Apart from this, all sensors exhibited consistent performance for the other curvatures, for up to 100 cycles. This test demonstrates flexibility of the sensors under harsh conditions and hence such sensors show promise for use in the field.^{69,84}

For pesticide sensing, electrochemical measurements were performed on an all LIG three electrode setup (see the Experimental Section below) with amperometry, which measured the signal induced by acetylthiocholine chloride (ACTH) at a working potential of 0.2 V vs Ag/AgCl, considering that higher potentials caused fouling of the electrode surface. Each sensor was tested using parathion concentrations from 40 pM to 360 pM. Results were obtained from the current-time plot for successive concentration additions, and the average response of three sensors were plotted (FIGS. 6D, H, and L). The response yielded the parathion sensitivity as parathion irreversibly inhibited AChE in each addition, thus causing a decreased signal as the reaction between ACTH and AChE was limited. The sensor exhibited an extremely low LOD of 15.4 pM, the lowest LOD for any parathion sensor to date,⁸⁵ as well as a linear range of 40-120 pM that is similar to other carbon nanomaterial-based sensors made with graphene nanoribbons⁸⁶ (LOD, 0.5 nM; linear range, 5 nM-2780 μM), reduced graphene oxide-palladium⁸⁷ (LOD, 7.4 nM; linear range, 0.1-125 μM), and screen printed modified graphene⁸⁸ (LOD, 52 pg/L; linear range, 0.1-1000 ng/L). It is reported that small enzymatic concentrations (˜200 units/mL) when sensing pesticides yields low limits of detection as well as a limited linear range.⁸⁹⁻⁹¹ This means that with smaller amounts of enzyme on the surface of the electrode, less pesticide is needed to fully inhibit the enzyme activity correlating to a lower linear range as compared to an inhibitory sensor with a higher enzyme concentration. The sensor was tested against 40 nM of possible interference pesticides including the commonly applied herbicides atrazine, glyphosate, dicamba, and 2,4-dichlorophenoxyacetic acid; the heavily used neonicotinoids imidacloprid, thiamethoxam, clothianidin, and dinotefuran; and finally, with paraoxon which is a metabolite of parathion. These results show that 40 nM of the target parathion yielded approximately a 50% change in current as compared to the leading interference species, paraoxon, which yielded a current change of approximately 10% (FIG. 6L). This indicates that the biosensor exhibits a high affinity for parathion compared to other commonly applied pesticides and hence could be used in a wide variety of locations even within major agricultural regions where numerous pesticide types are frequently used.

Next, the multiplexed sensors were tested in a local river water sample (from South Skunk River, Ames, Iowa, January 2021) to evaluate sensor performance within complex biological matrixes. The OCP response to 1 mM target ion in river water and 1 mM target ion in deionized water were compared for all three ISEs. The signal obtained in river water was 104%, 98%, and 102% for the K⁺, NO₃⁻, and NH₄⁺ ISEs as compared to the signal obtained in deionized water using the respective calibration curves (Table 2).

TABLE 2
Performance of ISEs in river water samples.

| | Calibration | | |
|---|---|---|---|
| | Potential at 1 mM | Detected potential | |
| ISE | (mV) | (mV) | Accuracy (%) |
| K⁺-ISE | 468.5 | 489.1 ± 1.1 | 104.41 |
| NO₃⁻-ISE | 406.6 | 402.0 ± 0.4 | 98.39 |
| NH₄⁺-ISE | 239.4 | 243.4 ± 0.3 | 101.68 |

Values given are averages of three replicates ± standard deviations.

For the pesticide sensor, an 84% signal recovery was observed in river water (FIG. 15). The overall sensing performance of the developed multiplexed sensors demonstrates the practical application of rapid in-field water sample tests with high accuracy compared to commercial liquid junction-based ion selective electrodes that are geared to water analysis typically in a laboratory. Moreover, the electrochemical parathion sensor overcomes the challenges associated with commercially available environ-mental biosensors that are geared toward rapid assessment in the field (e.g., OrganaDx by MyDx). These field-based environmental sensors generally require pipetting into multiple wells for multiplexed sensing and rely upon colorimetric test results which can be easily misread under different lighting conditions, do not report concentration readings as the test gives only a yes/no result, and can be fouled/misread due to particulate matter found in field samples.⁹²

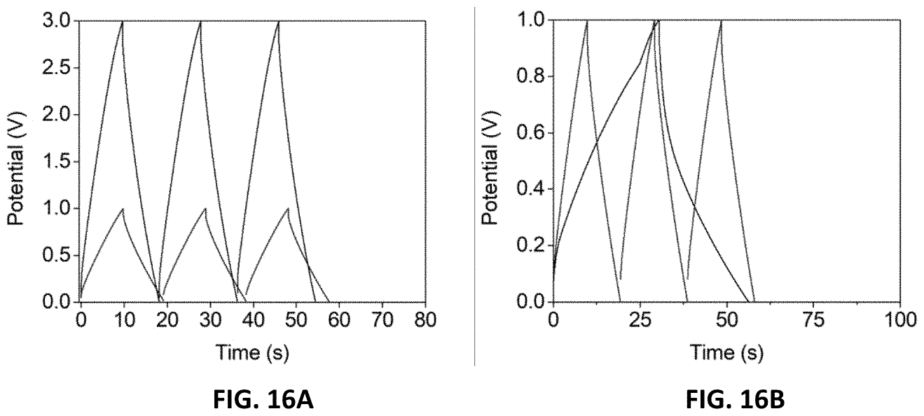

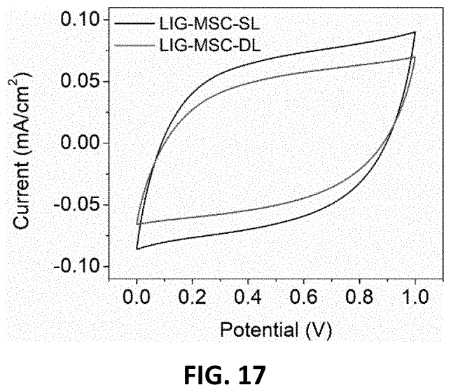

Design and Fabrication of LIG-Based Micro Super-capacitors. To demonstrate the broad impact of wettability tuning in other applications, micro supercapacitors (MSC) were prepared with superhydrophilic and near superhydrophobic LIG in interdigitated electrode (IDE) patterns (FIG. 7A). Two types of laser induced graphene micro supercapacitor electrodes were fabricated: superhydrophilic LIG 91 created by single lasing (LIG-MSC-SL) and hydrophobic LIG 92 created by double lasing (LIG-MSC-DL). The MSC electrodes 90 were first created by scribing the polyimide (PI) substrate 51 with the beam 45 of a CO₂ laser 44. Then, the poly(vinyl alcohol) (PVA)-based gel electrolyte 94 containing 1 M sulfuric acid (H₂SO₄) and Kapton tape 93 was used to complete the fabrication of the MSC devices (see the Experimental Section below). To study the effect of IDE wettability on the electrochemical performance of the MSC, LIG-SMC-SL 91, and LIG-MSC-DL 92 with the same dimensions (finger size 5 mm by 2 mm, 10 pairs in total which makes for 0.2 cm² effective electrode area) were fabricated. Cyclic voltammetry (CV) and galvanostatic charge-discharge (GCD) experiments in a potential window from 0 to 1.0 V were performed to study the electrochemical performance. FIGS. 7B and 7C show the CV curves of the LIG-MSC-SL 91 and LIG-MSC-DL 92 at different scan rates (10, 20, 50, 100, and 200 mV/s). The nearly rectangular shapes of CV curves indicate the electrical double layer formation. The GCD curves of the LIG-MSC-SL and LIG-MSC-DL (FIGS. 7D and 7E) at different current densities (0.1, 0.2, 0.5, 1, 2, 5 mA/cm²) show triangular shapes which indicate capacitive behavior.^{93,94} The LIG-MSC-SL sample shows larger area under the CV curve and GCD curve (FIGS. 7F and 7G) compared to the LIG-MSC-DL under the same scan rate and current density, indicating the higher capacitance of the superhydrophilic LIG electrodes. The near superhydrophobic LIG electrode reduces wetting compatibility between the PVA-based gel electrolyte and the LIG matrix, often resulting in pores within the electrode interior not fully wetted by the electrolyte solution. The abundant presence of —OH groups in PVA improves the wetting of electrolyte on LIG, which facilitates the ion-transport and higher accessibility to the electrode surface. The LIG-MSC-SL exhibits higher specific capacitance (Cₛₚ) over a wide range of current densities from 0.1 to 5 mA/cm² compared to LIG-MSC-DL, with the highest Cₛₚ of 14.9 mF/cm². Both LIG-MSC-SL and LIG-MSC-DL samples retain their capacitance even after 5000 cycles of GCD at 1 mA/cm². Multiple MSCs in series and parallel with different dimensions can also be prepared by simply altering the drawing files to extend the voltage windows and capacities (FIGS. 16A and 16B). Ragone plots were used to compare the LIG-MSC with commercially available electrolytic capacitor and thin-film batteries. The areal metrics are shown in FIG. 7J, and volumetric metrics are shown in FIG. 7K. The LIG-MSCs exhibit 2 orders of magnitude improvement of power density at similar energy densities compared to a Li-based thin-film battery and 3 orders of magnitude of improvement of the energy density compared to a commercial electrolytic capacitor.⁹⁴ Also, the LIG-MSC-SL shows slightly higher energy density (2.07 μWh/cm²) compared to LIG-MSC-DL (1.25 μWh/cm²) at 0.1 mA/cm². Lithium hexafluorophosphate solution (LiPF₆) in ethylene carbonate, dimethyl carbonate, and diethyl carbonate are also used as the model organic electrolytes to compare the effect of wettability on the capacitance of LIG-MSC. The specific capacitance for LIG-MSC-SL is slightly higher at 1.08 mF/cm² as compared to 0.81 mF/cm² for LIG-MSC-DL with LiPF₆ as the organic electrolyte based on the CV measurement (FIG. 17) at a scan rate of 50 mV/s. Such controlled wettability tuning of LIG allows easy tuning of the electrode surface based on the property of the electrolyte. For example, organic electrolytes used in energy storage devices require a hydrophobic electrode for sufficient wetting contact and ion transport.⁹⁵ In this case, LIG-DL can be easily fabricated by simply adding one more lasing pass.

Conclusion

A simple and sensitive multiplexed electrochemical sensor combined with open microfluidics was developed for environ-mental sensing applications by controlling the wettability of LIG. The open microfluidics enabled rapid sampling and required less volume of sample solution compared to conventional laboratory-based electrochemical sensing. The ion-selective electrodes were capable of detecting K⁺, NO₃⁻, and NH₄⁺ ions down to the micromolar range in the lab and millimolar range in river water samples. The pesticide sensor successfully detected parathion and exhibited a LOD of 15.4 pM, which is the lowest LOD for any electrochemical parathion sensor to date. Such LIG based microfluidics sensing platforms are highly scalable as the graphene electrodes can be simply manufactured through a direct write laser process performed in ambient conditions with a ubiquitous CO₂ laser while graphene functionalization could be carried out with automated pipettor systems. Using the same LIG fabrication technique, an electrochemical micro supercapacitor (MSC) was developed. The LIG-based MSC exhibited a high power density that was 2 orders of magnitude greater than a Li-based thin-film battery, and the energy density was 3 orders of magnitude greater than compared to a commercial electrolytic capacitor.

Moreover, this manuscript demonstrates a method to control the surface wettability of the LIG from highly hydrophobic to hydrophilic by only changing the lasing parameters. This lasing is also done in ambient conditions without the need for lasing in an oxygen limited environment such as within a nitrogen or argon filled chamber; hence, the controlled surface wettability patterning with the direct write laser demonstrated herein is highly scalable. Controlling the surface wettability of graphene can significantly improve the performance of electronics associated with electrochemical sensing,^{74,96-99} energy storage,¹⁰⁰⁻¹⁰² and solar water desalination in addition to permitting open fluidic fluid transport.¹⁰³ More specifically, superhydrophilic graphene with contact angles below 10° has proven important to many applications including as a wicking material in heat pipes, enhanced boiling heat transfer,^{104,105} and solar thermal water desalination.¹⁰⁶⁻¹⁰⁸ Superhydrophobic graphene promotes the development of self-cleaning¹⁰⁹ and anti-icing^{110,111} surfaces. Smart LIG surfaces created by facile surface wettability could lead to low-cost microfluidics as well as benefiting broader applications that involve interface chemistry such as electro-chemical sensing, energy storage, and oil/water separation. Hence, this tunable fabrication approach of LIG is expected to enable real-time, point-of-use health, and environmental monitoring across a wide range of applications including sensors, biosensors, wearables, antennas, energy harvesters, energy storage modules, and single-use electronics.

Experimental Section

Materials and Reagents. Polyvinyl chloride, 2-nitrophenyl octyl ether, tridodecylmethylammonium nitrate, tetrahydrofuran, potassium nitrate, nonactin, potassium tetrakis(4-chlorophenyl)borate, ammonium chloride, valinomycin, and potassium chloride were purchased from Sigma-Aldrich. Polyimide film (125 μm thick) was purchased from DuPont. Silver/silver chloride paste (Cl-4001) was purchased from EMS. Acetylcholinesterase (AChE) from Electrophorus electricus (lyophilized powder, 200-1000 units/mg), parathion, atrazine, dicamba, glyphosate, thiamethoxam, dinotefuran, imidacloprid, clothianidin, paraoxon were purchased from Sigma-Aldrich and all other pesticide sensing materials unless otherwise specified. Deionized (DI) water was used after passing through a B-pure water purification system (18.2 MΩcm⁻²).

Fabrication and Characterization of the LIG. The LIG electrodes were created by lasing a polyimide (PI) film with a 75 W CO₂ laser (Epilog Fusion M2) that has a spot size of approximately 76 μm. The laser setting for creating LIG-SL is speed 15%, power 7%, dot per inch (DPI) 1200 unless specified. The laser setting for creating LIG-DL is speed 20%, power 3%, dot per inch (DPI) 1200 unless specified. LIG-ISE sensors were created with the combination of LIG-SL and LIG-DL settings. LIG-PS sensors were created with the LIG-SL setting. A two-electrode array for ISE sensors and a three-electrode array for enzymatic sensors and interdigitated electrodes for supercapacitors were simultaneously prepared. Laser power and energy was measured by a thermal sensor from Ophir (model no. F150A-BB-26-PPS) with a StarLite Meter. Sheet resistance was measured by Hall measurement systems (MMR H5000) at room temperature. The sheet resistance was measured by the Van der Pauw method with a square sample and electrical contact at the four corners. The contact angle of water was measured using a goniometer with an automated dispensing system (Rame-Hart p/n 100-22) for droplet dispensing. ImageJ was used to process contact angle image and estimate the contact angle value. Raman spectroscopy were performed using an XploRA PLUS confocal Raman upright microscope equipped with a 532 nm excitation source and a synapse electron multiplying charge coupled device camera (Horiba Scientific, NJ, USA). The intensity was determined for the D, G, and 2D bands by fitting the data to a Lorentzian function. Scanning electron microscopy (SEM) images were taken by an FEI Quanta 250 FEG scanning electron microscope at a 10 kV accelerating voltage. Small-angle X-ray scattering (SAXS) was performed using a XENOCS Xeuss 2.0. The Cu tube is operated at 50 kV and 0.6 mA.

Functionalization of ISE and Enzymatic Sensors. After graphene electrodes were scribed, silver/silver chloride (Ag/AgCl) paste 83 (see FIG. 5C) was screen-printed onto one electrode followed by adding a PVB membrane to function as a solid-state reference electrode for both ISE and enzymatic sensors. Untreated LIG is used as a counter electrode in the case of the three-electrode array. The working electrodes for ISEs were prepared by drop-casting polymer membrane solutions onto the hydrophobic LIG (LIG-DL) working area. The NH₄⁺ ion-selective membrane was prepared by drop-casting 10 mL of a mixture of ammonium ionophore I (0.4 wt %), potassium tetrakis(4- chlorophenyl)borate (0.2 wt %), 2-nitrophenyl octyl ether (69 wt %), and poly(vinyl chloride) high molecular weight (30.4 wt %) in tetrahydrofuran (THF). The NO₃⁻ ion-selective membrane was prepared by drop-casting 20 mL of a mixture of tridodecylmethylammonium nitrate (0.2 wt %), 2-nitrophenyl octyl ether (69 wt %), and poly(vinyl chloride) high molecular weight (30.8 wt %) in THF. The K⁺ ion-selective membrane was prepared by drop-casting 20 mL of a mixture of valinomycin (0.5 wt %), dioctyl sebacate (69 wt %), and poly(vinyl chloride) high molecular weight (30.5 wt %) in THF. A solid-state reference electrode was made by depositing a membrane cocktail (10 wt % polyvinyl butyral (PVB) dissolved in methanol with saturated NaCl) onto the LIG-DL.⁷⁷

For enzymatic sensors, an enzymatic solution was prepared by first making 10 wt % glycerol in 20 mM phosphate buffer saline (PBS). This solution was used to prepare 5 wt % bovine serum albumin (BSA). The BSA solution was used to prepare 200 units/mL of AChE. The enzyme solution was aliquoted and stored at −18° C. when not in use. Sensors were fabricated by mixing 200 units/mL with 2.5% glutaraldehyde in a 1:1 volumetric ratio and drop coating 2 μL of this solution onto the LIG (LIG-SL).

Electrochemical Sensing of ISE and Enzymatic Sensors. To test the ISEs, the electrochemical sensing experiments were performed using a PalmSens 4 electrochemical potentiostat with a multiplexer (MU8-R2). Cyclic voltammetry (CV) was performed in 0.1 M KCl with 4 mM [Fe(CN)₆]⁴⁻ as a redox probe. The potentiostat was operated in the “open circuit potentiometry” mode. The selectivity coefficient is derived from the response of ISEs by using the fixed interference method (FIM).¹¹² The calibration curves of the primary ion and the respective calibration curves when the interference ion is present were measured. The primary ion activity aᵢ and the interfering ion activity a; is used to calculate the selectivity coefficient using eq 1. The concentration range of the solutions was from 10⁻⁶ mol/L to 10⁻² mol/L for each of the ions, ammonium, potassium, and nitrate. The range refers to the typical ammonium, potassium, and nitrate found in soil and surface water. The corresponding selectivity coefficient is calculated with the following eq 1:

Kᵢⱼ^{pot}=aᵢ/aⱼ^{z}^{ᵢ}^{z}^{ⱼ} (1)

For enzymatic sensors, electrochemical sensing experiments were performed using a CH instrument potentiostat (600E series). Amperometric methods were used in detecting parathion. A working potential of 0.2 V vs Ag/AgCl was selected as a practical working potential, considering that higher potentials caused fouling of the electrode surface. The concentration range for parathion calibration was from 40 pmol/L to 360 pmol/L.

Fabrication and Characterization of Supercapacitors. Two types of laser induced graphene micro supercapacitor electrodes were fabricated: superhydrophilic LIG created by single lasing (LIG-MSC-SL) and hydrophobic LIG created by double lasing (LIG-MSC-DL). Poly(vinyl alcohol)-based (PVA) gel electrolyte was prepared by mixing 10 g of PVA powder (Mowiol 18-88, Sigma-Aldrich) into 10 mL of 1 M sulfuric acid and stirred on hot plate at 85° C. until the mixture became a clear and gluelike gel. Polyimide tape were applied to insulate the leg region of the MSC and confine the area for electrolyte. About 15 μL of the prepared gel electrolyte was applied on the finger region of the MSC. The electrochemical performance of the fabricated MSCs was characterized by galvanostatic charge-discharge (GCD), cyclic voltammetry (CV), and electrochemical impedance spectroscopy (EIS) with a Gamry Reference 3000 electrochemical station. The areal specific capacitances (Cₛₚ) of each device at different current densities were calculated from the discharge curves obtained from GCD tests using eq 2:

$${C}_{sp} = \frac{I}{S \frac{Δ U}{Δ t}} \qquad ( 2 )$$

where I is the applied discharge current (amp), A (cm²) is the active area of the electrode (finger dimension 5 mm×0.2 mm, 10 pairs in total which makes the effective electrode area equal to 0.2 cm²), Δt is discharge time (second), and ΔU (volt) is the discharge voltage after the iR (current×resistance) drop is removed. The areal energy density (Wh cm⁻³) of each device is calculated using eq 3:

$$E = \frac{0.5 \times {C}_{sp} \times Δ {U}^{2}}{3600} \qquad ( 3 )$$

The volumetric power density (W cm⁻³) of the device is calculated from eq 4:

$$P = \frac{E}{Δ t} \times 3600 \qquad ( 4 )$$

Data Analysis. A completely randomized design was used in this study, and the results are reported as mean±standard deviation. Results were obtained by performing at least three independent experiments. Data analysis was performed using JMP Pro statistical software (version 15, SAS, Cary, N.C.).

### Associated Content

Supporting Information

The Supporting Information is available free of charge at https://pubs.acs.org/doi/10.1021/acsnano.1c04197.

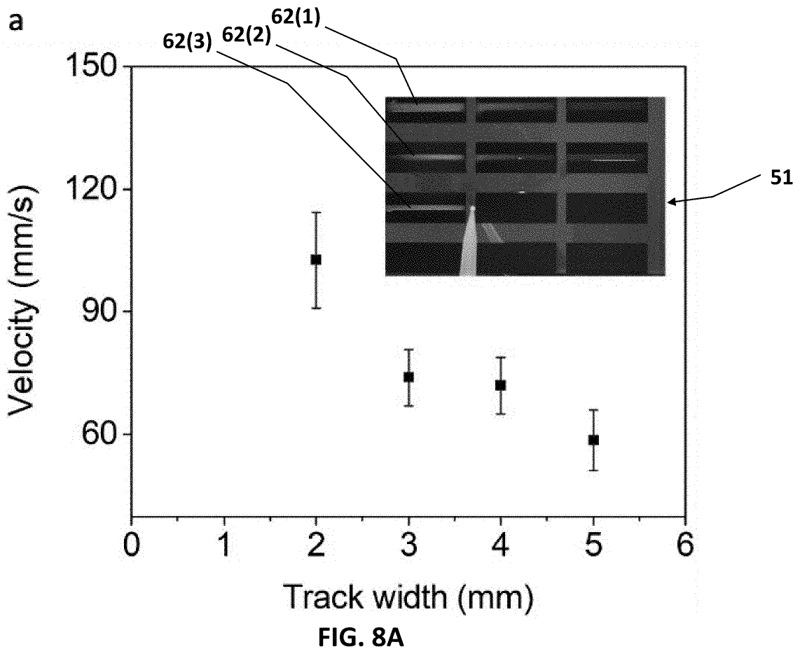

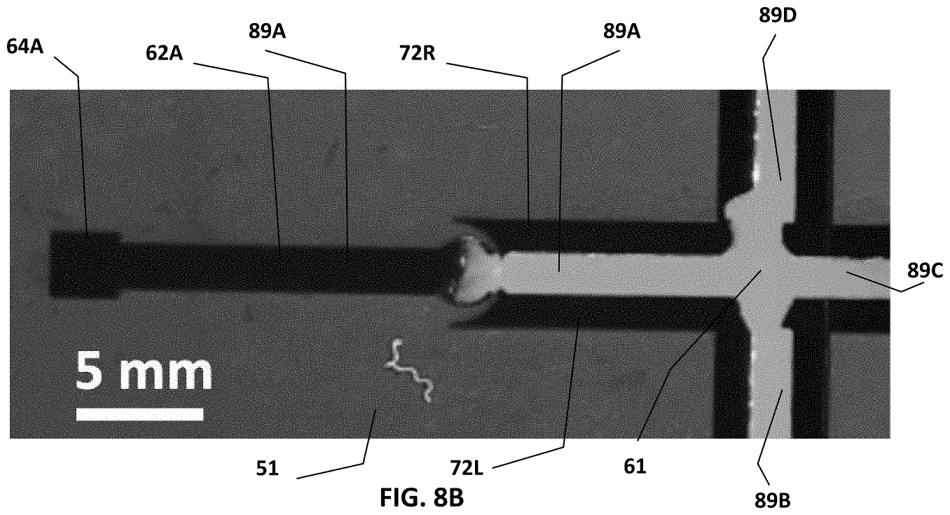

Fluid transport through the LIG-OM (FIGS. 8A-B); XPS spectra of C 1s and differentiated C KLL Auger regions (FIGS. 9A-B); effect of double lasing including the cross-sectional SEM images of LIG-DL created at different double lasing power (FIG. 10); improved sensitivity consistency of nitrate ISEs created with LIG-DL as opposed to those with LIG-SL (FIGS. 11A-B); consistent detection limit and sensitivity measurements of the LIG-DL nitrate ISEs over weekly testing for 2 months (FIGS. 12A-B); shelf life data displaying nitrate LIG-DL ISE calibration plot after 1 year of dry, ambient storage (FIG. 13); long-term stability of the LIG nitrate sensor (FIGS. 12A-B); strain resistance of the LIG sensors against bending (FIGS. 14A-B); calibration plot for the pesticide sensor used in the river water test (FIG. 15); performance of ISEs in river water sample (Table 2 above); electrochemical performance of the LIG-MSC in series/parallel configurations (FIGS. 16A-B) and with organic electrolyte (FIG. 17); and high-resolution images of LIG-DL created with different lasing powers (FIG. 18) (see ref. nos. 56(1) and 56(2).

Video showing water droplet repulsion of the LIG-DL 2 weeks after synthesis (Movie 1) publicly available at https://pubs.acs.org/doi/10.1021/acsnano.1c04197.

Video showing water dividing from a pipettor along the open microfluidic tracks to the four distinct sensors (Movie 2) publicly available at https://pubs.acs.org/doi/10.1021/acsnano.1c04197.

### REFERENCES

(1) Martinez, A. W.; Phillips, S. T.; Whitesides, G. M.; Carrilho, E. Diagnostics for the Developing World: Microfluidic Paper-Based Analytical Devices. Anal. Chem. 2010, 82 (1), 3-10.
(2) Nie, Z.; Nijhuis, C. A.; Gong, J.; Chen, X.; Kumachev, A.; Martinez, A. W.; Narovlyansky, M.; Whitesides, G. M. Electro-chemical Sensing in Paper-Based Microfluidic Devices. Lab Chip 2010, 10 (4), 477-483.
(3) Figueredo, F.; Garcia, P. T.; Cortón, E.; Coltro, W. K. T. Enhanced Analytical Performance of Paper Microfluidic Devices by Using Fe 3O4 Nanoparticles, MWCNT, and Graphene Oxide. ACS Appl. Mater. Interfaces 2016, 8 (1), 11-15.
(4) Hiltunen, J.; Liedert, C.; Hiltunen, M.; Huttunen, O. H.; Hiitola-Keinanen, J.; Aikio, S.; Harjanne, M.; Kurkinen, M.; Hakalahti, L.; Lee, L. P. Roll-to-Roll Fabrication of Integrated PDMS-Paper Microfluidics for Nucleic Acid Amplification. Lab Chip 2018, 18 (11), 1552-1559.
(5) Ma, J.; Yan, S.; Miao, C.; Li, L.; Shi, W.; Liu, X.; Luo, Y.; Liu, T.; Lin, B.; Wu, W.; Lu, Y. Paper Microfluidics for Cell Analysis. Adv. Healthcare Mater. 2019, 8 (1), 1801084.
(6) Kung, C.-T.; Hou, C.-Y.; Wang, Y.-N.; Fu, L.-M. Microfluidic Paper-Based Analytical Devices for Environmental Analysis of Soil, Air, Ecology and River Water. Sens. Actuators, B 2019, 301, 126855.
(7) Kong, Q.; Wang, Y.; Zhang, L.; Ge, S.; Yu, J. A Novel Microfluidic Paper-Based Colorimetric Sensor Based on Molecularly Imprinted Polymer Membranes for Highly Selective and Sensitive Detection of Bisphenol A. Sens. Actuators, B 2017, 243, 130.
(8) Ma, L.; Nilghaz, A.; Choi, J. R.; Liu, X.; Lu, X. Rapid Detection of Clenbuterol in Milk Using Microfluidic Paper-Based ELISA. Food Chem. 2018, 246, 437-441.
(9) Almeida, M. I. G. S.; Jayawardane, B. M.; Kolev, S. D.; McKelvie, I. D. Developments of Microfluidic Paper-Based Analytical Devices (MPADs) for Water Analysis: A Review. Talanta 2018, 177, 176.
(10) Zhu, Y.; Xu, X.; Brault, N. D.; Keefe, A. J.; Han, X.; Deng, Y.; Xu, J.; Yu, Q.; Jiang, S. Cellulose Paper Sensors Modified with Zwitterionic Poly(carboxybetaine) for Sensing and Detection in Complex Media. Anal. Chem. 2014, 86 (6), 2871-2875.
(11) Li, X.; Ballerini, D. R.; Shen, W. A Perspective on Paper-Based Microfluidics: Current Status and Future Trends. Biomicrofluidics 2012, 6 (1), No. 011301.
(12) Berthier, J.; Brakke, K. A.; Berthier, E. Introduction. Open Microfluidics, 1st ed.; Wiley: Hoboken, N.J., 2016; pp 1-11.
(13) Convery, N.; Gadegaard, N. 30 Years of Microfluidics. Micro and Nano Engineering. 2019, 2, 76-91.
(14) Abdelgawad, M.; Wheeler, A. R. Low-Cost, Rapid-Prototyping of Digital Microfluidics Devices. Microfluid. Nanofluid. 2008, 4 (4), 349-355.
(15) Abdelgawad, M.; Wheeler, A. R. The Digital Revolution: A New Paradigm for Microfluidics. Adv. Mater. 2009, 21 (8), 920-925.
(16) Zhang, Y.; Nguyen, N.-T. Magnetic Digital Microfluidics—A Review. Lab Chip 2017, 17 (6), 994-1008.
(17) Samiei, E.; Tabrizian, M.; Hoorfar, M. A Review of Digital Microfluidics as Portable Platforms for Lab-on a-Chip Applications. Lab Chip 2016, 16, 2376.
(18) Jiang, N.; Ahmed, R.; Damayantharan, M.; Ünal, B.; Butt, H.; Yetisen, A. K. Lateral and Vertical Flow Assays for Point-of-Care Diagnostics. Adv. Healthcare Mater. 2019, 8, 1900244.
(19) Nguyen, V. T.; Song, S.; Park, S.; Joo, C. Recent Advances in High-Sensitivity Detection Methods for Paper-Based Lateral-Flow Assay. Biosens. Bioelectron. 2020, 152, 112015.
(20) Zhao, C.; Thuo, M. M.; Liu, X. A Microfluidic Paper-Based Electrochemical Biosensor Array for Multiplexed Detection of Metabolic Biomarkers. Sci. Technol. Adv. Mater. 2013, 14, 054402.
(21) Gehring, A. G.; Tu, S. I. High-Throughput Biosensors for Multiplexed Food-Borne Pathogen Detection. Annu. Rev. Anal. Chem. 2011, 4, 151.
(22) Lloyd, T. Forty Years of Price Transmission Research in the Food Industry: Insights. Challenges and Prospects. J. Agric. Econ. 2017, 68, 3.
(23) Carey, R. O.; Wollheim, W. M.; Mulukutla, G. K.; Mineau, M. M. Characterizing Storm-Event Nitrate Fluxes in a Fifth Order Suburbanizing Watershed Using In Situ Sensors. Environ. Sci. Technol. 2014, 48 (14), 7756-7765.
(24) Macary, F.; Morin, S.; Probst, J. L.; Saudubray, F. A Multi-Scale Method to Assess Pesticide Contamination Risks in Agricultural Watersheds. Ecol. Indic. 2014, 36, 624.
(25) Berthier, E.; Dostie, A. M.; Lee, U. N.; Berthier, J.; Theberge, A. B. Open Microfluidic Capillary Systems. Anal. Chem. 2019, 91, 8739.
(26) Gong, M. M.; Sinton, D. Turning the Page: Advancing Paper-Based Microfluidics for Broad Diagnostic Application. Chem. Rev. 2017, 117, 8447.
(27) Temiz, Y.; Lovchik, R. D.; Kaigala, G. V.; Delamarche, E. Lab-on-a-Chip Devices: How to Close and Plug the Lab? Microelectron. Eng. 2015, 132, 156-175.
(28) Ghosh, A.; Ganguly, R.; Schutzius, T. M.; Megaridis, C. M. Wettability Patterning for High-Rate, Pumpless Fluid Transport on Open. Lab Chip 2014, 14 (9), 1538-1550.
(29) Nakashima, Y.; Nakanishi, Y.; Yasuda, T. Automatic Droplet Transportation on a Plastic Microfluidic Device Having Wettability Gradient Surface. Rev. Sci. Instrum. 2015, 86 (1), No. 015001.
(30) Khoo, H. S.; Tseng, F.-G. Spontaneous High-Speed Transport of Subnanoliter Water Droplet on Gradient Nanotextured Surfaces. Appl. Phys. Lett. 2009, 95 (6), No. 063108.
(31) Shirtcliffe, N. J.; Roach, P. Methods Mol. Biol. 2013, 949, 269-281.
(32) Koc, Y.; de Mello, A. J.; McHale, G.; Newton, M. I.; Roach, P.; Shirtcliffe, N. J. NanoScale Superhydrophobicity: Suppression of Protein Adsorption and Promotion of Flow-Induced Detachment. Lab Chip 2008, 8 (4), 582.
(33) Dungchai, W.; Chailapakul, O.; Henry, C. S. Electrochemical Detection for Paper-Based Microfluidics. Anal. Chem. 2009, 81 (14), 5821-5826.
(34) Nakajima, A.; Nakagawa, Y.; Furuta, T.; Sakai, M.; Isobe, T.; Matsushita, S. Sliding of Water Droplets on Smooth Hydrophobic Silane Coatings with Regular Triangle Hydrophilic Regions. Langmuir 2013, 29 (29), 9269-9275.
(35) Alheshibri, M. H.; Rogers, N. G.; Sommers, A. D.; Eid, K. F. Spontaneous Movement of Water Droplets on Patterned Cu and Al Surfaces with Wedge-Shaped Gradients. Appl. Phys. Lett. 2013, 102 (17), 174103.
(36) Jokinen, V.; Sainiemi, L.; Franssila, S. Complex Droplets on Chemically Modified Silicon Nanograss. Adv. Mater. 2008, 20 (18), 3453-3456.
(37) Jokinen, V.; Kostiainen, R.; Sikanen, T. Multiphase Designer Droplets for Liquid-Liquid Extraction. Adv. Mater. 2012, 24 (46), 6240-6243.
(38) Manoudis, P. N.; Karapanagiotis, I. Modification of the Wettability of Polymer Surfaces Using Nanoparticles. Prog. Org. Coat. 2014, 77 (2), 331-338.
(39) Hsu, C.-C.; Chen, P.-H. Surface Wettability Effects on Critical Heat Flux of Boiling Heat Transfer Using Nanoparticle Coatings. Int. J. Heat Mass Transfer 2012, 55 (13-14), 3713-3719.
(40) Baidya, A.; Ganayee, M. A.; Jakka Ravindran, S.; Tam, K. C.; Das, S. K.; Ras, R. H. A.; Pradeep, T. Organic Solvent-Free Fabrication of Durable and Multifunctional Superhydrophobic Paper from Waterborne Fluorinated Cellulose Nanofiber Building Blocks. ACS Nano 2017, 11 (11), 11091-11099.
(41) Zhang, Y.; Zhang, L.; Zhou, C. Review of Chemical Vapor Deposition of Graphene and Related Applications. Acc. Chem. Res. 2013, 46 (10), 2329-2339.
(42) Claussen, J. C.; Kumar, A.; Jaroch, D. B.; Khawaja, M. H.; Hibbard, A. B.; Porterfield, D. M.; Fisher, T. S. Nanostructuring Platinum Nanoparticles on Multilayered Graphene Petal Nanosheets for Electrochemical Biosensing. Adv. Funct. Mater. 2012, 22 (16), 3399-3405.
(43) Parate, K.; Pola, C. C.; Rangnekar, S. V.; Mendivelso-Perez, D. L.; Smith, E. A.; Hersam, M. C.; Gomes, C. L.; Claussen, J. C. Aerosol-Jet-Printed Graphene Electrochemical Histamine Sensors for Food Safety Monitoring. 2D Mater. 2020, 7, 034002.
(44) He, Q.; Das, S. R.; Garland, N. T.; Jing, D.; Hondred, J. A.; Cargill, A. A.; Ding, S.; Karunakaran, C.; Claussen, J. C. Enabling Inkjet Printed Graphene for Ion Selective Electrodes with Postprint Thermal Annealing. ACS Appl. Mater. Interfaces 2017, 9 (14), 12719-12727.
(45) Le, L. T.; Ervin, M. H.; Qiu, H.; Fuchs, B. E.; Lee, W. Y. Graphene Supercapacitor Electrodes Fabricated by Inkjet Printing and Thermal Reduction of Graphene Oxide. Electrochem. Commun. 2011, 13, 355.
(46) Randviir, E. P.; Brownson, D. A. C.; Metters, J. P.; Kadara, R. O.; Banks, C. E. The Fabrication, Characterisation and Electro-chemical Investigation of Screen-Printed Graphene Electrodes. Phys. Chem. Chem. Phys. 2014, 16, 4598.
(47) Torrisi, F.; Hasan, T.; Wu, W.; Sun, Z.; Lombardo, A.; Kulmala, T. S.; Hsieh, G.-W.; Jung, S.; Bonaccorso, F.; Paul, P. J.; Chu, D.; Ferrari, A. C. Inkjet-Printed Graphene Electronics. ACS Nano 2012, 6 (4), 2992-3006.
(48) Secor, E. B.; Prabhumirashi, P. L.; Puntambekar, K.; Geier, M. L.; Hersam, M. C. Inkjet Printing of High Conductivity, Flexible Graphene Patterns. J. Phys. Chem. Lett. 2013, 4 (8), 1347-1351.
(49) Secor, E. B.; Gao, T. Z.; Islam, A. E.; Rao, R.; Wallace, S. G.; Zhu, J.; Putz, K. W.; Maruyama, B.; Hersam, M. C. Enhanced Conductivity, Adhesion, and Environmental Stability of Printed Graphene Inks with Nitrocellulose. Chem. Mater. 2017, 29, 2332.
(50) Secor, E. B.; Ahn, B. Y.; Gao, T. Z.; Lewis, J. A.; Hersam, M. C. Rapid and Versatile Photonic Annealing of Graphene Inks for Flexible Printed Electronics. Adv. Mater. 2015, 27 (42), 6683-6688.
(51) Das, S. R.; Nian, Q.; Cargill, A. A.; Hondred, J. A.; Ding, S.; Saei, M.; Cheng, G. J.; Claussen, J. C. 3D Nanostructured Inkjet Printed Graphene via UV-Pulsed Laser Irradiation Enables Paper-Based Electronics and Electrochemical Devices. Nanoscale 2016, 8 (35), 15870-15879.
(52) Hondred, J. A.; Stromberg, L. R.; Mosher, C. L.; Claussen, J. C. High-Resolution Graphene Films for Electrochemical Sensing via Inkjet Maskless Lithography. ACS Nano 2017, 11 (10), 9836-9845.
(53) Das, S. R.; Srinivasan, S.; Stromberg, L. R.; He, Q.; Garland, N.; Straszheim, W. E.; Ajayan, P. M.; Balasubramanian, G.; Claussen, J. C. Superhydrophobic Inkjet Printed Flexible Graphene Circuits via Direct-Pulsed Laser Writing. Nanoscale 2017, 9 (48), 19058-19065.
(54) Hall, L. S.; Hwang, D.; Chen, B.; Van Belle, B.; Johnson, Z. T.; Hondred, J. A.; Gomes, C. L.; Bartlett, M. D.; Claussen, J. C. All-Graphene-Based Open Fluidics for Pumpless, Small-Scale Fluid Transport via Laser-Controlled Wettability Patterning. Nanoscale Horizons 2021, 6 (1), 24-32.
(55) Graymore, M.; Stagnitti, F.; Allinson, G. Impacts of Atrazine in Aquatic Ecosystems. Environ. Int. 2001, 26 (7-8), 483-495.
(56) Mekonen, S.; Argaw, R.; Simanesew, A.; Houbraken, M.; Senaeve, D.; Ambelu, A.; Spanoghe, P. Pesticide Residues in Drinking Water and Associated Risk to Consumers in Ethiopia. Chemosphere 2016, 162, 252-260.
(57) Gunasekara, A. S.; Truong, T.; Goh, K. S.; Spurlock, F.; Tjeerdema, R. S. Environmental Fate and Toxicology of Fipronil. J. Pestic. Sci. 2007, 32 (3), 189-199.
(58) Kucherenko, I. S.; Sanborn, D.; Chen, B.; Garland, N.; Serhan, M.; Forzani, E.; Gomes, C.; Claussen, J. C. Ion-Selective Sensors Based on Laser-Induced Graphene for Evaluating Human Hydration Levels Using Urine Samples. Adv. Mater. Technol. 2020, 5 (6), 1901037.
(59) Li, Y.; Luong, D. X.; Zhang, J.; Tarkunde, Y. R.; Kittrell, C.; Sargunaraj, F.; Ji, Y.; Arnusch, C. J.; Tour, J. M. Laser-Induced Graphene in Controlled Atmospheres: From Superhydrophilic to Superhydrophobic Surfaces. Adv. Mater. 2017, 29 (27), 1700496.
(60) Luong, D. X.; Yang, K.; Yoon, J.; Singh, S. P.; Wang, T.; Arnusch, C. J.; Tour, J. M. Laser-Induced Graphene Composites as Multifunctional Surfaces. ACS Nano 2019, 13, 2579-2586.
(61) Nasser, J.; Lin, J.; Zhang, L.; Sodano, H. A. Laser Induced Graphene Printing of Spatially Controlled Super-Hydrophobic/Hydrophilic Surfaces. Carbon 2020, 162, 570-578.
(62) Duy, L. X.; Peng, Z.; Li, Y.; Zhang, J.; Ji, Y.; Tour, J. M. Laser-Induced Graphene Fibers. Carbon 2018, 126, 472-479.
(63) Gao, L.; McCarthy, T. J. Contact Angle Hysteresis Explained. Langmuir 2006, 22 (14), 6234-6237.
(64) Wenzel, R. N. Resistance of Solid Surfaces to Wetting by Water. Ind. Eng. Chem. 1936, 28 (8), 988-994.
(65) Cassie, A. B. D.; Baxter, S. Wettability of Porous Surfaces. Trans. Faraday Soc. 1944, 40 (0), 546.
(66) Nayak, P.; Kurra, N.; Xia, C.; Alshareef, H. N. Highly Efficient Laser Scribed Graphene Electrodes for On-Chip Electrochemical Sensing Applications. Adv. Electron. Mater. 2016, 2 (10), 1600185.
(67) Liu, S.; Peng, Y.; Chen, J.; Shi, W.; Yan, T.; Li, B.; Zhang, Y.; Li, J. Engineering Surface Functional Groups on Mesoporous Silica: Towards a Humidity-Resistant Hydrophobic Adsorbent. J. Mater. Chem. A 2018, 6 (28), 13769-13777.
(68) Law, K.-Y. Y. Definitions for Hydrophilicity, Hydrophobicity, and Superhydrophobicity: Getting the Basics Right. J. Phys. Chem. Lett. 2014, 5 (4), 686-688.
(69) Garland, N. T.; McLamore, E. S.; Cavallaro, N. D.; Mendivelso-Perez, D.; Smith, E. A.; Jing, D.; Claussen, J. C. Flexible Laser-Induced Graphene for Nitrogen Sensing in Soil. ACS Appl. Mater. Interfaces 2018, 10 (45), 39124-39133.
(70) Deng, H.; Zhang, C.; Xie, Y.; Tumlin, T.; Giri, L.; Karna, S. P.; Lin, J. Laser Induced MoS 2/Carbon Hybrids for Hydrogen Evolution Reaction Catalysts. J. Mater. Chem. A 2016, 4 (18), 6824-6830.
(71) Zhang, J.; Ren, M.; Li, Y.; Tour, J. M. In Situ Synthesis of Efficient Water Oxidation Catalysts in Laser-Induced Graphene. ACS Energy Lett. 2018, 3 (3), 677-683.
(72) Ren, M.; Zhang, J.; Tour, J. M. Laser-Induced Graphene Synthesis of Co3O4 in Graphene for Oxygen Electrocatalysis and Metal-Air Batteries. Carbon 2018, 139, 880-887.
(73) Yang, Y.; Song, Y.; Bo, X.; Min, J.; Pak, O. S.; Zhu, L.; Wang, M.; Tu, J.; Kogan, A.; Zhang, H.; Hsiai, T. K.; Li, Z.; Gao, W. A Laser-Engraved Wearable Sensor for Sensitive Detection of Uric Acid and Tyrosine in Sweat. Nat. Biotechnol. 2020, 38, 217-224.
(74) Veder, J. P.; De Marco, R.; Clarke, G.; Chester, R.; Nelson, A.; Prince, K.; Pretsch, E.; Bakker, E. Elimination of Undesirable Water Layers in Solid-Contact Polymeric Ion-Selective Electrodes. Anal. Chem. 2008, 80 (17), 6731-6740.
(75) Hu, J.; Stein, A.; Bühlmann, P. Rational Design of All-Solid-State Ion-Selective Electrodes and Reference Electrodes. TrAC, Trends Anal. Chem. 2016, 76, 102-114.
(76) Hu, J.; Ho, K. T.; Zou, X. U.; Smyrl, W. H.; Stein, A.; Buhlmann, P. All-Solid-State Reference Electrodes Based on Colloid-Imprinted Mesoporous Carbon and Their Application in Disposable Paper-Based Potentiometric Sensing Devices. Anal. Chem. 2015, 87, 2981.
(77) Guinovart, T.; Crespo, G. A.; Rius, F. X.; Andrade, F. J. A Reference Electrode Based on Polyvinyl Butyral (PVB) Polymer for Decentralized Chemical Measurements. Anal. Chim. Acta 2014, 821, 72-80.
(78) Bakker, E.; Pretsch, E. E.; Bühlmann, P. Selectivity of Potentiometric Ion Sensors. Anal. Chem. 2000, 72 (6), 1127-1133.
(79) Li, F.; Ye, J.; Zhou, M.; Gan, S.; Zhang, Q.; Han, D.; Niu, L. All-Solid-State Potassium-Selective Electrode Using Graphene as the Solid Contact. Analyst 2012, 137 (3), 618-623.
(80) Hu, J.; Stein, A.; Bühlmann, P. A Disposable Planar Paper-Based Potentiometric Ion-Sensing Platform. Angew. Chem., Int. Ed. 2016, 55 (26), 7544-7547.
(81) Piek, M.; Piech, R.; Paczosa-Bator, B. All-Solid-State Nitrate Selective Electrode with Graphene/Tetrathiafulvalene Nanocomposite as High Redox and Double Layer Capacitance Solid Contact. Electrochim. Acta 2016, 210, 407-414.
(82) Rubinova, N.; Chumbimuni-Torres, K.; Bakker, E. Solid-Contact Potentiometric Polymer Membrane Microelectrodes for the Detection of Silver Ions at the Femtomole Level. Sens. Actuators, B 2007, 121 (1), 135-141.
(83) Parate, K.; Rangnekar, S. V.; Jing, D.; Mendivelso-Perez, D. L.; Ding, S.; Secor, E. B.; Smith, E. A.; Hostetter, J. M.; Hersam, M. C.; Claussen, J. C. Aerosol-Jet-Printed Graphene Immunosensor for Label-Free Cytokine Monitoring in Serum. ACS Appl. Mater. Interfaces 2020, 12, 8592.
(84) Ye, R.; James, D. K.; Tour, J. M. Laser-Induced Graphene: From Discovery to Translation. Adv. Mater. 2019, 31 (1), 1803621.
(85) Zhao, F.; He, J.; Li, X.; Bai, Y.; Ying, Y.; Ping, J. Smart Plant-Wearable Biosensor for In-Situ Pesticide Analysis. Biosens. Bioelectron. 2020, 170 (June), 112636.
(86) Govindasamy, M.; Mani, V.; Chen, S. M.; Chen, T. W.; Sundramoorthy, A. K. Methyl Parathion Detection in Vegetables and Fruits Using Silver@Graphene Nanoribbons Nanocomposite Modified Screen Printed Electrode. Sci. Rep. 2017, 7 (1), 1-11.
(87) Sakthinathan, S.; Kubendhiran, S.; Chen, S. M.; Karuppiah, C.; Chiu, T. W. Novel Bifunctional Electrocatalyst for ORR Activity and Methyl Parathion Detection Based on Reduced Graphene Oxide/Palladium Tetraphenylporphyrin Nanocomposite. J. Phys. Chem. C 2017, 121 (26), 14096-14107.
(88) Mehta, J.; Vinayak, P.; Tuteja, S. K.; Chhabra, V. A.; Bhardwaj, N.; Paul, A. K.; Kim, K. H.; Deep, A. Graphene Modified Screen Printed Immunosensor for Highly Sensitive Detection of Parathion. Biosens. Bioelectron. 2016, 83, 339-346.
(89) Kesik, M.; Ekiz Kanik, F.; Turan, J.; Kolb, M.; Timur, S.; Bahadir, M.; Toppare, L. An Acetylcholinesterase Biosensor Based on a Conducting Polymer Using Multiwalled Carbon Nanotubes for Amperometric Detection of Organophosphorous Pesticides. Sens. Actuators, B 2014, 205, 39-49.
(90) Hondred, J. A.; Johnson, Z. T.; Claussen, J. C. Nanoporous Gold Peel-and-Stick Biosensors Created with Etching Inkjet Maskless Lithography for Electrochemical Pesticide Monitoring with Micro-fluidics. J. Mater. Chem. C 2020, 8 (33), 11376-11388.
(91) Hondred, J. A.; Medintz, I. L.; Claussen, J. C. Enhanced Electrochemical Biosensor and Supercapacitor with 3D Porous Architectured Graphene via Salt Impregnated Inkjet Maskless Lithography. Nanoscale Horizons 2019, 4 (3), 735-746.
(92) Nelis, J. L. D.; Tsagkaris, A. S.; Zhao, Y.; Lou-Franco, J.; Nolan, P.; Zhou, H.; Cao, C.; Rafferty, K.; Hajslova, J.; Elliott, C. T.; Campbell, K. The End User Sensor Tree: An End-User Friendly Sensor Database. Biosens. Bioelectron. 2019, 130, 245-253.
(93) Chen, B.; Jiang, Y.; Tang, X.; Pan, Y.; Hu, S. Fully Packaged Carbon Nanotube Supercapacitors by Direct Ink Writing on Flexible Substrates. ACS Appl. Mater. Interfaces 2017, 9 (34), 28433-28440.
(94) Peng, Z.; Lin, J.; Ye, R.; Samuel, E. L. G.; Tour, J. M. Flexible and Stackable Laser-Induced Graphene Supercapacitors. ACS Appl. Mater. Interfaces 2015, 7 (5), 3414-3419.
(95) Zhou, H.; Peng, Y.; Wu, H. B.; Sun, F.; Yu, H.; Liu, F.; Xu, Q.; Lu, Y. Fluorine-Rich Nanoporous Carbon with Enhanced Surface Affinity in Organic Electrolyte for High-Performance Supercapacitors. Nano Energy 2016, 21, 80-89.
(96) Joon, N. K.; He, N.; Ruzgas, T.; Bobacka, J.; Lisak, G. PVC-Based Ion-Selective Electrodes with a Silicone Rubber Outer Coating with Improved Analytical Performance. Anal. Chem. 2019, 91 (16), 10524-10531.
(97) Liu, H.; Gao, J.; Xue, M.; Zhu, N.; Zhang, M.; Cao, T. Processing of Graphene for Electrochemical Application: Non-covalently Functionalize Graphene Sheets with Water-Soluble Electroactive Methylene Green. Langmuir 2009, 25, 12006.
(98) Baptista-Pires, L.; Pérez-López, B.; Mayorga-Martinez, C. C.; Morales-Narváez, E.; Domingo, N.; Esplandiu, M. J.; Alzina, F.; Torres, C. M. S.; Merkoci̧, A. Electrocatalytic Tuning of Biosensing Response through Electrostatic or Hydrophobic Enzyme-Graphene Oxide Interactions. Biosens. Bioelectron. 2014, 61, 655.
(99) Akkarachanchainon, N.; Rattanawaleedirojn, P.; Chailapakul, O.; Rodthongkum, N. Hydrophilic Graphene Surface Prepared by Electrochemically Reduced Micellar Graphene Oxide as a Platform for Electrochemical Sensor. Talanta 2017, 165, 692.
(100) Feng, J.; Guo, Z. Wettability of Graphene: From Influencing Factors and Reversible Conversions to Potential Applications. Nanoscale Horizons 2019, 4 (2), 339-364.
(101) Moeremans, B.; Cheng, H.-W.; Hu, Q.; Garces, H. F.; Padture, N. P.; Renner, F. U.; Valtiner, M. Lithium-Ion Battery Electrolyte Mobility at Nano-Confined Graphene Interfaces. Nat. Commun. 2016, 7 (1), 12693.
(102) Sheng, Y.; Fell, C. R.; Son, Y. K.; Metz, B. M.; Jiang, J.; Church, B. C. Effect of Calendering on Electrode Wettability in Lithium-Ion Batteries. Front. Energy Res. 2014, 2 (DEC), 56.
(103) Papadopoulou, E.; Megaridis, C. M.; Walther, J. H.; Koumoutsakos, P. Ultrafast Propulsion of Water Nanodroplets on Patterned Graphene. ACS Nano 2019, 13 (5), 5465-5472.
(104) Preston, D. J.; Mafra, D. L.; Miljkovic, N.; Kong, J.; Wang, E. N. Scalable Graphene Coatings for Enhanced Condensation Heat Transfer. Nano Lett. 2015, 15 (5), 2902-2909.
(105) Rafiee, J.; Mi, X.; Gullapalli, H.; Thomas, A. V.; Yavari, F.; Shi, Y.; Ajayan, P. M.; Koratkar, N. A. Wetting Transparency of Graphene. Nat. Mater. 2012, 11 (3), 217-222.
(106) Cohen-Tanugi, D.; Grossman, J. C. Water Desalination across Nanoporous Graphene. Nano Lett. 2012, 12 (7), 3602-3608.
(107) You, Y.; Sahajwalla, V.; Yoshimura, M.; Joshi, R. K. Graphene and Graphene Oxide for Desalination. Nanoscale 2016, 8, 117-119.
(108) Homaeigohar, S.; Elbahri, M. Graphene Membranes for Water Desalination. NPG Asia Mater. 2017, 9 (8), e427-e427.
(109) Ding, G.; Jiao, W.; Chen, L.; Yan, M.; Hao, L.; Wang, R. A Self-Sensing, Superhydrophobic, Heterogeneous Graphene Network with Controllable Adhesion Behavior. J. Mater. Chem. A 2018, 6 (35), 16992-17000.
(110) Zhang, Q.; Xu, X.; Li, H.; Xiong, G.; Hu, H.; Fisher, T. S. Mechanically Robust Honeycomb Graphene Aerogel Multifunctional Polymer Composites. Carbon 2015, 93, 659.
(111) Akhtar, N.; Anemone, G.; Farias, D.; Holst, B. Fluorinated Graphene Provides Long Lasting Ice Inhibition in High Humidity. Carbon 2019, 141, 451.
(112) Umezawa, Y.; Bühlmann, P.; Umezawa, K.; Tohda, K.; Amemiya, S. Potentiometric Selectivity Coefficients of Ion-Selective Electrodes. Part I. Inorganic Cations (Technical Report). Pure Appl. Chem. 2000, 72 (10), 1851-2082.

### 4.4. Options and Alternatives

As discussed herein, the foregoing embodiments are non-limiting examples of aspects of the invention. Variations, including variations obvious to those skilled in the art, will be included within the invention.

The Specific Examples of Nano 2022, 16, 15-28 and its Supporting Information cited above discuss some options and alternatives. Those skilled in the art will appreciate how the techniques according to the invention can be applied to LIG generated patterns and functionalized according to need or desire.

Other examples of options and alternatives are as follows:

Starting Substrate for LIG Lasing

The substrate mentioned in Nano 2022, 16, 15-28 and its Supporting Information cited above is polyimide. Alternatives that produce LIG are possible so long as it meets the following general rule that LIG can be produced from them. Such alternatives are known to those skilled in the art.

Laser and Laser Operating Parameters

A laser and its operating parameters mentioned in Nano 2022, 16, 15-28 and its Supporting Information cited above is a CO₂ laser.

A carbon-dioxide laser (CO₂ laser) was one of the earliest gas lasers to be developed, and is still one of the most useful types of laser. Carbon-dioxide lasers are the highest-power continuous-wave lasers that are currently available. They are also quite efficient: the ratio of output power to pump power can be as large as 20%. The CO₂ laser produces a beam of infrared light with the principal wavelength bands centering on 9.6 and 10.6 micrometers (μm). The common plastic poly (methyl methacrylate) (PMMA) absorbs IR light in the 2.8-25 μm wavelength band, so CO₂ lasers have been used in recent years for fabricating microfluidic devices from it, with channel widths of a few hundred micrometers.

Alternatives that produce LIG on a relevant substrate can vary so long their operating characteristics, including power density delivered to the substrate, can be adjusted or controlled in an effective manner according to principles of aspects of the invention. Those skilled in the art will know alternatives. At least one (e.g., UV laser) is discussed in the incorporated by reference sources herein.

Patterning

As mentioned, the ability to create a wide variety of LIG patterning on a substrate with a laser allows high flexibility in the form factors of such patterning. They can be continuous or discontinuous. They can vary in width from the width of the laser spot to many times that width by precise and accurate scanning of the laser path relative the substrate surface. They can be linear, curved, or combinations. Non-limiting examples are in the incorporated by reference sources herein.

Tuning

As mentioned, in one aspect of the invention, the desired wettability of a patterning can be pre-selected and then created by a single lasing. The lasing is controlled as to power and speed to create a desired wettability. In another aspect part of the patterning wettability characteristic is generated by a first lasing of the patterning, and then a second lasing over part of the first lasing at a different laser power and speed can create a different wettability for those parts of the patterning. By empirical or apriori testing or knowledge, specific wettability characteristic (from at or near super hydrophilic to near or at super hydrophilic) can be selected, and the lasing(s) controlled to achieve the same for a given application. Tuning of other LIG properties or characteristics are possible, individually or in some combination or coordination, using aspects of the invention.

End Uses/Functionalizations

Nano 2022, 16, 15-28 and its Supporting Information cited above give non-limiting examples. Other the incorporated by reference sources herein including but not limited to
Kucherenko, I. S.; Sanborn, D.; Chen, B.; Garland, N.; Serhan, M.; Forzani, E.; Gomes, C.; Claussen, J. C. Ion-Selective Sensors Based on Laser-Induced Graphene for Evaluating Human Hydration Levels Using Urine Samples. Adv. Mater. Technol. 2020, 5 (6), 1901037. https://doi.org/10.1002/admt.201901037;
Garland, N. T.; McLamore, E. S.; Cavallaro, N. D.; Mendivelso-Perez, D.; Smith, E. A.; Jing, D.; Claussen, J. C. Flexible Laser-Induced Graphene for Nitrogen Sensing in Soil. ACS Appl. Mater. Interfaces 2018, 10 (45), 39124-39133. https://doi.org/10.1021/acsami.8b10991;
Zachary T. Johnson, Kelli Williams, Bolin Chen, Robert Sheets, Nathan Jared, Jingzhe Li, Emily A. Smith, and Jonathan C. Claussen. Electrochemical Sensing of Neonicotinoids Using Laser-Induced Graphene. ACS Sens. 2021, 6, 3063-3071;
Raquel R. A. Soares, Robert G. Hjort, Cicero C. Pola, Kshama Parate, Efraim L. Reis, Nilda F. F. Soares, Eric S. McLamore, Jonathan C. Claussen, and Carmen L. Gomes. Laser-Induced Graphene Electrochemical Immunosensors for Rapid and Label-Free Monitoring of Salmonella enterica in Chicken Broth, ACS Sens. 2020, 5, 1900-1911;
   describe LIG patternings that could be created according to one or more aspects of the invention. Others are, of course, possible.

Other options and alternatives are possible.

What is claimed is:

1. A method for fabricating on a substrate a laser-induced graphene (LIG) patterning comprising:
a. selecting a substrate capable of LIG patterning;
b. selecting a laser having an adjustable fluence;
c. determining a desired LIG patterning for the substrate;
d. determining a desired electrical conductivity, surface morphology, and/or surface wettability for the desired LIG patterning; and
e. in one step with one sub-system, scribing in open ambient air the desired LIG patterning by controlling fluence of the laser at the LIG patterning effective to tunably produce the desired electrical conductivity, surface morphology, and/or surface wettability for the desired patterning.

2. The method of claim 1 wherein the scribing in open air comprises either:
a. a single lasing in a first pass of the laser at a first fluence; or
b. a double lasing in a first pass of the laser at a first fluence and a second pass of the laser over at least a portion of the first pass at a second fluence; or
c. a triple, quadruple, or more lasing(s) over the same or different parts of the first lasing or other portions of the substrate.

3. The method of claim 2 wherein the first fluence comprises a first laser pulse density, and the second fluence comprises a second laser pulse density at 1% to 7% power of the first fluence.

4. The method of claim 3 wherein the second fluence is 3% power and 20% speed of the first fluence to convert superhydrophilic or hydrophilic LIG to at least near super hydrophobic LIG.

5. The method of claim 2 wherein the first fluence is for the entire desired LIG patterning, and is effective to produce the desired electrical conductivity, surface morphology, and surface wettability for the entire desired LIG patterning from the first pass.

6. The method of claim 5 wherein the desired LIG patterning comprises an interdigitated set of electrodes.

7. The method of claim 6 wherein the first fluence is selected for a desired surface wettability of the entire interdigitated set of electrodes including and between super hydrophobic and superhydrophilic.

8. The method of claim 7 wherein the interdigitated electrodes are functionalized with an electrolyte as a micro super capacitor and the first fluence is selected as a function of the electrolyte.

9. The method of claim 2 wherein the first fluence is for the entire desired LIG patterning, and is effective to produce a first desired electrical conductivity, surface morphology, and surface wettability for the entire desired LIG patterning, and the second fluence is for one or more portions of the entire desired LIG patterning and is effective to produce a second desired electrical conductivity, surface morphology, and surface wettability for the one or more portions that differs from one or more of electrical conductivity, surface morphology, or surface wettability for the first desired electrical conductivity, surface morphology, and surface wettability.

10. The method of claim 9 wherein the desired LIG patterning comprises an open microfluidic circuit where the one or more portions of the patterning are sidewalls bounding an open microfluidic track, wherein the first fluence produces at least a hydrophilic LIG at the track and the second fluence produces at least near super hydrophobic LIG at the sidewalls.

11. The method of claim 10 wherein the first fluence is selected for a desired surface wettability of the open microfluidic track and the second fluence is selected for a desired surface wettability of the sidewalls.

12. The method of claim 11 wherein the desired patterning further comprising open microfluidic circuits with flow division.

13. The method of claim 11 wherein the desired patterning further comprises open microfluidic circuits for fluid transport to a detection zone and leads for one or more electrodes for one or more sensors.

14. The method of claim 13 wherein the leads have either the first fluence or the second fluence applied for desired electrical conductivity, surface morphology, or surface wettability.

15. The method of claim 13 wherein the sensors are functionalized to comprise one of:
a. an ion selective sensor; or
b. an enzymatic sensor.

16. The method of claim 15 wherein the functionalized sensors are used for:
a. disease diagnostics,
b. environmental monitoring,
c. food safety,
d. water testing.

17. The method of claim 1 wherein the LIG patterning is tunably functionalized for at least one of:
a. sensors;
b. biosensors;
c. wearables;
d. antenna;
e. energy harvesters;
f. energy storage modules;
g. single-use electronics.

18. The method of claim 1 wherein the desired patterning is preprogrammed in a CAD drawing and the laser is moved according to the CAD drawing.

19. The method of claim 18 in combination with a CAD system and laser manipulator.

20. The method of claim 19 in combination with a scalable fabrication system.

21. A method for fabricating on a substrate a laser-induced graphene (LIG) patterning for open surface microfluidic fluid transport with flow division to a plurality of sensors comprising:
a. selecting a substrate capable of LIG patterning;
b. selecting a laser having an adjustable fluence and speed;
c. determining a desired LIG patterning for open surface microfluidic fluid transport, flow division, and sensing zones of sensor sensing elements;
d. single lasing in open ambient air the desired LIG patterning for the track and sidewalls of the open surface microfluidics and sensor sensing elements at sensing zones by controlling fluence and speed of the laser in a first pass of the laser;
e. double lasing one or more portions of the single lased LIG patterning to tunably produce a different surface wettability for the one or more double lased portions at a desired electrical conductivity and surface morphology for sidewalls of the open surface microfluidics and selected sensor sensing elements; and
f. functionalizing the sensor sensing elements for electrochemical sensing.

22. The method of claim 21 wherein:
a. the single lasing is at a first fluence and speed; and
b. the double lasing is at a second fluence and speed.

23. The method of claim 22 wherein:
a. the first fluence and speed is effective to generate at least a hydrophobic surface; and
b. the second lasing and speed is effective to generate at least a hydrophilic surface.

24. The method of claim 23 wherein the first fluence comprises a first laser pulse density, and the second fluence comprises a second laser pulse density at 1% to 7% power of the first fluence.

25. The method of claim 24 wherein the second fluence is 3% power and 20% speed of the first fluence to convert superhydrophilic or hydrophilic LIG to at least near super hydrophobic LIG.

26. A method for fabricating on a substrate a laser-induced graphene (LIG) patterning for creating a micro supercapacitor comprising:
a. selecting a substrate capable of LIG patterning;
b. selecting a laser having an adjustable fluence and speed;
c. determining a desired LIG patterning for an interdigitated pair of electrodes;
d. single lasing in open ambient air the desired LIG patterning for the interdigitated pair of electrodes by controlling fluence and speed of the laser; and
e. functionalizing the interdigitated electrodes for a micro super capacitor.

27. The method of claim 26 wherein:
a. the first fluence and speed is effective to generate one of
i. an at least a hydrophobic surface; or
ii. an at least a hydrophilic surface.

28. A system for fabricating on a substrate a laser-induced graphene (LIG) patterning comprising:
a. a scalable sub-system for conveying a substrate capable of LIG patterning;
b. a laser scribing sub-system having a laser with an adjustable fluence;
c. using the scalable sub-system for conveying and the laser scribing sub-system in the method of claim 1.

29. A system for fabricating on a substrate a laser-induced graphene (LIG) patterning comprising:
a. a scalable sub-system for conveying a substrate capable of LIG patterning;
b. a laser scribing sub-system having a laser with an adjustable fluence;
c. using the scalable sub-system for conveying and the laser scribing sub-system in the method of claim 21.

30. A system for fabricating on a substrate a laser-induced graphene (LIG) patterning comprising:
a. a scalable sub-system for conveying a substrate capable of LIG patterning;
b. a laser scribing sub-system having a laser with an adjustable fluence;
c. using the scalable sub-system for conveying and the laser scribing sub-system in the method of claim 26.
